(19) United States
(12) Patent Application Publication
(10) Pub. No.: US 2008/0286445 A1
(43) Pub. Date: Nov. 20, 2008

(54) COMPOSITION, AND METHOD OF FABRICATING LIGHT-EMITTING ELEMENT

(75) Inventors: Tsunenori SUZUKI, Yokohama (JP); Sachiko KAWAKAMI, Atsugi (JP); Satoshi SEO, Kawasaki (JP); Satoko SHITAGAKI, Isehara (JP)

Correspondence Address: FISH & RICHARDSON P.C., P.O. BOX 1022, MINNEAPOLIS, MN, 55440-1022, US

(73) Assignee: SEMICONDUCTOR ENERGY LABORATORY CO., LTD., Atsugi-shi (JP)

(21) Appl. No.: 12/121,384

(22) Filed: May 15, 2008

(30) Foreign Application Priority Data
May 17, 2007 (JP) 2007-131241

(51) Int. Cl. B05D 5/12; C09K 11/06

(52) U.S. Cl. 427/64; 252/301.16

(57) ABSTRACT

Objects of the present invention are to provide a composition in which an anthracene derivative is dissolved and a technique in which a thin film with favorable properties is formed using the composition by a wet process. Another object of the present invention is to fabricate a highly reliable light-emitting element using the composition at low cost and high productivity. The present invention provides a composition containing a solvent and an anthracene derivative represented by a general formula (1). By use of this composition, a thin film with favorable properties can be formed by a wet process. Accordingly, by use of such a thin film, a highly reliable light-emitting element can be fabricated.

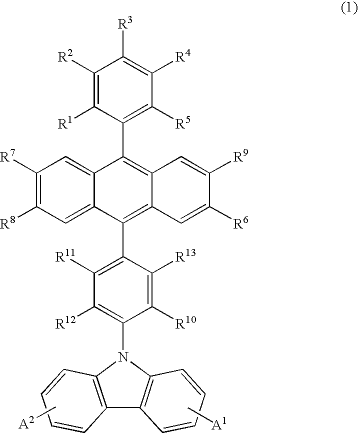

### BACKGROUND OF THE INVENTION

1. Field of the Invention

The present invention relates to a composition containing an anthracene derivative and a method of forming a thin film in which the composition is used. Further, the present invention also relates to a method of fabricating a light-emitting element in which electroluminescence is used.

2. Description of the Related Art

Compared with inorganic compounds, organic compounds provide materials that have a variety of structures and make it possible to synthesize materials that have a variety of functions depending on molecular designs. Because of these advantages, photo electronics and electronics using functional organic materials have been attracting attention in recent years.

Examples of electronic devices in which organic compounds are used as functional organic materials include solar cells, light-emitting elements, organic transistors, and the like. These are devices in which electric properties and optical properties of organic compounds are utilized. In particular, tremendous progress in light-emitting elements has been made.

It is said that light-emitting elements have a mechanism of light emission as follows: by application of a voltage between a pair of electrodes with a light-emitting layer interposed therebetween, electrons injected from a cathode and holes injected from an anode are recombined with each other in an emission center of a light-emitting layer to form molecular excitons, and the molecular excitons release energy in relax to a ground state; accordingly light is emitted. A singlet excited state and a triplet excited state are known as excited states, and it is considered that light can be emitted through either excited state.

Such light-emitting elements have a lot of material-dependant problems for improvement in element characteristics. In order to solve the problems, improvement in element structures, development of materials, or the like have been carried out.

Improvement in reliability is a challenge in light-emitting elements. In particular, it has been difficult to obtain a highly reliable clement by use of a blue light-emitting material that generally has high crystallinity. For example, diphenylanthracene with high fluorescence quantum efficiency has high crystallinity and can not provide favorable film properties; accordingly, reliability of a light-emitting element that contains diphenylanthracene is low. In order to obtain a material having lower crystallinity and higher stability, a phenylanthracene derivative as an anthracene derivative has been studied (for example, see Patent Document 1: Japanese Published Patent Application No. H8-12600).

### SUMMARY OF THE INVENTION

A thin film of the above anthracene derivative is typically formed by a vacuum evaporation method that is a dry process and used for a light-emitting element. The vacuum evaporation method, however, has problems, such as low material utilization efficiency and limitation on the size of a substrate, and thus is unsuitable for industrialization in which high productivity at low cost is required.

As a method that is capable of film formation on a large substrate at relatively low cost, wet processes in which a solution prepared by dissolution of a material in a solvent is used for film formation (a droplet discharging method (also referred to as an inkjet method) and a coating method (e.g., a spin coating method)) have been proposed.

However, in the use of a material such as an anthracene derivative, it has been difficult to obtain a thin film that has stability and favorable film properties by a wet process because of solubility in a solvent and the above problem such as high crystallinity.

Accordingly, objects of the present invention are to provide a composition in which an anthracene derivative is dissolved and a technique in which a thin film that has favorable film properties is formed using the composition by a wet process. Further, another object of the present invention is to fabricate a highly reliable light-emitting element using the composition while achieving a cost reduction and a productivity improvement.

The present inventors have found that a thin film which has no defect in shape and favorable film properties can be formed by a wet process using any of compositions in which anthracene derivatives represented by general formulae (1) to (5) are dissolved in solvents. Detailed description is made below.

One aspect of the present invention is a composition containing a solvent and an anthracene derivative represented by the general formula (1).

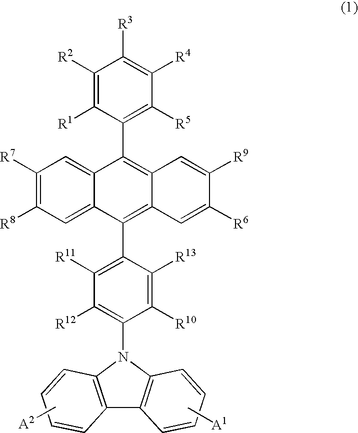

In the formula, R¹ to R¹³ each represent hydrogen, an alkyl group having 1 to 6 carbon atoms, or an aryl group having 6 to 14 carbon atoms, which may be substituted, and may be the same or different from each other; and A¹ and A² each represent hydrogen, an alkyl group having 1 to 6 carbon atoms, an aryl group having 6 to 14 carbon atoms, which may be substituted, or a diarylamino group, which may be substituted, and may be the same or different from each other.

One aspect of the present invention is a composition containing a solvent and an anthracene derivative represented by a general formula (2).

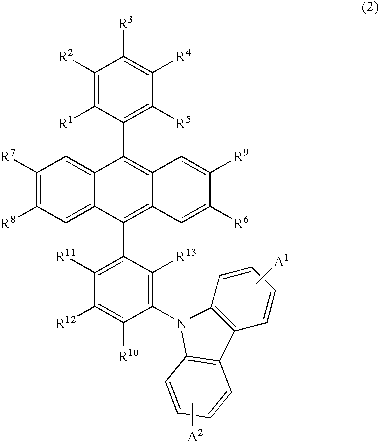

In the formula, R¹ to R¹³ each represent hydrogen, an alkyl group having 1 to 6 carbon atoms, or an aryl group having 6 to 14 carbon atoms, which may be substituted, and may be the same or different from each other; and A¹ and A² each represent hydrogen, an alkyl group having 1 to 6 carbon atoms, an aryl group having 6 to 14 carbon atoms, which may be substituted, or a diarylamino group, which may be substituted, and may be the same or different from each other.

One aspect of the present invention is a composition containing a solvent and an anthracene derivative represented by the general formula (1).

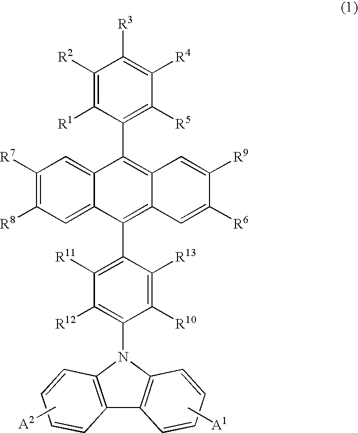

In the formula, R¹ to R¹³ each represent hydrogen or an aryl group having 6 to 14 carbon atoms, which may be substituted, and may be the same or different from each other; and A¹ and A² each represent hydrogen, an aryl group having 6 to 14 carbon atoms, which may be substituted, or a diarylamino group, which may be substituted, and may be the same or different from each other.

One aspect of the present invention is a composition containing a solvent and an anthracene derivative represented by the general formula (2).

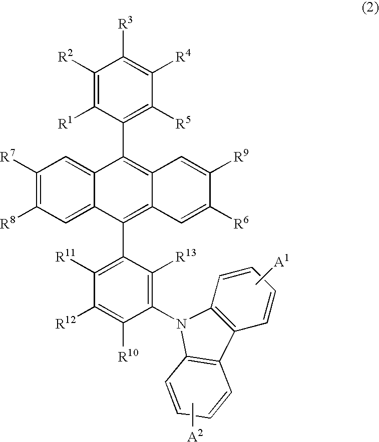

In the formula, R¹ to R¹³ each represent hydrogen or an aryl group having 6 to 14 carbon atoms, which may be substituted, and may be the same or different from each other; and A¹ and A² each represent hydrogen, an aryl group having 6 to 14 carbon atoms, which may be substituted, or a diarylamino group, which may be substituted, and may be the same or different from each other.

One aspect of the present invention is a composition containing a solvent and an anthracene derivative represented by a general formula (3).

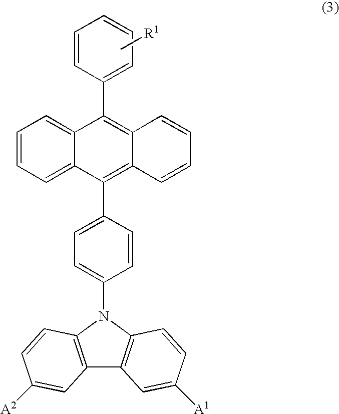

In the formula, R¹ represents hydrogen, an alkyl group having 1 to 6 carbon atoms, or an aryl group having 6 to 14 carbon atoms, which may be substituted; and A¹ and A² each represent hydrogen, an alkyl group having 1 to 6 carbon atoms, an aryl group having 6 to 14 carbon atoms, which may be substituted, or a diarylamino group, which may be substituted, and may be the same or different from each other.

One aspect of the present invention is a composition containing a solvent and an anthracene derivative represented by the general formula (3).

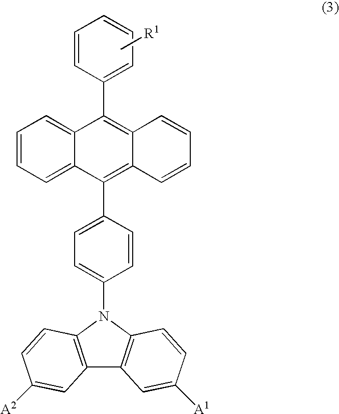

In the formula, R¹ represents hydrogen or an aryl group having 6 to 14 carbon atoms, which may be substituted; and A¹ and A² each represent hydrogen, an aryl group having 6 to 14 carbon atoms, which may be substituted, or a diarylamino group, which may be substituted, and may be the same or different from each other.

One aspect of the present invention is a composition containing a solvent and an anthracene derivative represented by a general formula (4).

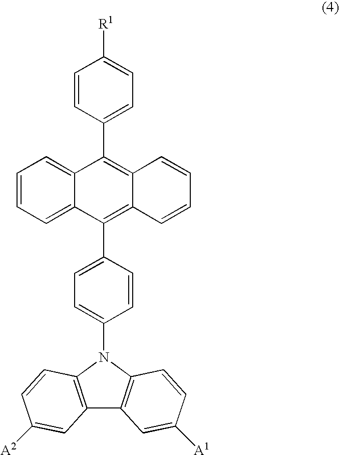

In the formula, R¹ represents hydrogen, an alkyl group having 1 to 6 carbon atoms, or an aryl group having 6 to 14 carbon atoms, which may be substituted; and A¹ and A² each represent hydrogen, an alkyl group having 1 to 6 carbon atoms, an aryl group having 6 to 14 carbon atoms, which may be substituted, or a diarylamino group, which may be substituted, and may be the same or different from each other.

One aspect of the present invention is a composition containing a solvent and an anthracene derivative represented by the general formula (4).

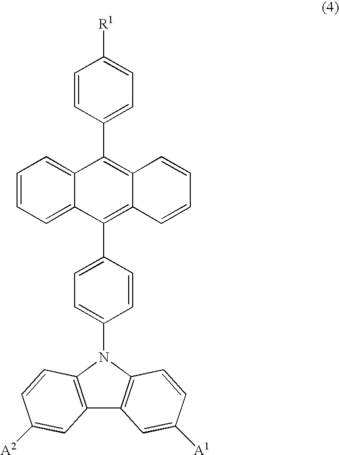

In the formula, R¹ represents hydrogen or an aryl group having 6 to 14 carbon atoms, which may be substituted; and A¹ and A² each represent hydrogen, an aryl group having 6 to 14 carbon atoms, which may be substituted, or a diarylamino group, which may be substituted, and may be the same or different from each other.

One aspect of the present invention is a composition containing a solvent and an anthracene derivative represented by a general formula (5).

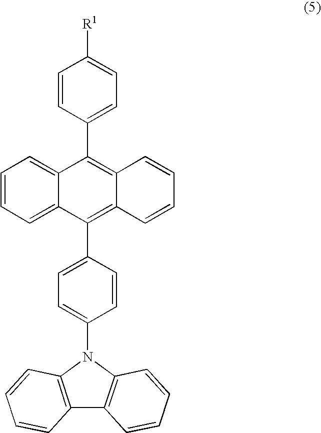

In the formula, R¹ represents hydrogen, an alkyl group having 1 to 6 carbon atoms, or an aryl group having 6 to 14 carbon atoms, which may be substituted.

One aspect of the present invention is a composition containing a solvent and an anthracene derivative represented by the general formula (5).

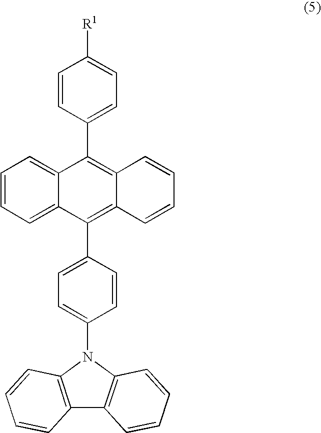

In the formula, R¹ represents hydrogen or an aryl group having 6 to 14 carbon atoms, which may be substituted.

The anthracene derivatives can be dissolved in, as the solvent in the above-described compositions, solvents that have aromatic rings (e.g., a benzene ring), such as toluene, xylene, methoxybenzene (anisole), dodecylbenzene, or a mixed solvent of dodecylbenzene and tetralin. The above-described anthracene derivatives can also be dissolved in organic solvents that do not have aromatic rings, such as dimethylsulfoxide (DMSO), dimethylformamide (DMF), or chloroform.

Further, the present invention also covers a method of forming a thin film that contains any of the above compositions. In one aspect of a method of forming a thin film of the present invention, any of the compositions is applied to a substrate, and the solvent is removed.

In one aspect of a method of forming a thin film of the present invention, any of the compositions is applied to a substrate, and the solvent is removed by heat treatment.

Furthermore, the present invention also covers a method of fabricating a light-emitting element with the use of any of the above compositions.

In one aspect of a method of fabricating a light-emitting element of the present invention, a first electrode is formed, a layer containing a light-emitting substance is formed by application of any of the compositions to the first electrode and then removing the solvent, and a second electrode is formed over the layer containing a light-emitting substance. The light-emitting element may be fabricated so that it includes functional layers, which can be formed by a wet or a dry process on the first electrode side and/or second electrode side of the layer containing a light-emitting substance.

A light-emitting device of the present invention can be manufactured using the light-emitting element of the present invention. The light-emitting device can be made to have a light-emitting element that includes a thin film formed using any of the above compositions and a control unit configured to control light emission of the light-emitting element. It is to be noted that the category of the light-emitting device in this specification includes image display devices and light sources (e.g., lighting devices).

Further, the category of the light-emitting device also includes modules in each of which a connector such as a flexible printed circuit (FPC), a tape automated bonding (TAB) tape, or a tape carrier package (TCP) is attached to a panel; modules in each of which a printed wiring board is provided at an end of a TAB tape or a TCP; and modules in each of which an integrated circuit (IC) is directly mounted on the light-emitting element by a chip on glass (COG) method.

Furthermore, an electronic device in which the light-emitting element of the present invention is used for its display portion can be manufactured. Accordingly, one aspect of the present invention is an electronic device that includes a display portion, and the display portion can be made to have the above-described light-emitting element and a control unit configured to control light emission of the light-emitting element.

A thin film formed by a wet process with the use of any of the compositions of the present invention in which an anthracene derivative is dissolved in a solvent can be made to have favorable film properties without defects or the like. Thus, with the use of such a composition and a thin film, a highly reliable light-emitting element can be fabricated.

In the present invention, since a wet process is employed for fabrication of a thin film and a light-emitting element, high material utilization efficiency and a reduction in expensive facilities such as a large vacuum apparatus can be achieved, resulting in a cost reduction and a productivity improvement. Thus, by use of the present invention, a light-emitting device and an electronic device that are highly reliable can be manufactured while achieving a cost reduction and a productivity improvement.

### BRIEF DESCRIPTION OF THE DRAWINGS

FIGS. 1A to 1C each illustrate a light-emitting element of the present invention.

FIG. 2 illustrates a light-emitting element of the present invention.

FIG. 3 illustrates a light-emitting element of the present invention.

FIGS. 4A and 4B illustrate a light-emitting device of the present invention.

FIGS. 5A and 5B illustrate a light-emitting device of the present invention.

FIGS. 6A to 6E illustrate electronic devices of the present invention.

FIG. 7 illustrates an electronic device of the present invention.

FIGS. 8A and 8B illustrate lighting devices of the present invention.

FIG. 9 illustrates a lighting device of the present invention.

FIGS. 10A to 10D illustrate a method of manufacturing a light-emitting device of the present invention.

FIG. 11 illustrates an example of a droplet discharging apparatus that can be applied to the present invention.

FIG. 12 illustrates an emission spectrum of a light-emitting element of Example 2.

FIG. 13 illustrates a light-emitting element of Example 4.

FIG. 14 illustrates luminance-current efficiency characteristics of Light-Emitting Element A of Example 4.

FIG. 15 illustrates current-voltage characteristics of Light-Emitting Element A of Example 4.

FIG. 16 illustrates an emission spectrum of Light-Emitting Element A of Example 4.

FIGS. 17A and 17B illustrate results of reliability testing of Light-Emitting Element A of Example 4.

### DETAILED DESCRIPTION OF THE INVENTION

Hereinafter, embodiment modes of the present invention are described in detail using the accompanying drawings. It is easily understood by those skilled in the art that the present invention is not limited to the description below and that modes and details thereof can be modified in a variety of ways without departing from the spirit and the scope of the present invention. Therefore, the present invention should not be interpreted as being limited to the description of the embodiment modes below.

### Embodiment Mode 1

In this embodiment mode, compositions of the present invention and a method of forming a thin film with the use of the composition are described.

The anthracene derivative contained in any of the compositions of the present invention is characterized in that it has one diphenylanthracene structure and one carbazole group in each molecule, as shown in general formulae (1) to (5) given below, for the reasons mentioned below.

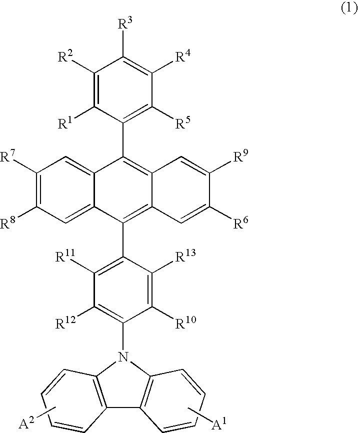

In the formula, R¹ to R¹³ each represent hydrogen, an alkyl group having 1 to 6 carbon atoms, or an aryl group having 6 to 14 carbon atoms, which may be substituted, and may be the same or different from each other; and A¹ and A² each represent hydrogen, an alkyl group having 1 to 6 carbon atoms, an aryl group having 6 to 14 carbon atoms, which may be substituted, or a diarylamino group, which may be substituted, and may be the same or different from each other.

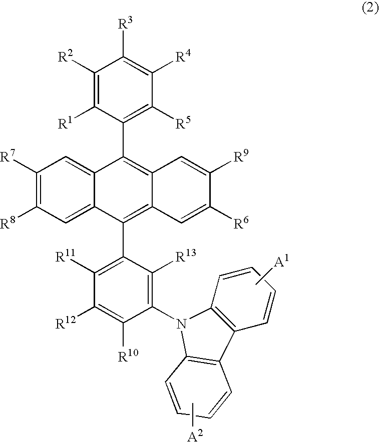

In the formula, R¹ to R¹³ each represent hydrogen, an alkyl group having 1 to 6 carbon atoms, or an aryl group having 6 to 14 carbon atoms, which may be substituted, and may be the same or different from each other; and A¹ and A² each represent hydrogen, an alkyl group having 1 to 6 carbon atoms, an aryl group having 6 to 14 carbon atoms, which may be substituted, or a diarylamino group, which may be substituted, and may be the same or different from each other.

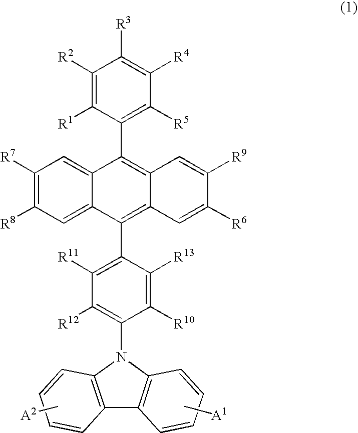

In the formula, R¹ to R¹³ each represent hydrogen or an aryl group having 6 to 14 carbon atoms, which may be substituted, and may be the same or different from each other; and A¹ and A² each represent hydrogen, an aryl group having 6 to 14 carbon atoms, which may be substituted, or a diarylamino group, which may be substituted, and may be the same or different from each other.

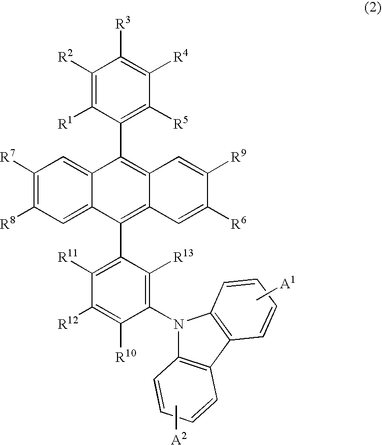

In the formula, R¹ to R¹³ each represent hydrogen or an aryl group having 6 to 14 carbon atoms, which may be substituted, and may be the same or different from each other; and A¹ and A² each represent hydrogen, an aryl group having 6 to 14 carbon atoms, which may be substituted, or a diarylamino group, which may be substituted, and may be the same or different from each other.

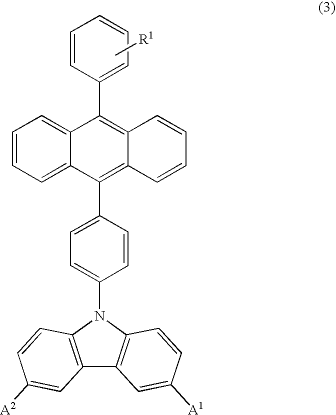

In the formula, R¹ represents hydrogen, an alkyl group having 1 to 6 carbon atoms, or an aryl group having 6 to 14 carbon atoms, which may be substituted; and A¹ and A² each represent hydrogen, an alkyl group having 1 to 6 carbon atoms, an aryl group having 6 to 14 carbon atoms, which may be substituted, or a diarylamino group, which may be substituted, and may be the same or different from each other.

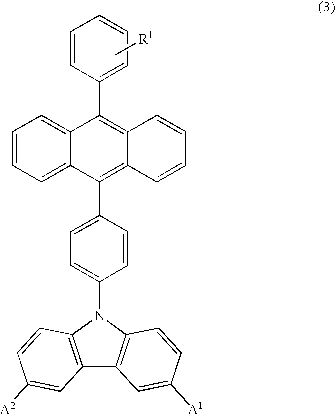

In the formula, R¹ represents hydrogen or an aryl group having 6 to 14 carbon atoms, which may be substituted; and A¹ and A² each represent hydrogen, an aryl group having 6 to 14 carbon atoms, which may be substituted, or a diarylamino group, which may be substituted, and may be the same or different from each other.

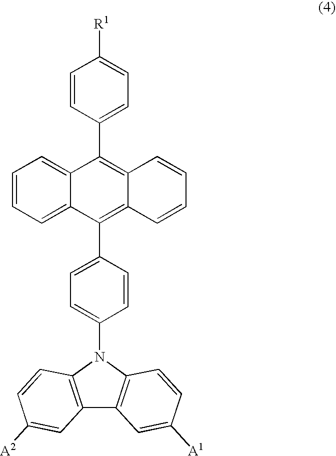

In the formula, R¹ represents hydrogen, an alkyl group having 1 to 6 carbon atoms, or an aryl group having 6 to 14 carbon atoms, which may be substituted; and A¹ and A² each represent hydrogen, an alkyl group having 1 to 6 carbon atoms, an aryl group having 6 to 14 carbon atoms, which may be substituted, or a diarylamino group, which may be substituted, and may be the same or different from each other.

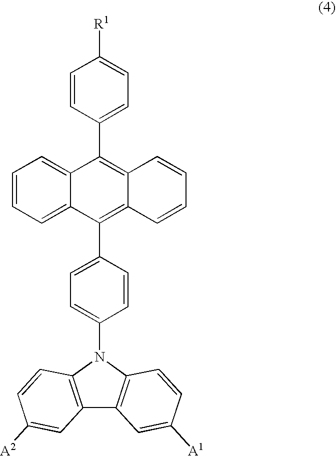

In the formula, R¹ represents hydrogen or an aryl group having 6 to 14 carbon atoms, which may be substituted; and A¹ and A² each represent hydrogen, an aryl group having 6 to 14 carbon atoms, which may be substituted, or a diarylamino group, which may be substituted, and may be the same or different from each other.

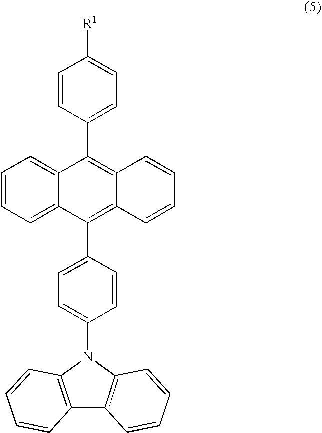

In the formula, R¹ represents hydrogen, an alkyl group having 1 to 6 carbon atoms, or an aryl group having 6 to 14 carbon atoms, which may be substituted.

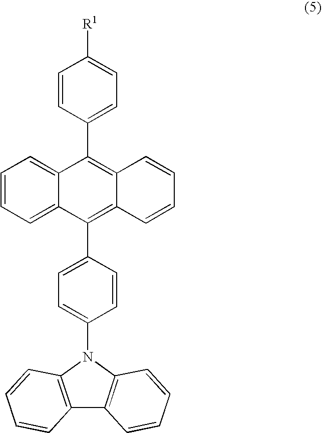

In the formula, R¹ represents hydrogen or an aryl group having 6 to 14 carbon atoms, which may be substituted.

An alkyl group is highly effective in inhibiting crystallization, and thus, introduction of an alkyl group to a structure has the effect of reducing inhibiting the crystallization. However, with regard to anthracene derivatives contained in the compositions of the present invention, each anthracene derivative can be dissolved in a solvent even if the structure has no alkyl group, and a film with uniform film properties can be formed by a wet process. The structure not having an alkyl group is more preferably used for electronic devices or the like because carriers are easily transported in such a structure.

Since the anthracene derivative that has the above-described structure and is contained in any of the compositions of the present invention has a wide band gap, blue light emission with high color purity can be obtained. Furthermore, the anthracene derivative contained in any of the compositions of the present invention has high electrochemical stability and thermal stability.

The anthracene derivative contained in any of the compositions of the present invention can not only be used individually for the layer containing a light-emitting substance but also be used as a host. Light emission from a dopant that is to serve as a light-emitting substance can be obtained with a structure in which the dopant that is to serve as a light-emitting substance is dispersed in the composition of the present invention which contains an anthracene derivative and a solvent. Use of the anthracene derivative as a host makes it possible to obtain blue light emission with high color purity.

The anthracene derivative contained in any of the compositions of the present invention can also be used for the functional layers of a light-emitting element. The anthracene derivative in which at least one of A¹ and A² in the above general formula (1) represents a diarylamino group can be used for a hole-transporting layer or a hole-injecting layer. The anthracene derivative in which both A¹ and A² in the above general formula (1) do not represent a diarylamino group can be used for an electron-transporting layer or an electron-injecting layer. Thus, the functional layers of the light-emitting element can be formed by a wet process with the use of any of the compositions of the present invention which contains an anthracene derivative and a solvent.

For a light-emitting element, by use of a thin film formed by a wet process with the use of any of the compositions of the present invention which contains an anthracene derivative and a solvent, the light-emitting element can be made to be highly reliable.

According to the above-described design principle, typical examples of the anthracene derivatives represented by the above general formulae (1) to (5) are shown in structural formulae (11) to (120) given below. Naturally, the present invention is not limited to the examples. In structural formulae in this specification, t-Bu indicates a tert-butyl group and Ph indicates a phenyl group.

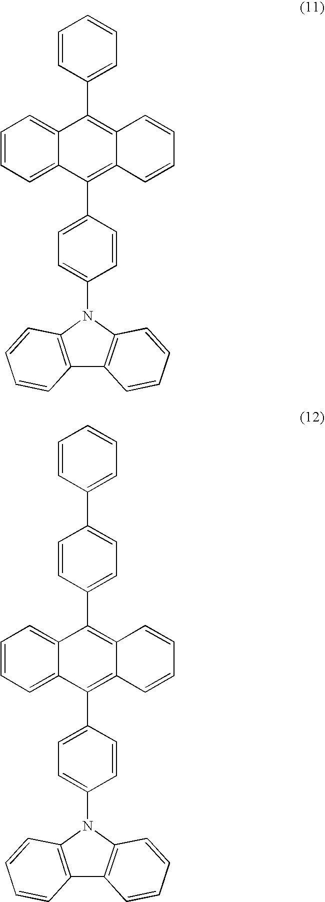

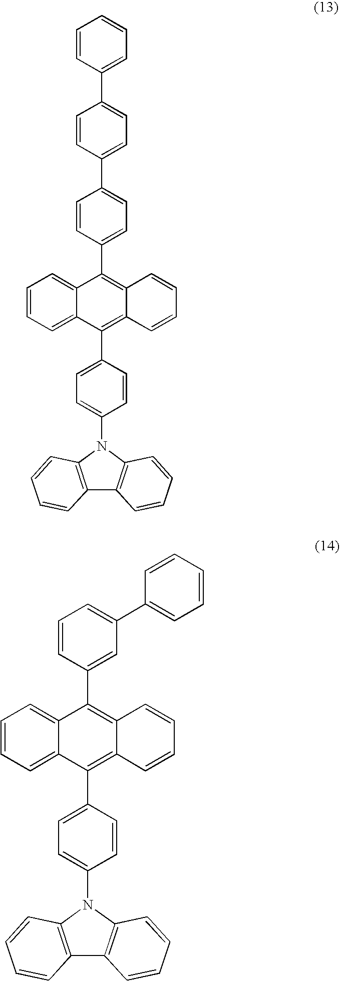

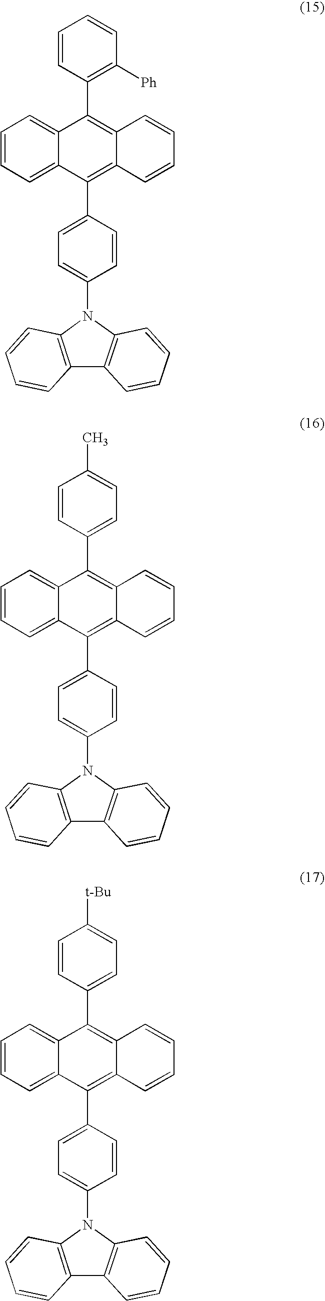

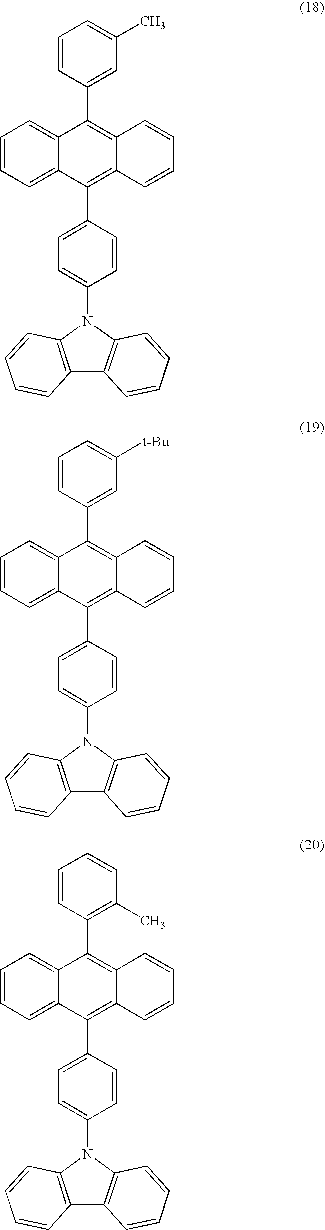

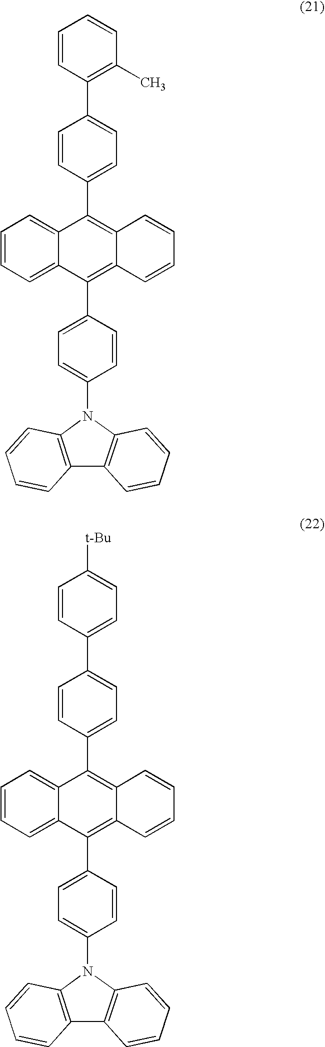

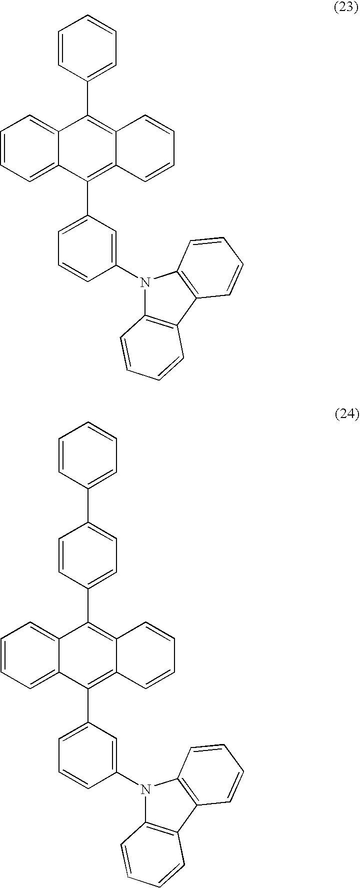

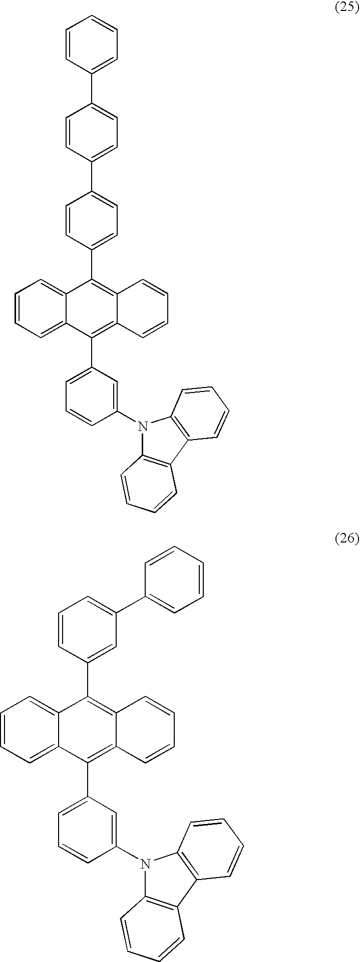

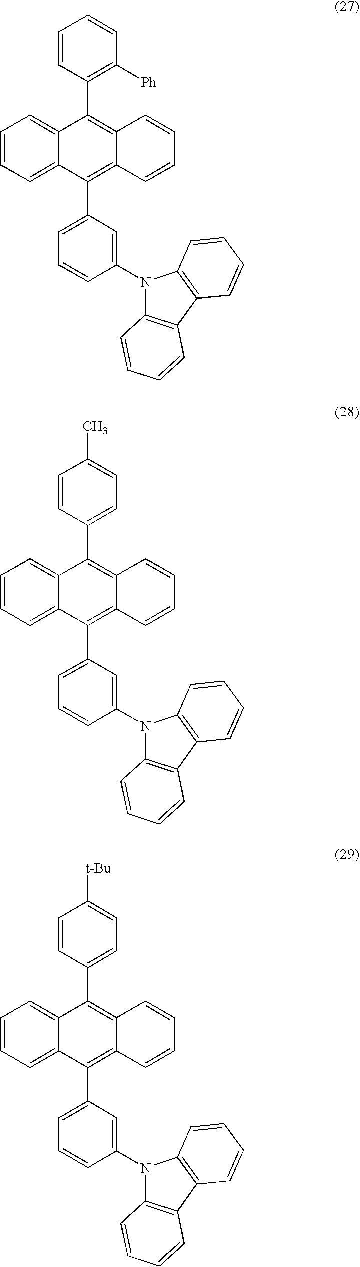

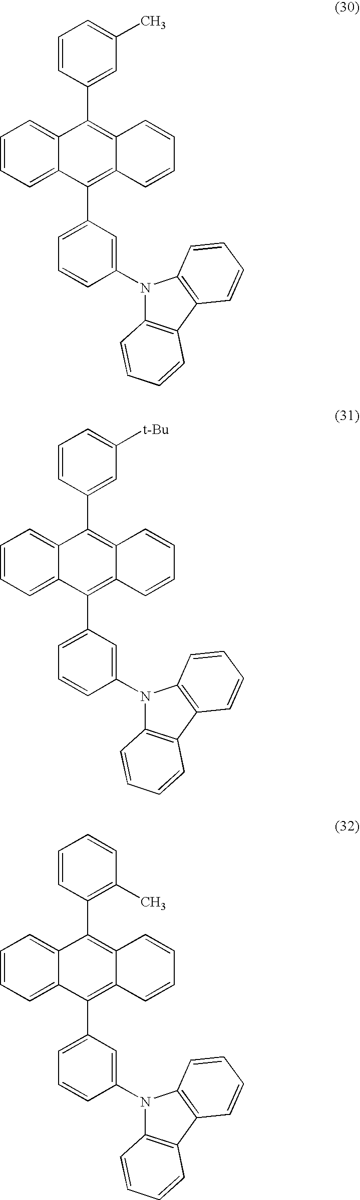

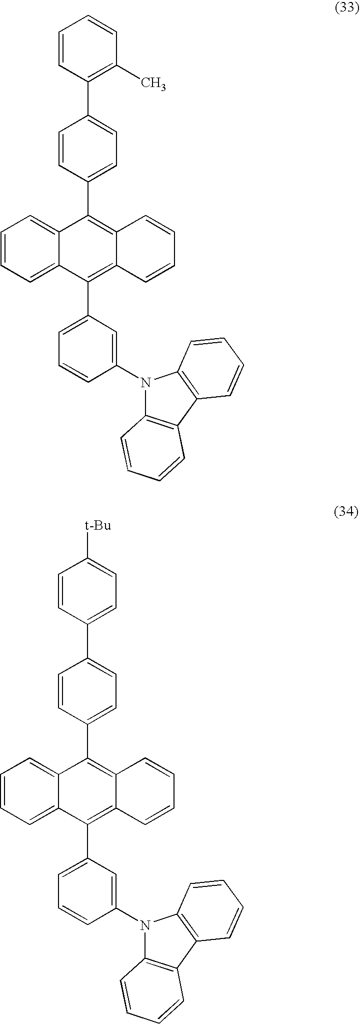

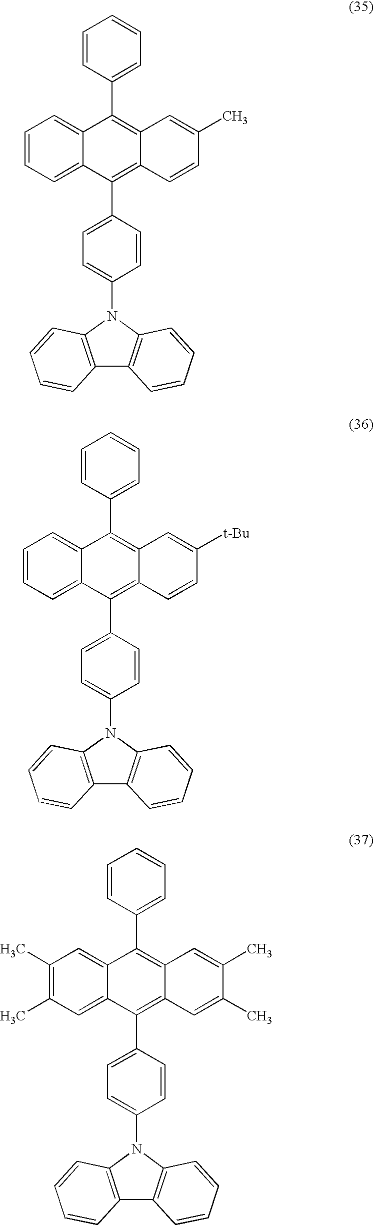

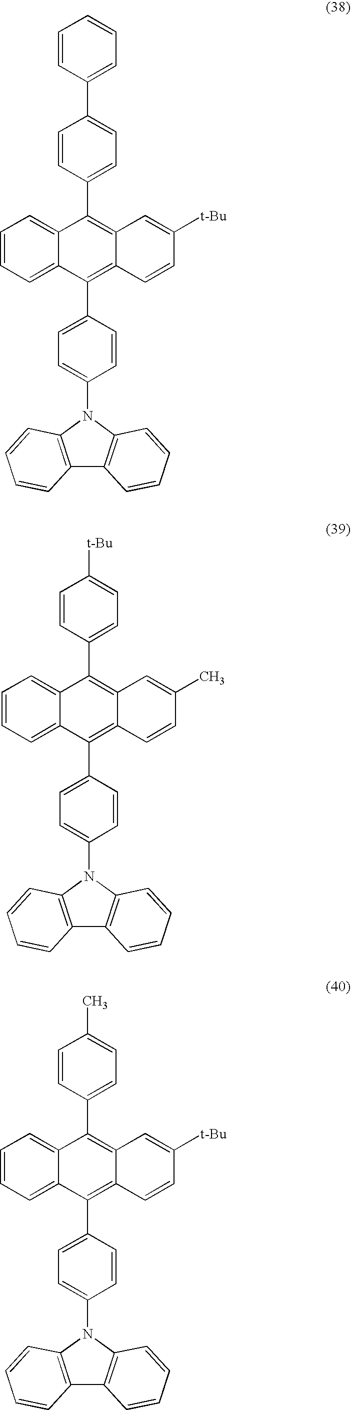

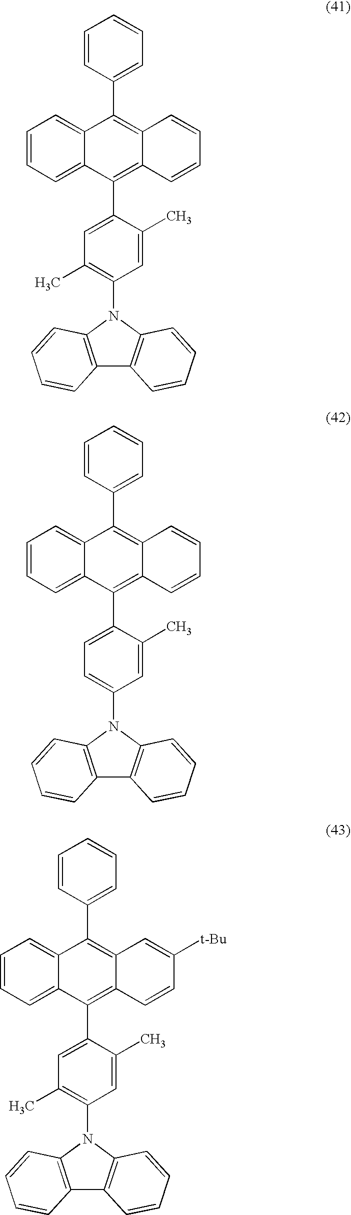

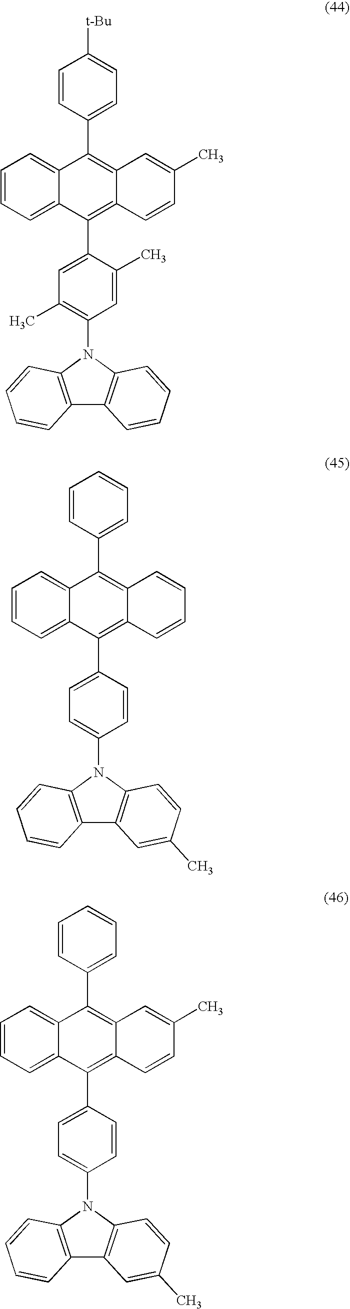

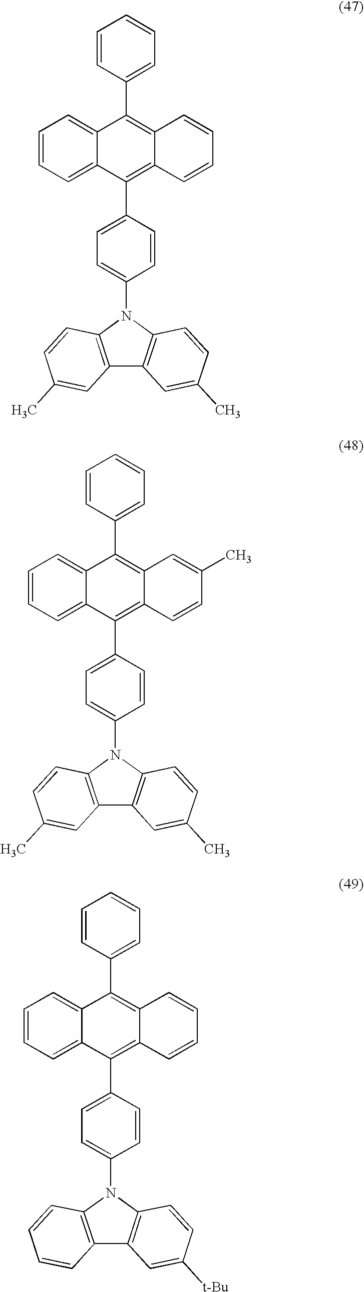

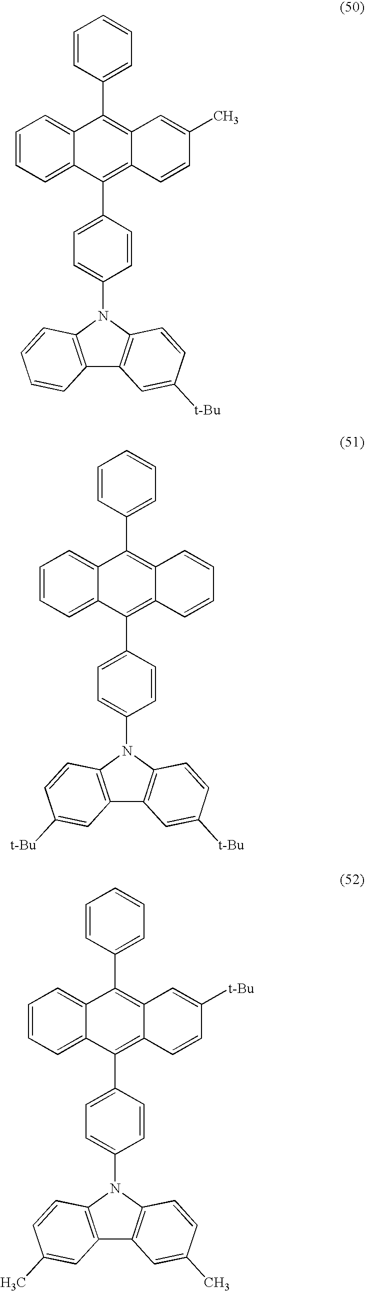

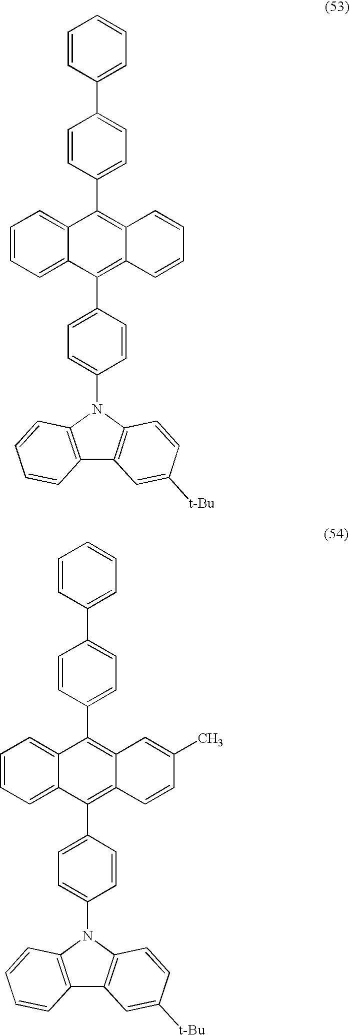

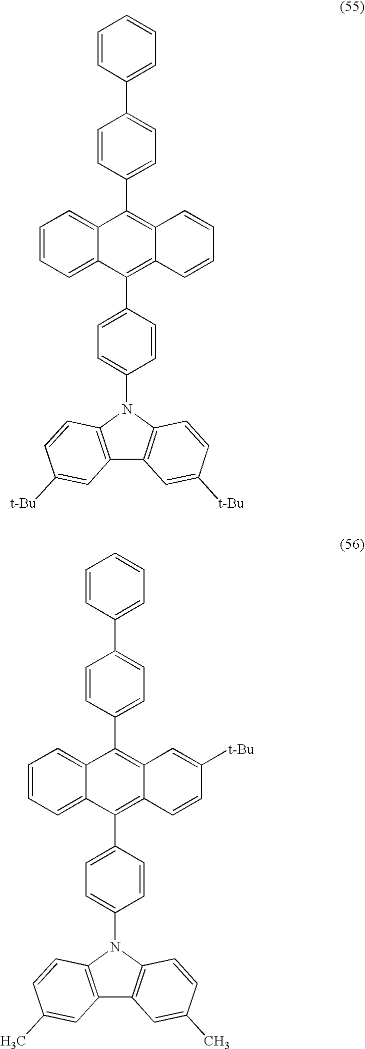

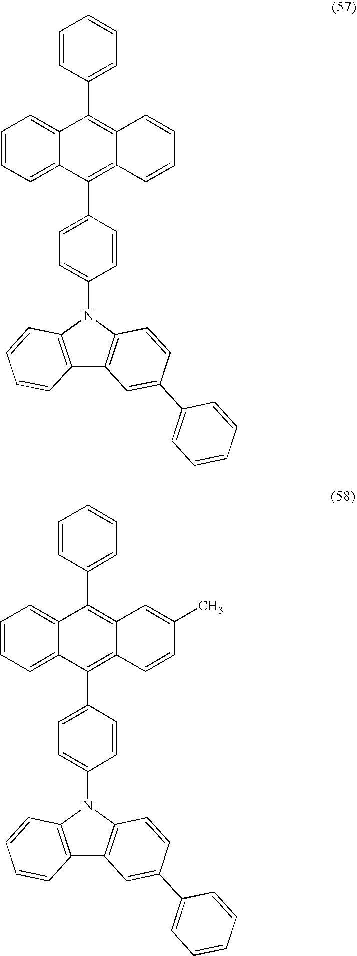

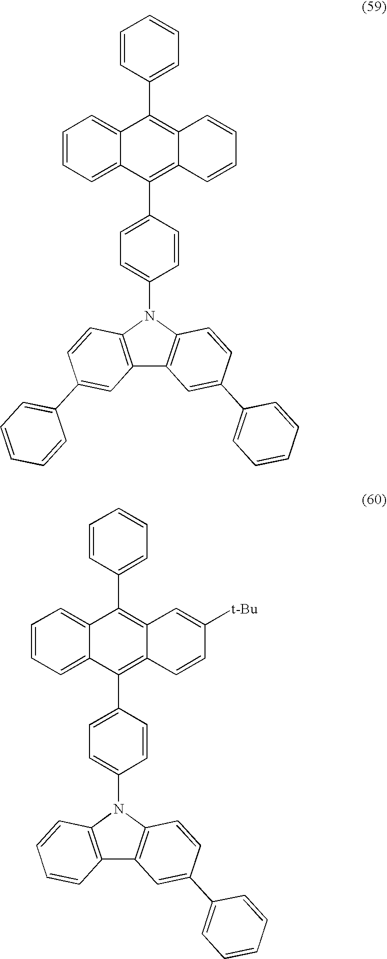

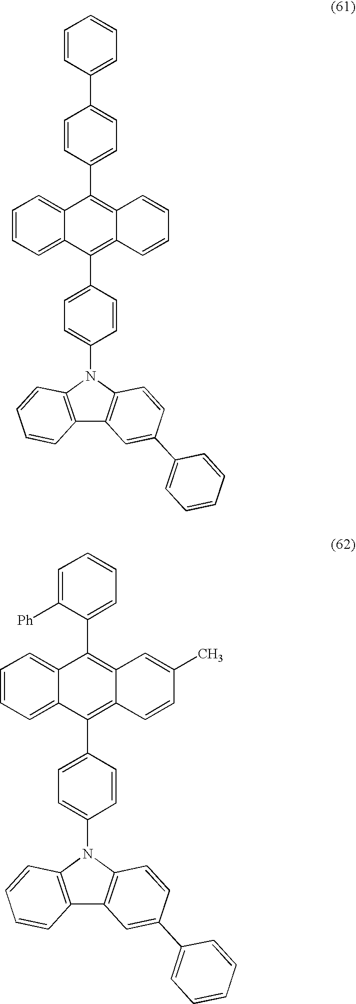

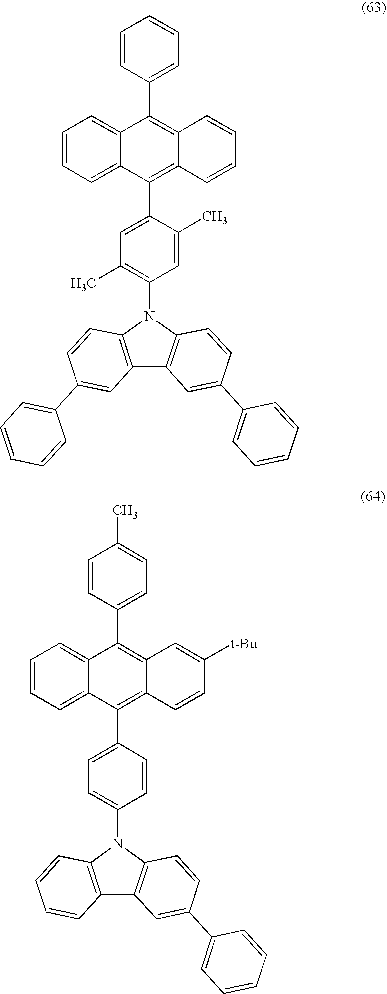

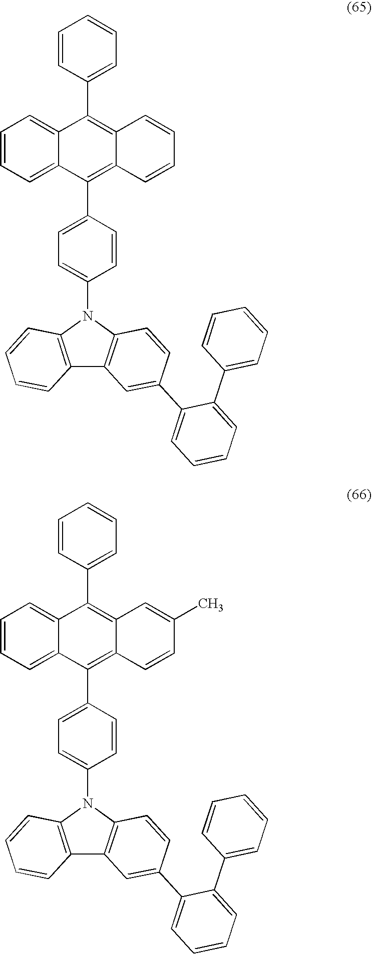

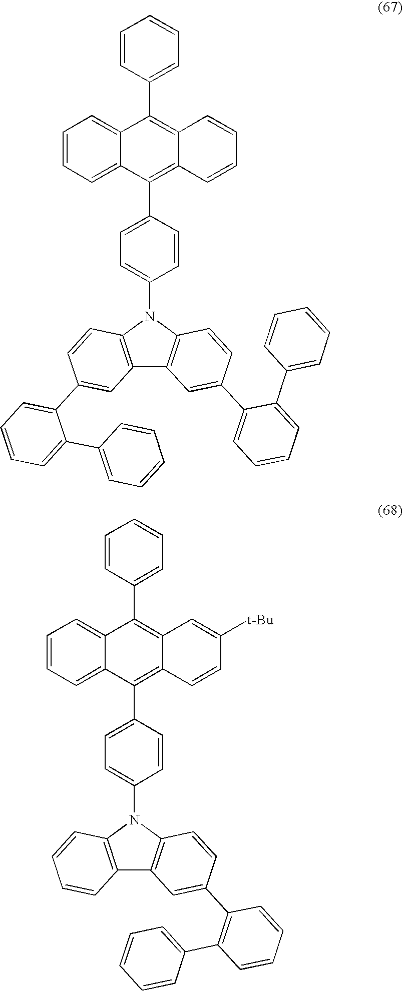

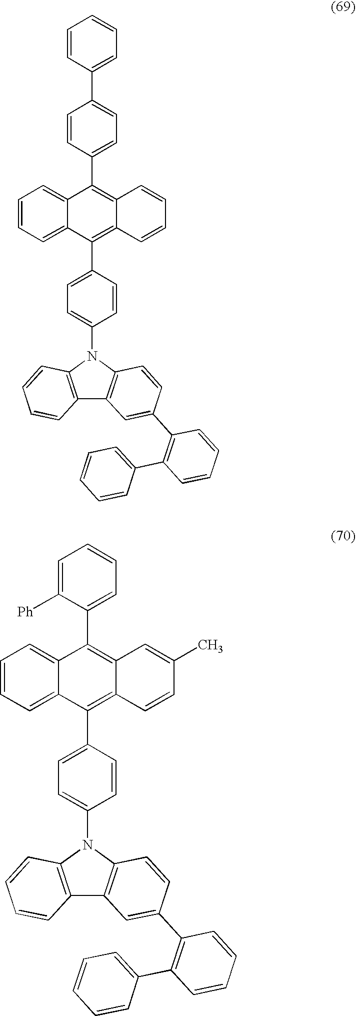

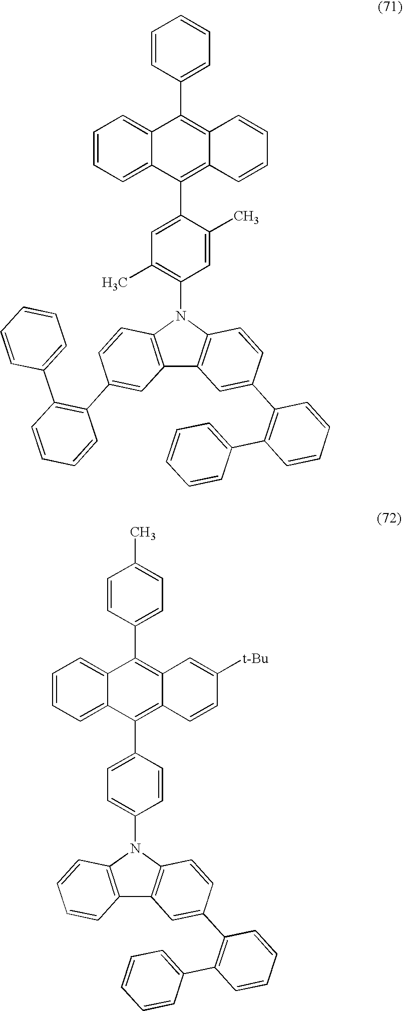

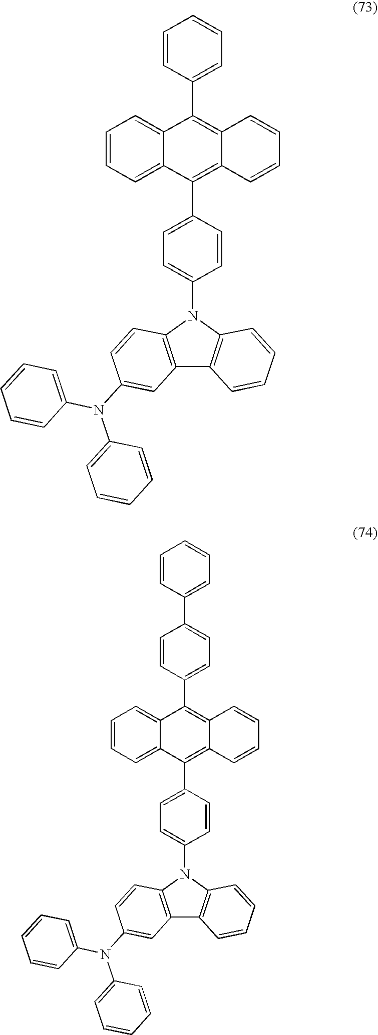

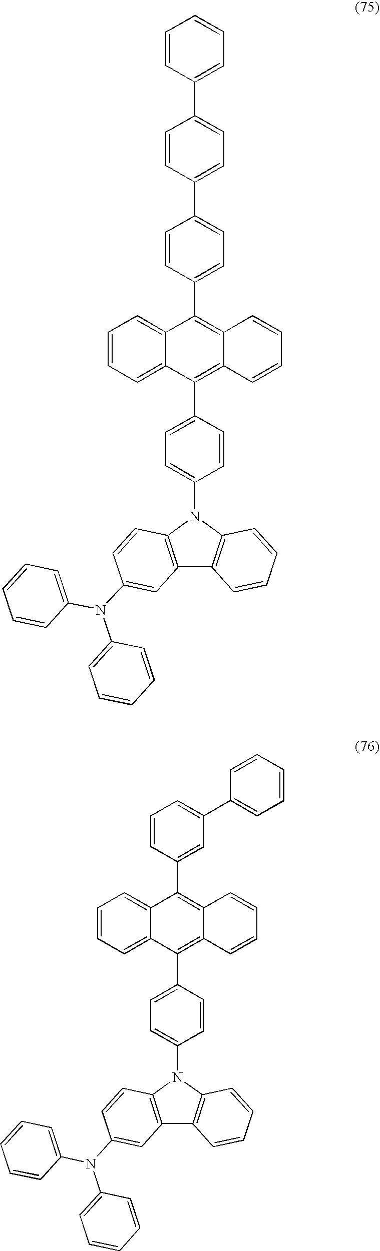

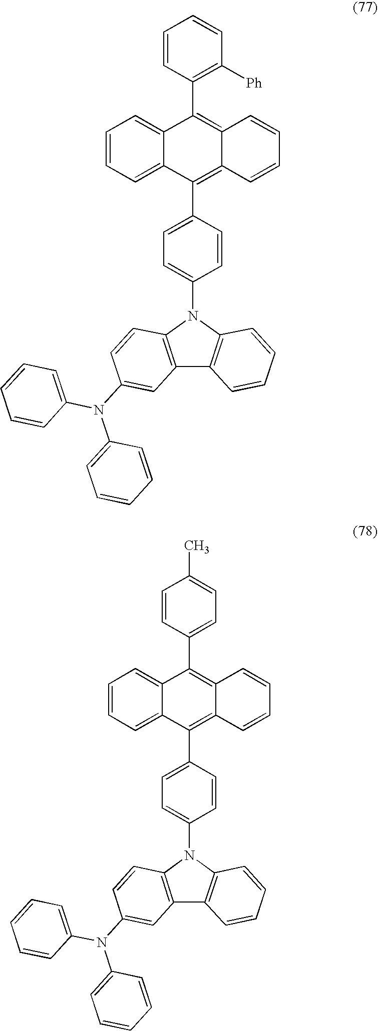

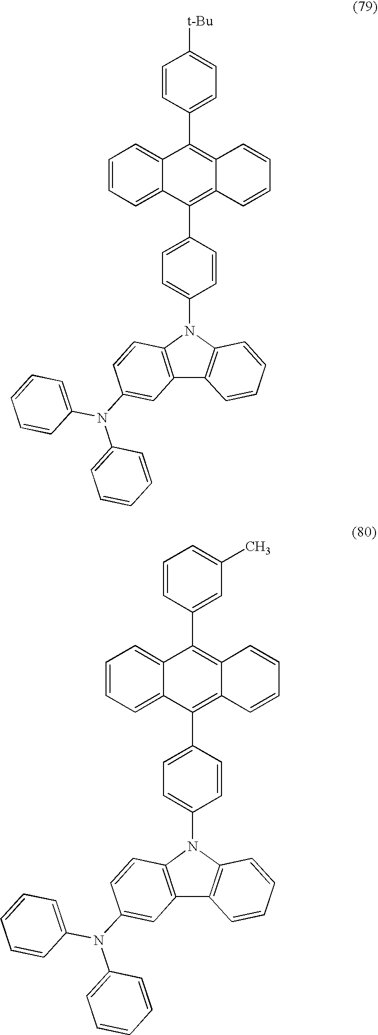

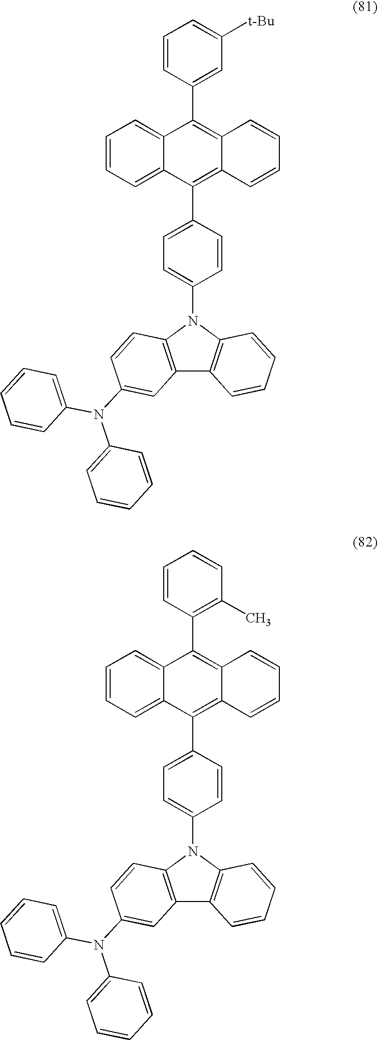

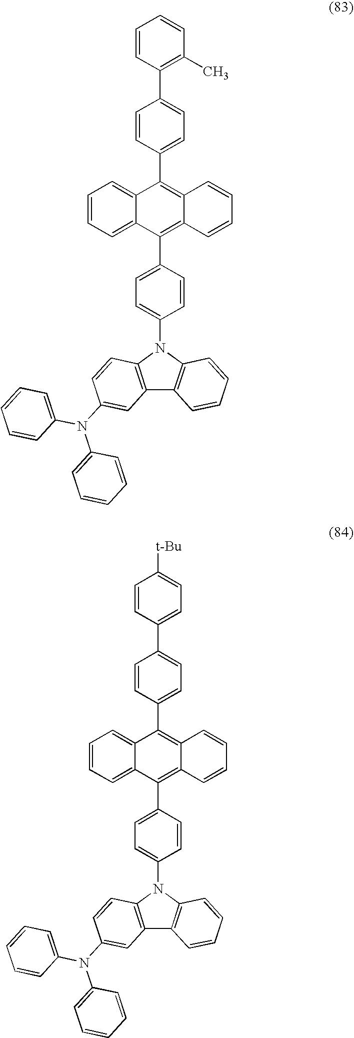

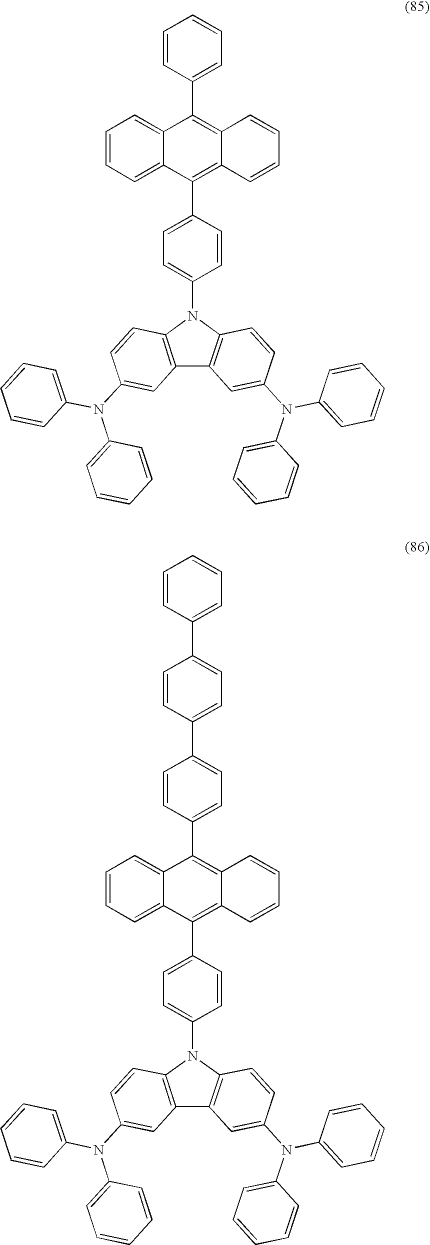

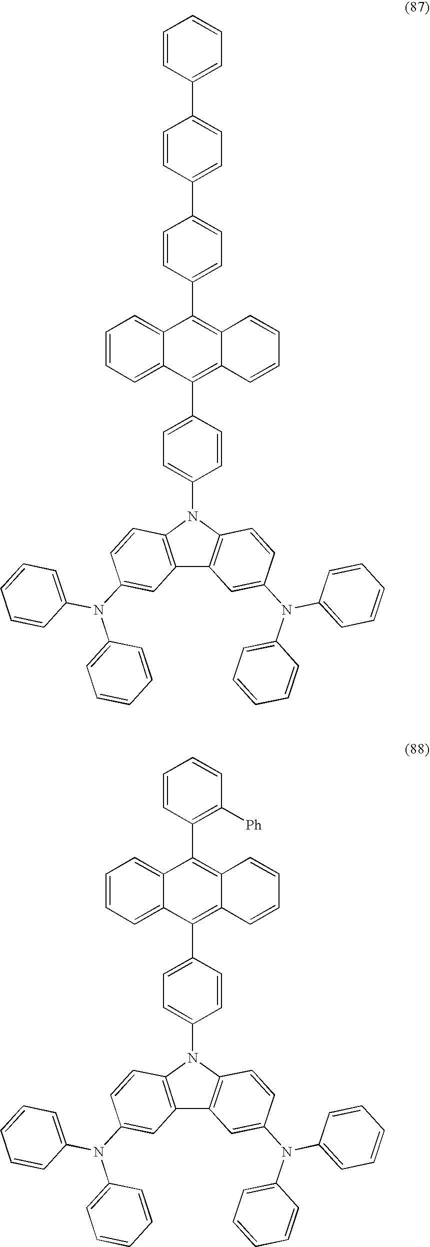

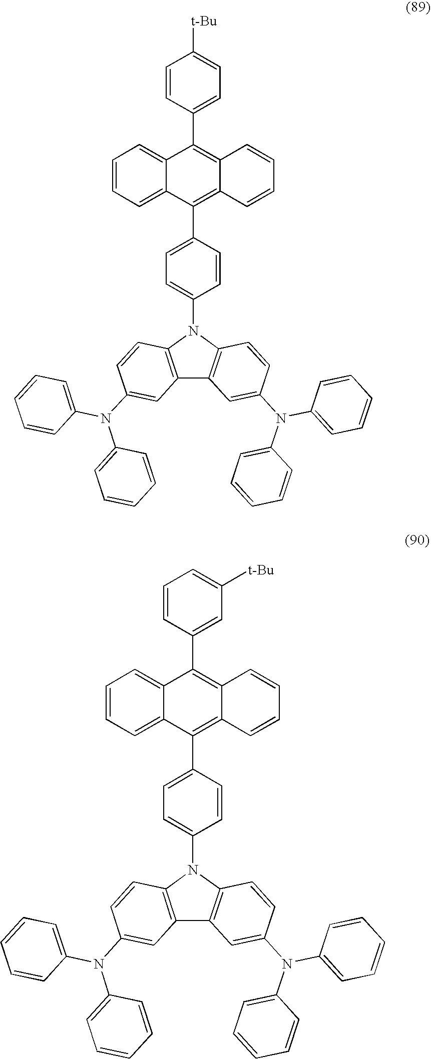

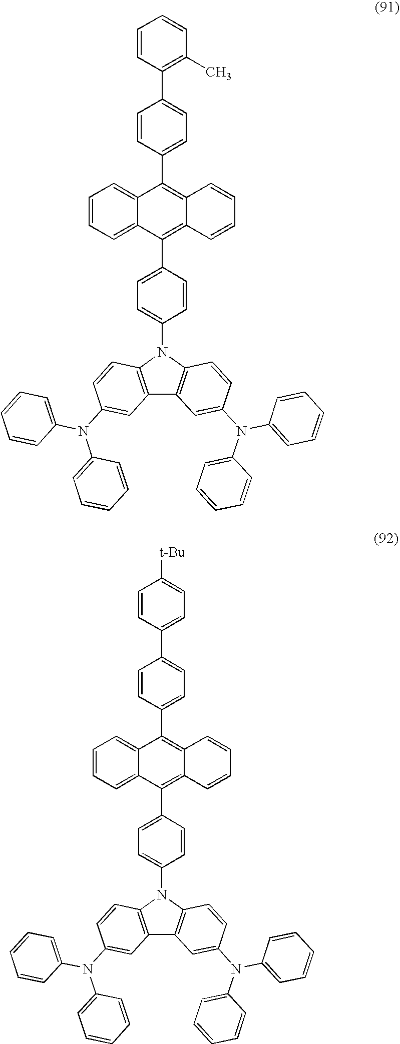

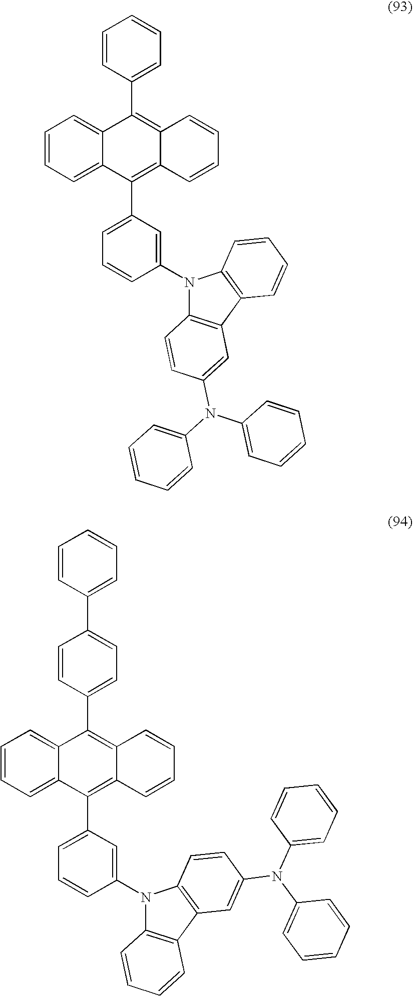

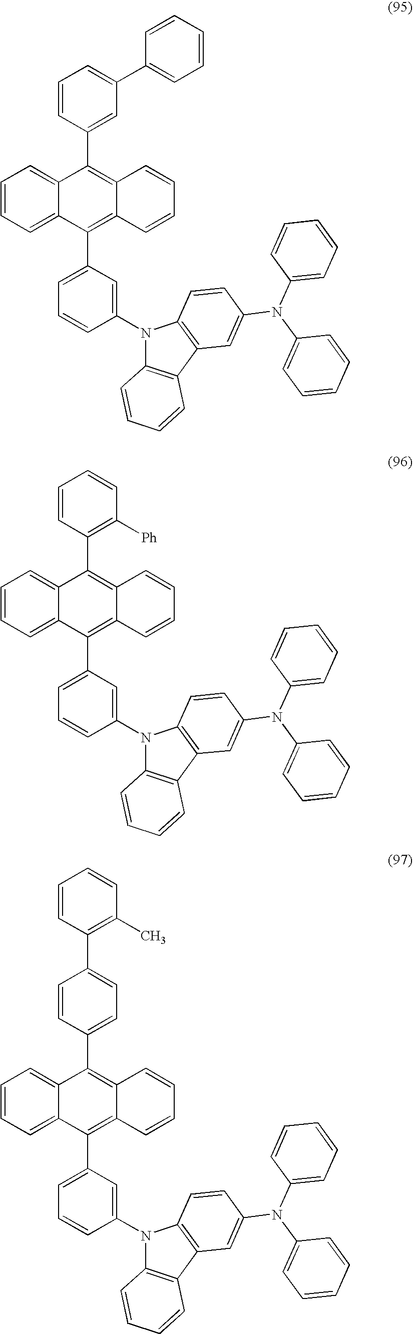

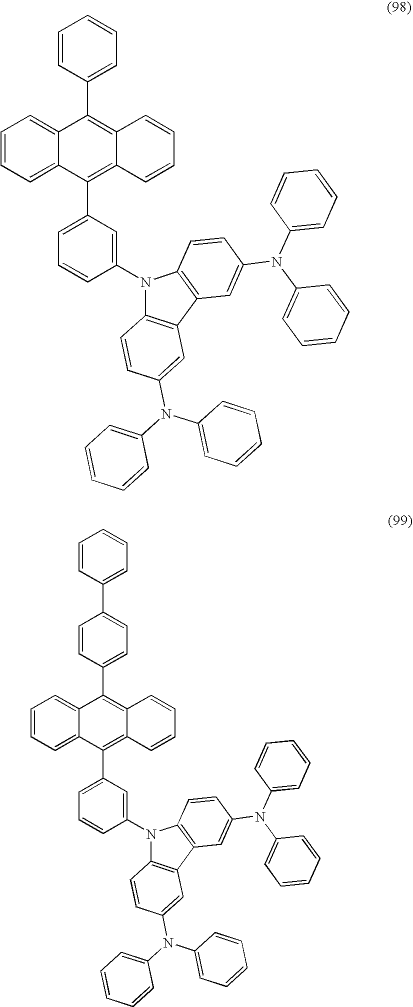

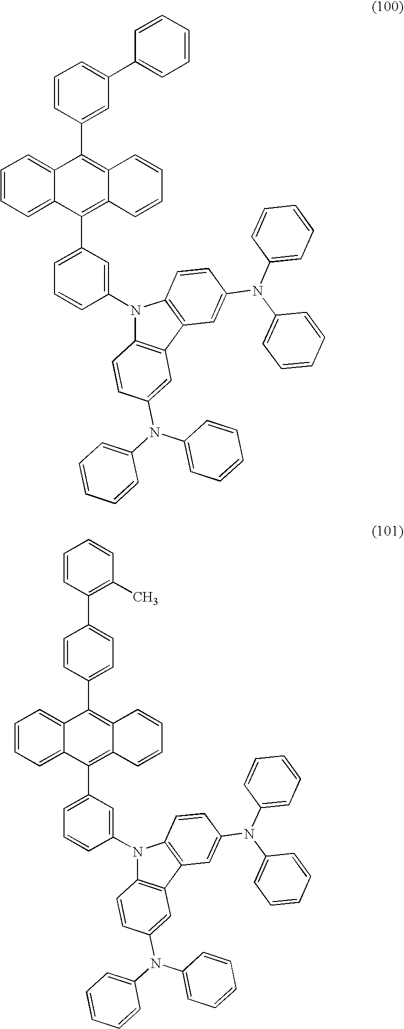

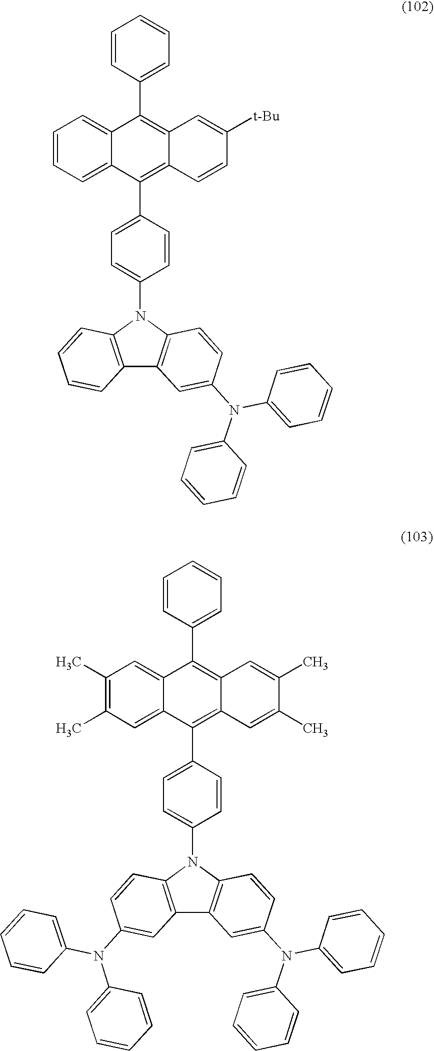

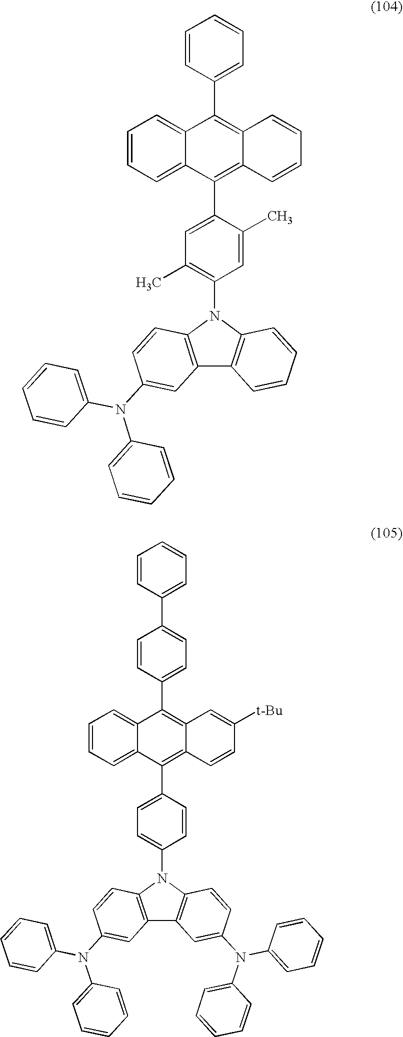

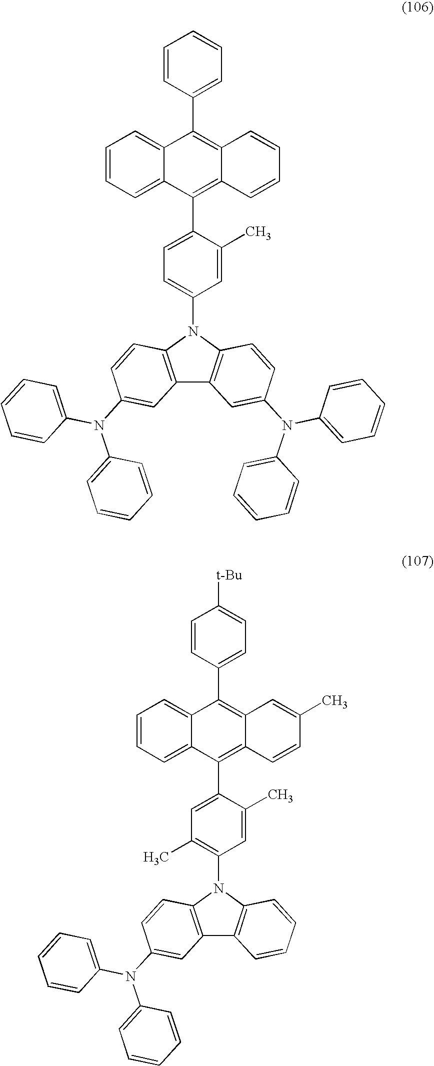

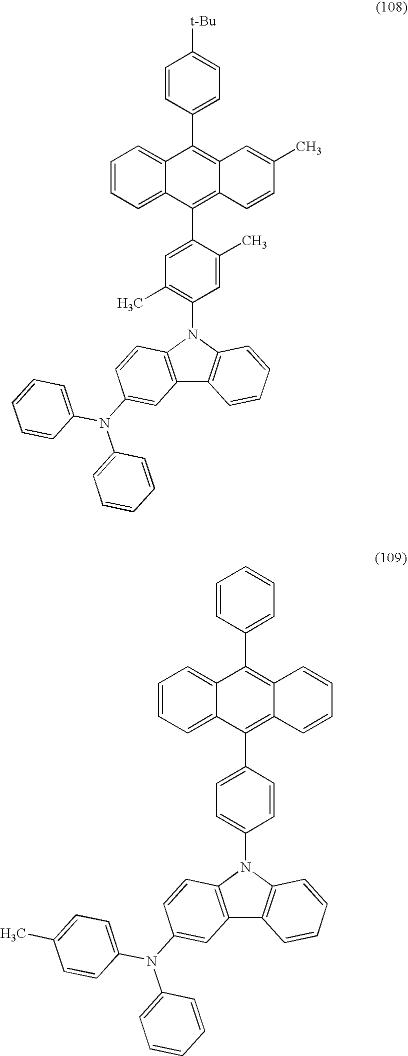

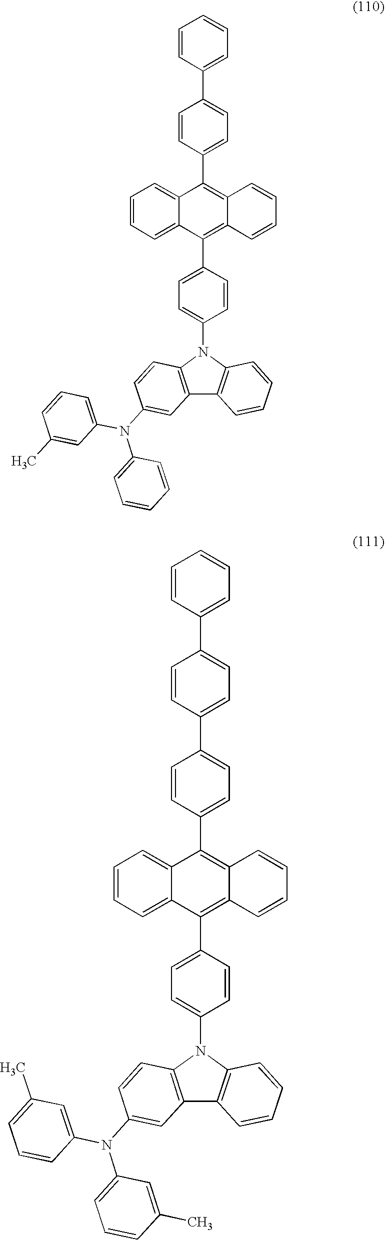

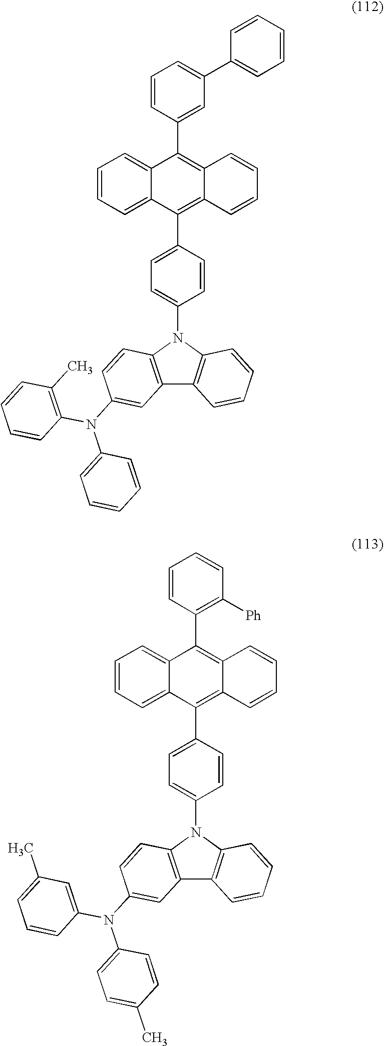

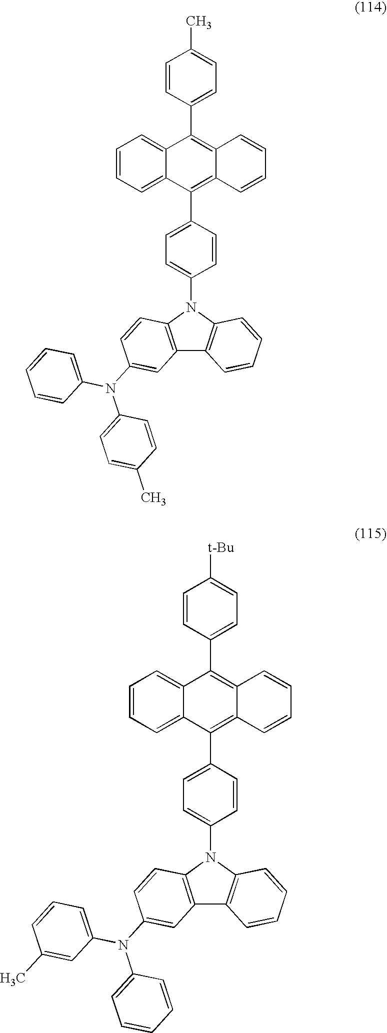

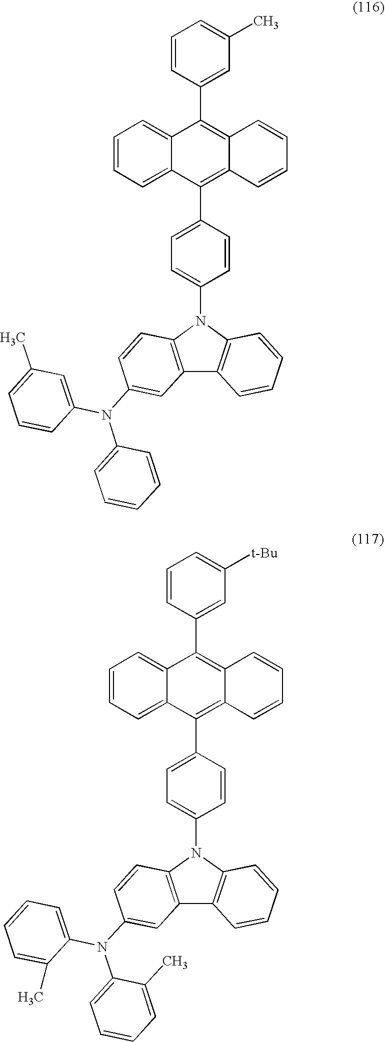

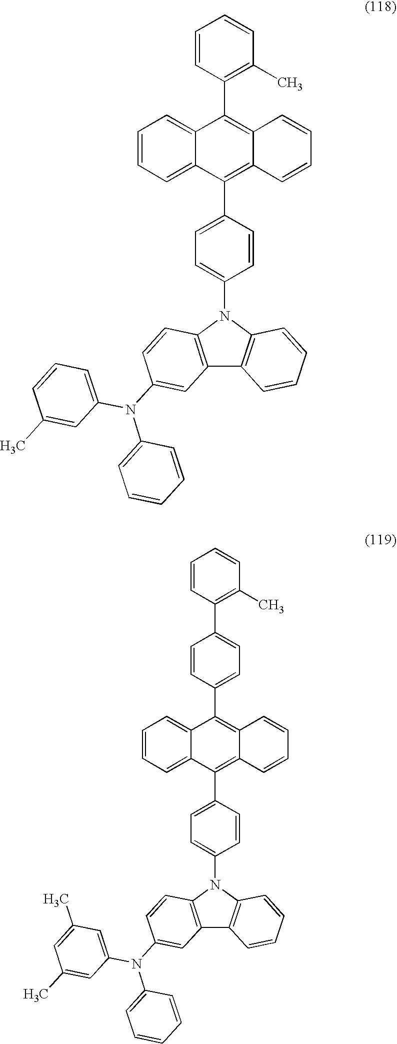

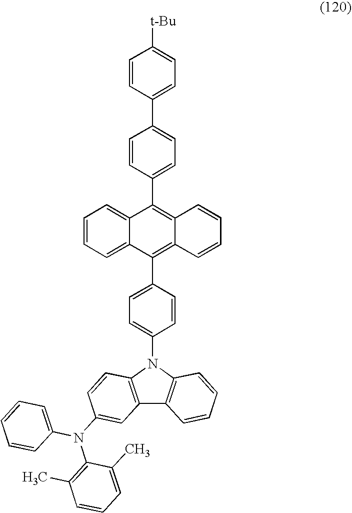

In the above-described compositions, a variety of solvents can be used as the solvent. For example, the anthracene derivatives can be dissolved in solvents that have aromatic rings (e.g., a benzene ring), such as toluene, xylene, methoxybenzene (anisole), dodecylbenzene, or a mixed solvent of dodecylbenzene and tetralin. The above-described anthracene derivatives can also be dissolved in solvents that do not have aromatic rings, such as dimethylsulfoxide (DMSO), dimethylformamide (DMF), or chloroform.

Further, each composition described in this embodiment mode may also contain any other organic material. For the organic material, any of aromatic compounds or heteroaromatic compounds which are solid at room temperature can be used. For the organic material, any of low molecular weight compounds or macromolecular compounds can be used. As regards low molecular weight compounds, it is preferable to use low molecular weight compounds each of which has a substituent that increases solubility in a solvent (which may be referred to as intermediate molecular weight compounds).

Furthermore, the composition may also contain a binder in order to improve film properties of a film that is to be formed. For the binder, it is preferable to use any of macromolecular compounds which are electrically inert. Specifically, polymethylmethacrylate (abbreviated to PMMA), polyimide, or the like can be used.

A thin film can be formed by a wet process with the use of a liquid composition of the present invention in which an anthracene derivative is dissolved in a solvent. In the wet process, a material that is to form a thin film is dissolved in the solvent, and the liquid composition is attached to a region where the layer is to be formed, the solvent is removed, and the resulting material is solidified, whereby the thin film is formed.

For the wet process, any of the following methods can be employed: a spin coating method, a roll coat method, a spray method, a casting method, a dipping method, a droplet discharging (ejection) method (an inkjet method), a dispenser method, a variety of printing methods (a method by which a thin film can be formed in a desired pattern, such as screen (stencil) printing, offset (planographic) printing, letterpress printing, or gravure (intaglio) printing, or the like. It is to be noted that the compositions of the present invention can be used as long as a method in which a liquid composition is used is employed without limitation to the above methods.

In a wet process, compared with a dry process such as an evaporation method or a sputtering method, a material is not scattered in a chamber, and therefore, material use efficiency is higher. Furthermore, facilities needed for a vacuum apparatus and the like can be reduced because the formation can be performed at atmospheric pressure. Further still, since the size of a substrate that is to be processed is not limited by the size of a vacuum chamber, it is possible to respond to use of a larger substrate to increase a processing area, whereby low cost and an improvement of productivity can be achieved. A wet process requires only heat treatment at about temperature at which a solvent of a composition can be removed, and thus is a so-called low temperature process. Therefore, it is possible to use even substrates and materials that can be degraded or deteriorated by heat treatment at high temperature.

Furthermore, since a liquid composition having fluidity is used for the formation, materials can be easily mixed. For example, an emission color that is to be obtained can be controlled by addition of a plurality of dopants to a composition. Further still, good coverage with respect to a region on which the thin film is formed can also be achieved.

The thin film can be selectively formed by a droplet discharging method in which a composition can be discharged into a desired pattern, a printing method in which a composition can be transferred or drawn into a desired pattern, or the like. Therefore, a loss of a material is further prevented, and a material can be efficiently used, resulting in a reduction in manufacturing cost. Furthermore, such methods do not require shaping of the thin film by a photolithography process, and thus have the effects of simplifying the process and improving the productivity.

A thin film formed by a wet process with the use of any of the compositions of this embodiment mode, in which an anthracene derivative is dissolved in a solvent, can be made to have favorable film properties without defects or the like. Thus, with the use of such a composition and a thin film, a highly reliable light-emitting element (device) can be fabricated.

In this embodiment mode, since a wet process is employed for fabrication of a thin film and a light-emitting element, high material utilization efficiency and a reduction in expensive facilities such as a large vacuum apparatus can be achieved, resulting in a cost reduction and a productivity improvement. Thus, a light-emitting device and an electronic device that are highly reliable can be manufactured while achieving a cost reduction and a productivity improvement.

### Embodiment Mode 2

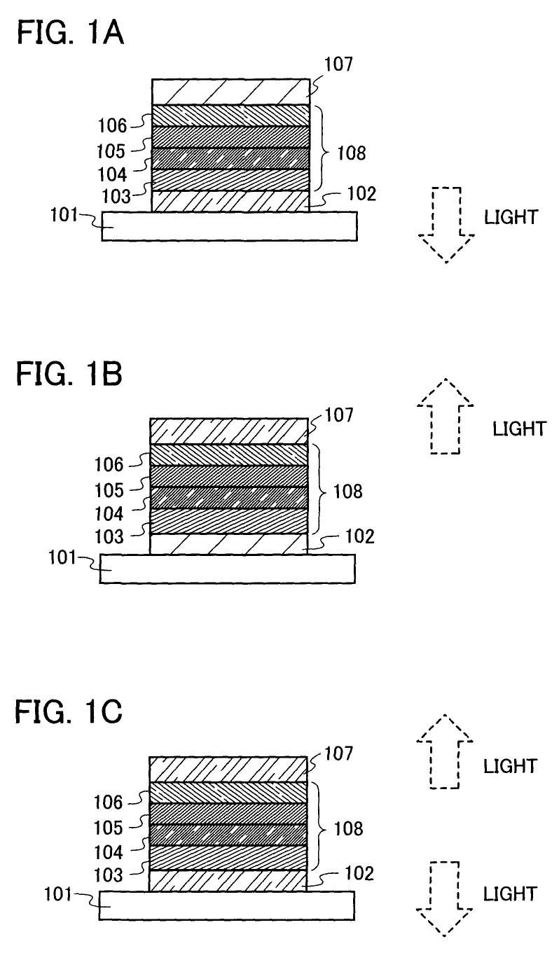

One mode of a light-emitting element having a thin film formed by a wet process with the use of any of the compositions of the present invention which contains an anthracene derivative and a solvent is described below using FIG. 1A.

In the light-emitting element of the present invention, an EL layer containing at least a layer that contains a light-emitting substance (also referred to as a light-emitting layer) is interposed between a pair of electrodes. The EL layer may also have a plurality of layers in addition to the layer that contains a light-emitting substance. The plurality of layers is a combination of layers formed of a substance with a high carrier-injecting property and a substance with a high carrier-transporting property, which are stacked so that a light-emitting region is formed in a region away from the electrodes, that is, so that the carriers are recombined in an area away from the electrodes. In this specification, the layer formed of a substance with a high carrier-injecting property or a substance with a high carrier-transporting property is also referred to as a functional layer functioning to inject or transport carriers or the like. For the functional layer, it is possible to use a layer containing a substance with a high hole-injecting property (also referred to as a hole-injecting layer), a layer containing a substance with a high hole-transporting property (also referred to as a hole-transporting layer), a layer containing a substance with a high electron-injecting property (also referred to as an electron-injecting layer), a layer containing a substance with a high electron-transporting property (also referred to as an electron-transporting layer), and the like.

In the present invention, the layer that contains a light-emitting substance is formed by a wet process with the use of a liquid composition in which a light-emitting substance is dissolved in a solvent (any of the compositions described in Embodiment Mode 1 containing an anthracene derivative and a solvent). In the wet process, a material that is to form a thin film is dissolved in the solvent, and the liquid composition is attached to a region where the layer is to be formed, the solvent is removed, and the resulting material is solidified, whereby the thin film is formed. In this specification, a film formed by a wet process, which is described as a film, may be extremely thin depending on its formation conditions, and the film does not necessarily maintain the form of a film; for example, it may have a discontinuous island structure or the like.

For the wet process, any of the following methods can be employed: a spin coating method, a roll coat method, a spray method, a casting method, a dipping method, a droplet discharging (ejection) method (an inkjet method), a dispenser method, a variety of printing methods (a method by which a thin film can be formed in a desired pattern, such as screen (stencil) printing, offset (planographic) printing, letterpress printing, or gravure (intaglio) printing, or the like. It is to be noted that the compositions of the present invention can be used as long as a method in which a liquid composition is used is employed without limitation to the above methods.

In a wet process, compared with a dry process such as an evaporation method or a sputtering method, a material is not scattered in a chamber, and therefore, material use efficiency is higher. Furthermore, facilities needed for a vacuum apparatus and the like can be reduced because the formation can be performed at atmospheric pressure. Further still, since the size of a substrate that is to be processed is not limited by the size of a vacuum chamber, it is possible to respond to use of a larger substrate to increase a processing area, whereby low cost and an improvement of productivity can be achieved. A wet process requires only heat treatment at about temperature at which a solvent of a composition can be removed, and thus is a so-called low temperature process. Therefore, it is possible to use even substrates and materials that can be degraded or deteriorated by heat treatment at high temperature.

Furthermore, since a liquid composition having fluidity is used for the formation, materials can be easily mixed. For example, an emission color that is to be obtained can be controlled by addition of a plurality of dopants to a composition. Further still, good coverage with respect to a region on which the thin film is formed can also be achieved.

The thin film can be selectively formed by a droplet discharging method in which a composition can be discharged into a desired pattern, a printing method in which a composition can be transferred or drawn into a desired pattern, or the like. Therefore, a loss of a material is further prevented, and a material can be efficiently used, resulting in a reduction in manufacturing cost. Furthermore, such methods do not require shaping of the thin film by a photolithography process, and thus have the effects of simplifying the process and improving the productivity.

A first electrode, a second electrode, and the functional layers (such as the hole-injecting layer, the hole-transporting layer, the electron-injecting layer, or the electron-transporting layer) which are included in a light-emitting element may be formed by any of the above wet processes such as an inkjet method, a spin coating method, or a printing method, or by a dry process such as a vacuum evaporation method, a CVD method, or a sputtering method. The use of a wet process as described above enables the formation at atmospheric pressure using a simple device and process, and thus has the effects of simplifying the process and improving the productivity. In contrast, in a dry process, dissolution of a material is not needed, and thus, a material that has low solubility in a solution can be used to expand the range of material choices.

A method of forming each electrode or each functional layer may be determined depending on a material that is to be used or the order of the stacking as appropriate. For a wet process in which a solvent is used, it is necessary to use a combination of the materials such that a lower thin film, which is a surface on which another film is to be formed, has low solubility in the solvent.

In a light-emitting element of this embodiment mode shown in each of FIGS. 1A to 1C, an EL layer 108 is provided between a first electrode 102 and a second electrode 107. The EL layer 108 has a first layer 103, a second layer 104, a third layer 105, and a fourth layer 106. In the light-emitting element of each of FIGS. 1A to 1C, the first electrode 102 is formed over a substrate 101; the first layer 103, the second layer 104, the third layer 105, and the fourth layer 106 are stacked over the first electrode 102 in this order; and a second electrode 107 is provided thereover. In the description below, it is assumed that the first electrode 102 functions as an anode and the second electrode 107 functions as a cathode in this embodiment mode.

The substrate 101 is used as a base of the light-emitting element. For the substrate 101, glass, quartz, plastic, or the like may be used, for example. Alternatively, a flexible substrate can be used. The flexible substrate is a substrate that can be bent, such as a plastic substrate made of polycarbonate, polyarylate, or polyether sulfone, for example. In addition, a film (made of polypropylene, polyester, vinyl, polyvinyl fluoride, vinyl chloride, or the like), or an inorganic evaporated film can also be used. However, any material other than these may be used as long as the material functions as a base of the light-emitting element.

It is preferred that the first electrode 102 be formed using any of metals, alloys, and conductive compounds with a high work function (specifically, 4.0 eV or higher), a mixture thereof, or the like. Specifically, indium tin oxide (ITO), indium tin oxide containing silicon or silicon oxide, indium zinc oxide (IZO), indium oxide containing tungsten oxide and zinc oxide (IWZO), or the like can be used. Such conductive metal oxide films are typically formed by sputtering, but may also be formed by application of a sol-gel method or the like. For example, an indium zinc oxide (IZO) film can be formed using a target in which 1 wt % to 20 wt % of zinc oxide is added to indium oxide by a sputtering method. A film of indium oxide containing tungsten oxide and zinc oxide (IWZO) can be formed using a target in which 0.5 wt % to 5 wt % of tungsten oxide and 0.1 wt % to 1 wt % of zinc oxide are added to indium oxide by a sputtering method. Alternatively, gold (Au), platinum (Pt), nickel (Ni), tungsten (W), chromium (Cr), molybdenum (Mo), iron (Fe), cobalt (Co), copper (Cu), palladium (Pd), nitride of a metal material (e.g., titanium nitride), or the like can be used.

A first layer 103 is a layer that contains a substance having a high hole-injecting property, and molybdenum oxide, vanadium oxide, ruthenium oxide, tungsten oxide, manganese oxide, or the like can be used. Alternatively, the first layer 103 can be formed using any of the following materials: phthalocyanine compounds such as phthalocyanine (abbreviated to H₂Pc) and copper phthalocyanine (CuPc), aromatic amine compounds such as 4,4′-bis[N-(4-diphenylaminophenyl)-N-phenylamino]biphenyl (abbreviated to DPAB) and 4,4′-bis(N-{4-[N-(3-methylphenyl)-N-phenylamino]phenyl}-N-phenylamino)biphenyl (abbreviated to DNTPD), macromolecular compounds such as poly(3,4-ethylenedioxythiophene)/poly(styrenesulfonic acid) (abbreviated to PEDOT/PSS), and the like.

Alternatively, a composite material formed by composing an organic compound and an inorganic compound can be used for the first layer 103. In particular, a composite material containing an organic compound and an inorganic compound having an electron accepting property with respect to the organic compound has an excellent hole-injecting property and hole-transporting property because the electrons are transported between the organic compound and the inorganic compound to increase the carrier density.

In the case of using the composite material formed by composing an organic compound and an inorganic compound for the first layer 103, the first layer 103 can achieve an ohmic contact with the first electrode 102; therefore, a material of the first electrode can be selected regardless of the work function.

As the inorganic compound used for the composite material, an oxide of a transition metal is preferably used. Moreover, an oxide of metals belonging to Groups 4 to 8 of the periodic table can be used. Specifically, vanadium oxide, niobium oxide, tantalum oxide, chromium oxide, molybdenum oxide, tungsten oxide, manganese oxide, or rhenium oxide is preferably used because of their high electron accepting properties. In particular, use of molybdenum oxide is more preferable because of its stability in the atmosphere, a low hygroscopic property, and easily handling.

As the organic compound used for the composite material, any of a variety of compounds such as aromatic amine compounds, carbazole derivatives, aromatic hydrocarbons, macromolecular compounds (such as oligomers, dendrimers, or polymers), or the like can be used. It is to be noted that an organic compound having a high hole-transporting property is preferably used as the organic compound used for the composite material. Specifically, use of a substance having a hole mobility of greater than or equal to 10⁻⁶ cm²/(V·s) is preferable. However, any substance other than the above substances may also be used as long as it is a substance in which the hole-transporting property is higher than the electron-transporting property. The organic compounds each of which can be used for the composite material are described in specific terms below.

Examples of the aromatic amine compounds include N,N′-di(p-tolyl)-N,N′-diphenyl-p-phenylenediamine (abbreviated to DTDPPA), 4,4′-bis[N-(4-diphenylaminophenyl)-N-phenylamino]biphenyl (abbreviated to DPAB), 4,4′-bis(N-{4-[N-(3-methylphenyl)-N-phenylamino]phenyl}-N-phenylamino)biphenyl (abbreviated to DNTPD), 1,3,5-tris[N-(4-diphenylaminophenyl)-N-phenylamino]benzene (abbreviated to DPA3B), and the like.

Specific examples of the carbazole derivatives each of which can be used for the composite material include 3-[N-(9-phenylcarbazol-3-yl)-N-phenylamino]-9-phenylcarbazole (abbreviated to PCzPCA1); 3,6-bis[N-(9-phenylcarbazol-3-yl)-N-phenylamino]-9-phenylcarbazole (abbreviated to PCzPCA2), 3-[N-(1-naphtyl)-N-(9-phenylcarbazol-3-yl)amino]-9-phenylcarbazole (abbreviated to PCzPCN1), and the like.

Alternatively, 4,4′-di(N-carbazolyl)biphenyl (abbreviated to CBP), 1,3,5-tris[4-(N-carbazolyl)phenyl]benzene (abbreviated to TCPB), 9-[4-(N-carbazolyl)]phenyl-10-phenylanthracene (abbreviated to CzPA), 1,4-bis[4-(N-carbazolyl)phenyl]-2,3,5,6-tetraphenylbenzene, or the like can be used.

Examples of the aromatic hydrocarbons each of which can be used for the composite material include 2-tert-butyl-9,10-di(2-naphthyl)anthracene (abbreviated to t-BuDNA), 2-tert-butyl-9,10-di(1-naphthyl)anthracene, 9,10-bis(3,5-diphenylphenyl)anthracene (abbreviated to DPPA), 2-tert-butyl-9,10-bis(4-phenylphenyl)anthracene (abbreviated to t-BuDBA), 9,10-di(2-naphthyl)anthracene (abbreviated to DNA), 9,10-diphenylanthracene (abbreviated to DPAnth), 2-tert-butylanthracene (abbreviated to t-BuAnth), 9,10-bis(4-methyl-1-naphthyl)anthracene (abbreviated to DMNA), 2-tert-butyl-9,10-bis[2-(1-naphthyl)phenyl]anthracene, 9,10-bis[2-(1-naphthyl)phenyl]anthracene, 2,3,6,7-tetramethyl-9,10-di(1-naphthyl)anthracene, 2,3,6,7-tetramethyl-9,10-di(2-naphthyl)anthracene, 9,9′-bianthryl, 10,10′-diphenyl-9,9′-bianthryl, 10,10′-bis(2-phenylphenyl)-9,9′-bianthryl, 10,10′-bis[(2,3,4,5,6-pentaphenyl)phenyl]-9,9′-bianthryl, anthracene, tetracene, rubrene, perylene, 2,5,8,11-tetra(tert-butyl)perylene, and the like. Besides these compounds, pentacene, coronene, or the like can also be used. In particular, use of an aromatic hydrocarbon that has a hole mobility of greater than or equal to 1×10⁻⁶ cm²/(V·s) and has 14 to 42 carbon atoms is more preferable.

It is to be noted that the aromatic hydrocarbons each of which can be used for the composite material may have a vinyl skeleton. Examples of the aromatic hydrocarbons having a vinyl skeleton include 4,4′-bis(2,2-diphenylvinyl)biphenyl (abbreviated to DPVBi), 9,10-bis[4-(2,2-diphenylvinyl)phenyl]anthracene (abbreviated to DPVPA), and the like.

A macromolccular compound such as poly(N-vinylcarbazole) (abbreviated to PVK) or poly(4-vinyltriphenylamine) (abbreviated to PVTPA) can also be used.

As a substance forming the second layer 104, a substance having a high hole-transporting property, specifically, an aromatic amine compound (that is, a compound having a benzene ring-nitrogen bond) is preferably used. As a material that is widely used, 4,4′-bis[N-(3-methylphenyl)-N-phenylamino]biphenyl, derivatives thereof such as 4,4′-bis[N-(1-napthyl)-N-phenylamino]biphenyl (hereinafter referred to as NPB), and star burst aromatic amine compounds such as 4,4′,4″-tris(N,N-diphenyl-amino)triphenylamine, and 4,4′,4″-tris[N-(3-methylphenyl)-N-phenylamino]triphenylamine are given. These materials described here mainly are substances having a hole mobility of greater than or equal to 10⁻⁶ cm²/(V·s). However, any substance other than the above substances may also be used as long as it is a substance in which the hole-transporting property is higher than the electron-transporting property. The second layer 104 may be a single layer, a mixed layer of the aforementioned substances, or a layer formed of two or more layers stacked together.

The third layer 105 is a layer that contains a light-emitting substance. In this embodiment mode, the third layer 105 is formed using any of the compositions described in Embodiment Mode 1. Specifically, any of the compositions described in Embodiment Mode 1 may be applied by a wet process (e.g., a droplet discharging method (an inkjet method), a spin coating method, a printing method), and then, the solvent is removed. For removing the solvent, a heat treatment, a low pressure treatment, a heat treatment under low pressure, and the like are given. The use of a wet process enables an improvement of material use efficiency and a reduction in manufacturing cost of a light-emitting element. The anthracene derivative contained in the thin film formed using any of the compositions of the present invention emits blue light, and thus can be preferably used as a light-emitting substance for a light-emitting element.

Alternatively, for the third layer 105, any of the compositions of the present invention which contains an anthracene derivative and a solvent can also be used as a host. Light emission from a dopant that is to serve as a light-emitting substance can be obtained with a structure in which the dopant that is to serve as a light-emitting substance is dispersed in the composition of the present invention which contains an anthracene derivative and a solvent.

When the anthracene derivative in any of the compositions of the present invention is used as a material in which another light-emitting substance is dispersed, an emission color depending on the light-emitting substance can be obtained. Further, it is also possible to obtain an emission color that is a mixture of the emission color depending on the anthracene derivative in any of the compositions of the present invention and the emission color depending on the light-emitting substance dispersed in the anthracene derivative.

In this case, any of a variety of materials can be used as the light-emitting substance dispersed in the anthracene derivative of the present invention. Specifically, fluorescent substances that emit fluorescence, such as 9,10-diphenyl-2-[N-phenyl-N-(9-phenyl-9H-carbazol-3-yl)amino]anthracene (abbreviated to 2PCAPA), 4-(dicyanomethylene)-2-methyl-6-(p-dimethylaminostyryl)-4H-pyran (abbreviated to DCM1), 4-(dicyanomethylene)-2-methyl-6-(julolidin-4-yl-vinyl)-4H-pyran (abbreviated to DCM2), N,N-dimethylquinacridone (abbreviated to DMQd), rubrene N,N′-bis[4-(9H-carbazol-9-yl)phenyl]-N,N′-diphenylstilbene-4,4′-diamine (abbreviated to YGA2S), or 4-(9H-carbazol-9-yl)-4′-(10-phenyl-9-anthryl)triphenylamine (abbreviated to YGAPA) can be used. Alternatively, phosphorescent substances that emit phosphorescence, such as (acetylacetonato)bis[2,3-bis(4-fluorophenyl)quinoxalinato]iridium(III) (abbreviated to Ir(Fdpq)₂(acac)) or (2,3,7,8,12,13,17,18-octaethyl-21H,23H-porphyrinato)platinum(II) (abbreviated to PtOEP) can also be used.

For the fourth layer 106, a substance having a high electron-transporting property can be used. For example, metal complexes having a quinoline or benzoquinoline skeleton, such as tris(8-quinolinolato)aluminum (abbreviated to Alq), tris(4-methyl-8-quinolinolato)aluminum (abbreviated to Almq₃), bis(10-hydroxybenzo[h]quinolinato)beryllium (abbreviated to BeBq₂), or bis(2-methyl-8-quinolinolato)(4-phenylphenolato)aluminum (abbreviated to BAlq) or the like can be used. Alternatively, metal complexes having an oxazole-based or thiazole-based ligand, such as bis[2-(2-hydroxyphenyl)benzoxazolato]zinc (abbreviated to Zn(BOX)₂) or bis[2-(2-hydroxyphenyl)-benzothiazolato]zinc (abbreviated to Zn(BTZ)₂) or the like can be used. In stead of the metal complexes, 2-(4-biphenylyl)-5-(4-tert-butylphenyl)-1,3,4-oxadiazole (abbreviated to PBD), 1,3-bis[5-(p-tert-butylphenyl)-1,3,4-oxadiazol-2-yl]benzene (abbreviated to OXD-7), 3-(4-biphenylyl)-4-phenyl-5-(4-tert-butylphenyl)-1,2,4-triazole (abbreviated to TAZ), bathophenanthroline (abbreviated to BPhen), bathocuproine (abbreviated to BCP), or the like can also be used. The substances described here are substances each having an electron mobility of greater than or equal to 10⁻⁶ cm²/(V·s). It is to be noted that any substance other than the above substances may also be used as long it is a substance in which the electron-transporting property is higher than the hole-transporting property. Furthermore, the electron-transporting layer is not limited to a single layer and may be a stack of two or more layers each containing the aforementioned substance.

Further, a layer having a function of promoting electron injection (an electron-injecting layer) may be provided between the forth layer 106 and the second electrode 107. For the layer having a function of promoting electron injection, an alkali metal, an alkaline earth metal, or a compound thereof, such as lithium fluoride (LiF), cesium fluoride (CsF), or calcium fluoride (CaF₂) can be used. A layer in which an alkali metal, an alkaline earth metal, or a compound thereof is contained in a substance with an electron-transporting property, such as a layer in which magnesium (Mg) is contained in Alq, can be used. It is to be noted that the use of such a layer as an electron-injecting layer is advantageous because electron injection from the second electrode 107 proceeds efficiently.

The second electrode 107 can be formed using any of metals, alloys, and conductive compounds with a low work function (specifically, 3.8 eV or lower), a to mixture of them, or the like. Specific examples of such cathode materials include elements belonging to Group 1 and Group 2 of the periodic table, that is, alkali metals such as lithium (Li) and cesium (Cs) and alkaline earth metals such as magnesium (Mg), calcium (Ca), and strontium (Sr); alloys of them (e.g., MgAg and AlLi); rare earth metals such as europium (Eu) and ytterbium (Yb), alloys of them; and the like. However, when the layer having a function of promoting electron injection is provided between the second electrode 107 and the electron-transporting layer to be stacked with this second electrode 107, any of a variety of conductive materials such as Al, Ag, ITO, and ITO containing silicon or silicon oxide can be used for the second electrode 107 regardless of its work function.

Further, the anthracene derivative contained in any of the compositions of the present invention can be used for the functional layer of the light-emitting element. The anthracene derivative in which at least one of A¹ and A² represents a diarylamino group in the above general formula (1) enables the functional layer containing the anthracene derivative to function as a hole-transporting layer or a hole-injecting layer, and accordingly the anthracene derivative can be used for the first layer 103 or the second layer 104. The anthracene derivative in which both A¹ and A² do not represent a diarylamino group in the above general formula (1) enables the functional layer containing the anthracene derivative to function as an electron-transporting layer or an electron-injecting layer, and accordingly, the anthracene derivative can be used for the fourth layer 106. Thus, the functional layers (the first layer 103, the second layer 104, and the fourth layer 106) of the light-emitting element can be formed by a wet process using any of the compositions of the present invention which contains an anthracene derivative and a solvent. Furthermore, when the functional layers are formed by a wet process using any of the compositions of the present invention which contains an anthracene derivative and a solvent, the third layer 105 containing a light-emitting substance may be formed using any other phosphor by a dry process such as an evaporation method.

For the formation of the first layer 103, the second layer 104, the third layer 105, and the fourth formation method of layer 106, any of a variety of methods such as an evaporation method, a droplet discharging method (an inkjet method), a spin coating method, or a printing method can be employed. Further, a different deposition method can be employed for each electrode or each layer.

In the light-emitting element of the present invention having the structure as described above, the potential difference generated between the first electrode 102 and the second electrode 107 makes a current flow, whereby holes and electrons are recombined in the third layer 105 that is a layer containing a high light-emitting property and thus light is emitted. That is, a light-emitting region is formed in the third layer 105.

Light is extracted outside through one or both of the first electrode 102 and the second electrode 107. Thus, one or both of the first electrode 102 and the second electrode 107 are light-transmissive electrodes. When only the first electrode 102 is a light-transmissive electrode, light is extracted from the substrate side through the first electrode 102. In contrast, when only the second electrode 107 is a light-transmissive electrode, light is extracted from a side opposite to the substrate side through the second electrode 107. When both the first electrode 102 and the second electrode 107 are light-transmissive electrodes, light is extracted from both the substrate side and the side opposite to the substrate side through the first electrode 102 and the second electrode 107.

It is to be noted that the structure of the layers provided between the first electrode 102 and the second electrode 107 is not limited to the above structure and may be any structure as long as the light-emitting region for recombination of holes and electrons is positioned away from the first electrode 102 and the second electrode 107 so as to suppress quenching by the light-emitting region being close to a metal.

That is, there is no particular limitation on the stacked structure of the layers. It is acceptable as long as the light-emitting layer containing any of the compositions of the present invention is freely combined with the layers each containing a substance with a high electron-transporting property, a substance with a high hole-transporting property, a substance with a high electron-injecting property, a substance with a high hole-injecting property, a bipolar substance (a substance with a high electron-transporting and hole-transporting property), a hole-blocking material, or the like.

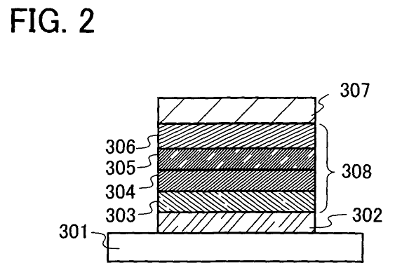

In a light-emitting element shown in FIG. 2, an EL layer 308 is provided between a first electrode 302 and a second electrode 307 over a substrate 301. The EL layer 308 has a first layer 303 that contains a substance with a high electron-transporting property, a second layer 304 that contains a light-emitting substance, a third layer 305 that contains a substance with a high hole-transporting property, and a fourth layer 306 that contains a substance with high hole-injecting property. The first electrode 302 that is to function as a cathode, the first layer 303 formed of a substance with a high electron-transporting property, the second layer 304 that contains a light-emitting substance, the third layer 305 formed of a substance with a high hole-transporting property, the fourth layer 306 formed of a substance with high hole-injecting property, and the second electrode 307 that is to function as an anode are stacked in this order.

It is to be note that, when the light-emitting element described in this embodiment mode is applied to a display device and layers containing a light-emitting substance are formed separately for each color, it is preferred that they be selectively formed by a wet process. The use of a droplet discharging method makes it easier to form the layers containing a light-emitting substance separately for each color even if a large substrate is employed, whereby the productivity is improved.

Hereinafter, a method of fabricating a light-emitting element is described in specific terms.

In the light-emitting element of the present invention, an EL layer is interposed between a pair of electrodes. The EL layer includes at least a layer that contains a light-emitting substance (also referred to as a light-emitting layer) formed using any of the compositions of the present invention by a wet process. Furthermore, the EL layer may include a functional layer (e.g., a hole-injecting layer, a hole-transporting layer, an electron-transporting layer, or an electron-injecting layer). Each electrode (the first electrode or the second electrode) and each functional layer may be formed by any of the above wet processes such as a droplet discharging method (an inkjet method), a spin coating method, or a printing method, or by a dry process such as a vacuum evaporation method, a CVD method, or a sputtering method. The use of a wet process as described above enables the formation at atmospheric pressure using a simple device and process, and thus has the effects of simplifying the process and improving the productivity. In contrast, in a dry process, dissolution of a material is not needed, and thus, a material that has low solubility in a solution can be used to expand the range of material choices.

The layer containing a light-emitting substance is formed by a wet process using any of the compositions of the present invention, and thus, all the thin films included in the light-emitting element may be formed by a wet process. In this case, the light-emitting element can be fabricated with only facilities needed for a wet process. Alternatively, the stacked layers to the layer containing a light-emitting substance may be formed by a wet process whereas the functional layer, the second electrode, or the like which are stacked over the layer containing a light-emitting substance may be formed by a dry process. Further alternatively, the first electrode and the functional layers may be formed by a dry process before the formation of the layer containing a light-emitting substance whereas the layer containing a light-emitting substance, the functional layer stacked thereover, and the second electrode may be formed by a wet process. Naturally, the present invention is not limited to such a method, and the light-emitting element can be fabricated by appropriate selection from a wet process and a dry process depending on a material that is to be used, necessary film thickness, and the interface state.

One example is described below. Over a first electrode, PEDOT/PSS is used for forming a hole-injecting layer. An aqueous solution of PEDOT/PSS can be used for the formation by a spin coating method, an inkjet method, or the like because PEDOT/PSS is water-soluble. A hole-transporting layer is not provided, and a layer containing a light-emitting substance is provided over the hole-injecting layer. The layer containing a light-emitting substance can be formed by an inkjet method with the use of any of the compositions described in Embodiment Mode 1 which contains a solvent in which the hole-injecting layer (formed of PEDOT/PSS) which has been already formed does not dissolve, (e.g., a solvent having an aromatic ring (e.g., a benzene ring) such as toluene, xylene, methoxybenzene (anisole), dodecylbenzene, a mixed solvent of dodecylbenzene and tetralin; or an organic solvent not having an aromatic ring, such as dimethylsulfoxide (DMSO), dimethylformamide (DMF), or chloroform). Next, an electron-transporting layer is formed over the layer containing a light-emitting substance. If the electron-transporting layer is formed by a wet process, it need be formed using a solvent in which the hole-injecting layer and the layer containing a light-emitting substance which have been already formed do not dissolve. In that case, the range of solvent choices is narrowed, and accordingly, the formation by a dry process is easier. Thus, when the formation of the electron-transporting layer to the second electrode is performed in vacuum consistently by a vacuum evaporation method, the process can be simplified.

In this embodiment mode, the light-emitting element is fabricated over a substrate made of glass, plastic, or the like. When a plurality of such light-emitting elements is fabricated over one substrate, a passive matrix light-emitting device can be manufactured. Alternatively, for example, a thin film transistor (TFT) is formed over a substrate made of glass, plastic, or the like, and then, a light-emitting element may be fabricated over an electrode that is electrically connected to the TFT. Thus, an active matrix light-emitting device in which drive of the light-emitting element is controlled by the TFT can be manufactured. It is to be noted that there is no particular limitation on the structure of the TFT, and either a staggered TFT or an inversely staggered TFT may be employed. Further, there is no particular limitation on the crystallinity of a semiconductor used for forming the TFT, and an amorphous semiconductor, a crystalline semiconductor, or a single-crystal semiconductor may be used. In addition, a driver circuit formed over a TFT substrate may be formed using n-channel and p-channel TFTs, or using either n-channel or p-channel TFTs.

A thin film formed by a wet process with the use of any of the compositions of this embodiment mode, in which an anthracene derivative is dissolved in a solvent, can be made to have favorable film properties without defects or the like. Thus, with the use of such a composition and a thin film, a highly reliable light-emitting element (device) can be fabricated.

In this embodiment mode, since a wet process is employed for fabrication of a thin film and a light-emitting element, high material utilization efficiency and a reduction in expensive facilities such as a large vacuum apparatus can be achieved, resulting in a cost reduction and a productivity improvement. Thus, a light-emitting device and an electronic device that are highly reliable can be manufactured while achieving a cost reduction and a productivity improvement.

### Embodiment Mode 3

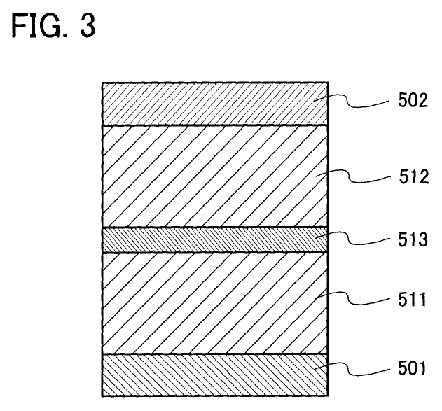

In this embodiment mode, a mode of a light-emitting element in which a plurality of light-emitting units according to the present invention is stacked (hereinafter, referred to as a stacked-type element) is described with reference to FIG. 3. The light-emitting element is a stacked-type light-emitting element including a plurality of light-emitting units between a first electrode and a second electrode.

In FIG. 3, a first light-emitting unit 511 and a second light-emitting unit 512 are stacked between a first electrode 501 and a second electrode 502. The first electrode 501 and the second electrode 502 can be similar to the electrodes described in Embodiment Mode 2. Structures of the first light-emitting unit 511 and the second light-emitting unit 512 may be the same or different from each other and can be similar to the structure described in Embodiment Mode 2.

A charge generation layer 513 contains a composite material of an organic compound and a metal oxide. The composite material of an organic compound and a metal oxide is described in Embodiment Modes 2 or 5 and contains an organic compound and a metal oxide such as vanadium oxide, molybdenum oxide, or tungsten oxide. As the organic compound, a variety of compounds such as aromatic amine compounds, carbazole derivatives, aromatic hydrocarbons, or macromolecular compounds (such as oligomers, dendrimers, or polymers) can be used. It is to be noted that an organic compound having a hole mobility of greater than or equal to 10⁻⁶ cm²/(V·s) is preferably applied as the organic compound. However, a substance other than these compounds may also be used as long as it is a substance in which the hole-transporting property is higher than the electron-transporting property. Since the composite material of an organic compound and a metal oxide is superior in carrier-injecting property and carrier-transporting property, low-voltage driving or low-current driving can be realized.

It is to be noted that the charge generation layer 513 may be formed by a combination of a composite material of an organic compound and a metal oxide with another material. For example, the charge generation layer 513 may be formed by a combination of a layer containing the composite material of an organic compound and a metal oxide with a layer containing one compound selected from among electron-donating substances and a compound having a high electron-transporting property. Further, the charge generation layer 513 may be formed by a combination of a layer containing the composite material of an organic compound and a metal oxide with a transparent conductive film.

In any case, any structure of the charge generation layer 513 interposed between the first light-emitting unit 511 and the second light-emitting unit 512 is acceptable as long as it is one by which electrons are injected into one of the light-emitting units and holes are injected into the other of the light-emitting units when a voltage is applied between the first electrode 501 and the second electrode 502.

In this embodiment mode, the light-emitting element having two light-emitting units is described; however, the present invention can be applied in a similar manner to a light-emitting element in which three or more light-emitting units are stacked. When a plurality of light-emitting units is arranged to be partitioned from each other with a charge generation layer between a pair of electrodes, like the light-emitting element according to this embodiment mode, emission from a region of high luminance can be realized at a low current density, and thus, an element with a long life can be achieved. When the light-emitting element is applied to a lighting device, a drop in voltage due to the resistance of an electrode material can be suppressed, and thus, uniform emission in a large area can be achieved. A light-emitting device that can be driven at a low voltage and has low power consumption can be realized.

A layer containing a light-emitting substance is provided in each of the first light-emitting unit 511 and the second light-emitting unit 512. Also in this embodiment mode, as described in Embodiment Mode 1, the layer containing a light-emitting substance is formed using any of the compositions of the present invention which contains an anthracene derivative and a solvent by a wet process.

A thin film formed by a wet process with the use of any of the compositions of this embodiment mode, in which an anthracene derivative is dissolved, can be made to have favorable film properties without defects or the like. Thus, with the use of such a composition and a thin film, a highly reliable light-emitting element (device) can be fabricated.

In this embodiment mode, since a wet process is employed for fabrication of a thin film and a light-emitting element, high material utilization efficiency and a reduction in expensive facilities such as a large vacuum apparatus can be achieved, resulting in a cost reduction and a productivity improvement. Thus, a light-emitting device and an electronic device that are highly reliable can be manufactured while achieving a cost reduction and a productivity improvement.

This embodiment mode can be combined with any other embodiment mode as appropriate.

### Embodiment Mode 4

In this embodiment mode, a light-emitting device manufactured using any of the compositions of the present invention which contains an anthracene derivative and a solvent is described.

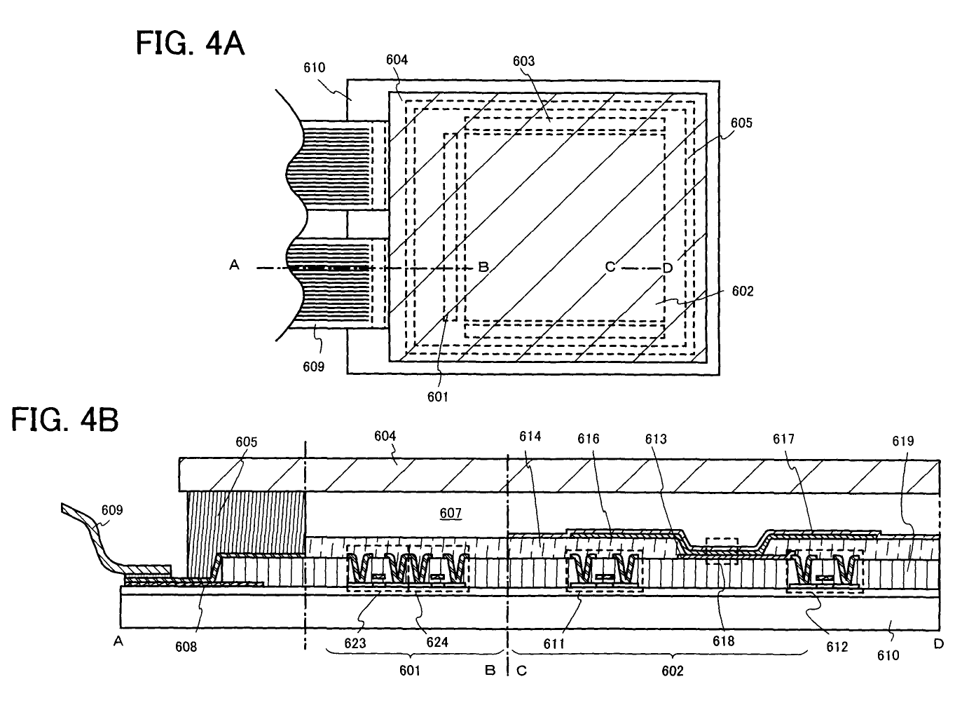

In this embodiment mode, a light-emitting device manufactured using any of the compositions of the present invention which contains an anthracene derivative and a solvent is described using FIGS. 4A and 4B. FIG. 4A is a top view of a light-emitting device, and FIG. 4B is a cross-sectional view taken along lines A-B and C-D of FIG. 4A. A driver circuit portion (a source side driver circuit) 601, a pixel portion 602, and a driver circuit portion (a gate side driver circuit) 603 are indicated by dotted lines. Reference numerals 604 and 605 denote a sealing substrate and a sealing material, respectively. A portion enclosed by the sealing material 605 corresponds to a space 607.

A lead wiring 608 is a wiring used to transmit signals to be inputted to the source side driver circuit 601 and the gate side driver circuit 603 and receives a video signal, a clock signal, a start signal, a reset signal, and the like from a flexible printed circuit (FPC) 609 which is an external input terminal. It is to be noted that only the FPC is illustrated in this case; however, the FPC may be provided with a printed wiring board (PWB). The category of the light-emitting device in this specification includes not only a light-emitting device itself but also a light-emitting device to which an FPC or a PWB is attached.

Next, a cross-sectional structure is described using FIG. 4B. The driver circuit portion and the pixel portion are formed over an element substrate 610. In this case, one pixel in the pixel portion 602 and the source side driver circuit 601 which is the driver circuit portion are illustrated.

A CMOS circuit, which is a combination of an n-channel TFT 623 and a p-channel TFT 624, is formed as the source side driver circuit 601. Each driver circuit portion may be any of a variety of circuits such as a CMOS circuit, a PMOS circuit, or an NMOS circuit. Although a driver-integration type device, in which a driver circuit is formed over a substrate, is described in this embodiment mode, a driver circuit needed not necessarily be formed over the substrate but can be formed externally from a substrate.

The pixel portion 602 is formed of a plurality of pixels each of which includes a switching TFT 611, a current control TFT 612, and a first electrode 613 which is electrically connected to a drain of the current control TFT 612. It is to be noted that an insulating layer 614 is formed to cover end portions of the first electrode 613. In this case, the insulating layer 614 is formed using a positive photosensitive acrylic resin film. The first electrode 613 is formed over an insulating layer 619 which is an interlayer insulating layer.

The insulating layer 614 is formed so as to have a curved surface having curvature at an upper end portion or a lower end portion thereof in order to make the coverage be favorable. For example, in the case of using a positive photosensitive acrylic resin as a material for the insulating layer 614, it is preferable that the insulating layer 614 be formed so as to have a curved surface with radius of curvature (0.2 μm to 3 μm) only at the upper end portion thereof The insulating layer 614 can be formed using either a negative type which becomes insoluble in an etchant by light irradiation or a positive type which becomes soluble in an etchant by light irradiation.

A layer 616, which contains a light-emitting substance, and a second electrode 617 are formed over the first electrode 613. In this case, it is preferred that the first electrode 613 serving as an anode be formed using a material with a high work function. For example, the first electrode 613 can be formed using a single-layer film of an ITO film, an indium tin oxide film containing silicon, an indium oxide film containing 2 wt % to 20 wt % of zinc oxide, a titanium nitride film, a chromium film, a tungsten film, a Zn film, a Pt film, or the like; a stack of a titanium nitride film and a film containing aluminum as its main component; or a stacked film such as a film having a three-layer structure of a titanium nitride film, a film containing aluminum as its main component, and another titanium nitride film. When the first electrode 613 has a stacked structure, resistance as a wiring is low, a good ohmic contact is formed, and further, the first electrode 613 can be made to function as an anode.

The layer 616 containing a light-emitting substance is formed using any of the compositions of the present invention which contains an anthracene derivative and a solvent by a wet process. For the wet process, any of a variety of methods, for example, a droplet discharging method such as an inkjet method, a printing method, a spin coating method, and the like can be used. The layer 616 containing a light-emitting substance may be formed using another material such as a low molecular weight material, a material with a molecular weight such as that of an oligomer or a dendrimer, or a macromolecular material.

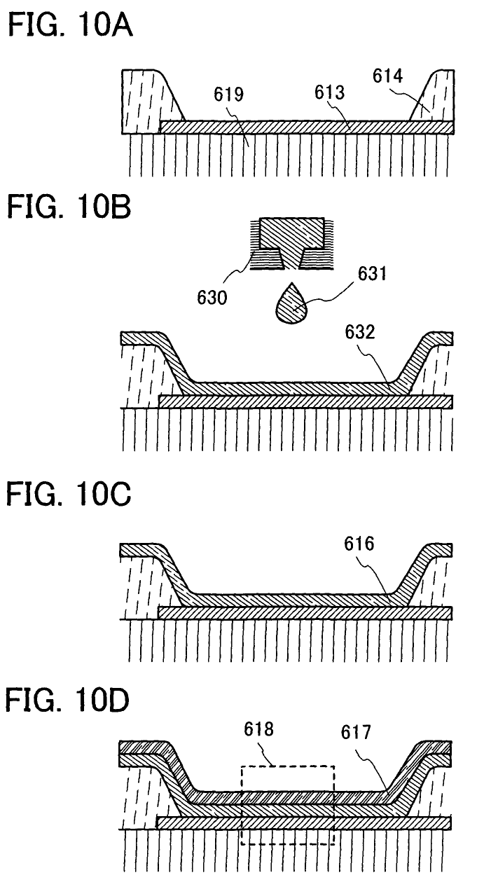

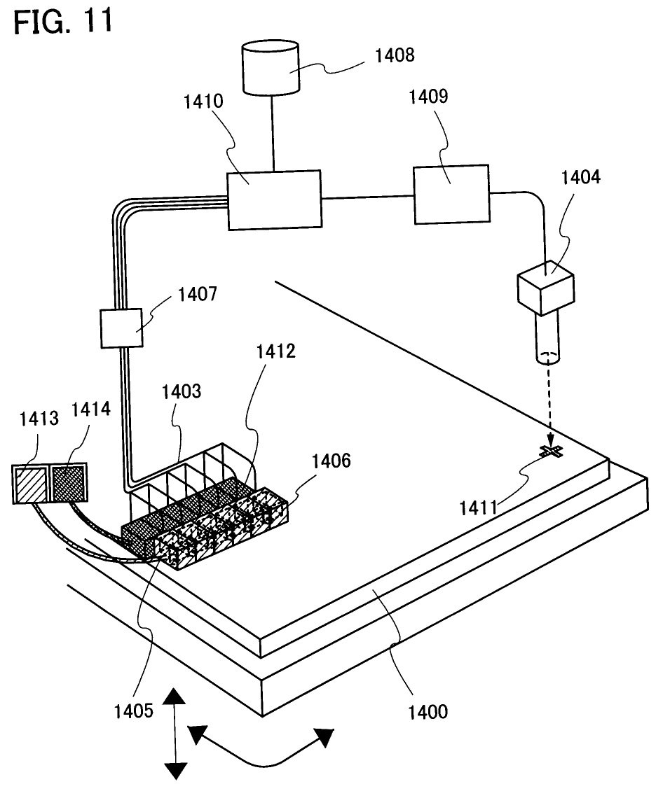

In this embodiment mode, using FIGS. 10A to 10D and FIG. 11, an example is described in which the layer 616 containing a light-emitting substance is formed by a droplet discharging method as a wet process. FIGS. 10A to 10D show a fabrication process of a light-emitting element of the light-emitting device shown in FIGS. 4A and 4B.

In FIG. 10A, the first electrode 613 is formed over the insulating layer 619, and the insulating layer 614 is formed so as to cover a part of the first electrode 613. In an exposed portion of the first electrode 613 which is an opening of the insulating layer 614, a droplet 631 is discharged from a droplet discharge device 630 to form a layer 632 containing a composition. The droplet 631 is any of the compositions of the present invention which contains a solvent and an anthracene derivative and attached to the first electrode 613 (see FIG. 10B). The solvent is removed from the layer 632 containing the composition, and the resulting material is solidified, whereby the layer 616 containing a light-emitting substance is formed (see FIG. 10C). The solvent may be removed by drying or a heating step. In addition, the step of discharging the composition may be performed under reduced pressure. The second electrode 617 is formed over the layer 616 containing a light-emitting substance, whereby a light-emitting element 618 is fabricated (see FIG. 10D). When the layer 616 containing a light-emitting substance is formed by a droplet discharging method as described above, the composition can be selectively discharged into a region in which the layer is to be formed, and accordingly, waste of material can be reduced. Furthermore, a photolithography process or the like for shaping is not needed, and thus, the process can be simplified and a low cost can be achieved.

A droplet discharging means used in this embodiment mode is generally a means to discharge liquid droplets, such as a nozzle equipped with a composition discharge outlet, a head having one or a plurality of nozzles.

One mode of a droplet discharging apparatus used for a droplet discharging method is shown in FIG. 11. Each of heads 1405 and 1412 of a droplet discharging means 1403 is connected to a control means 1407, and this control means 1407 is controlled by a computer 1410; thus, a preprogrammed pattern can be drawn. The timing for dawning may be determined, for example, based on a marker 1411 formed over a substrate 1400. Alternatively, a reference point may be fixed based on an edge of the substrate 1400. The reference point is detected by an imaging means 1404 and converted into a digital signal by an image processing means 1409. Then, the digital signal is recognized by the computer 1410, and then, a control signal is generated and transmitted to the control means 1407. An image sensor or the like using a charge coupled device (CCD) or a complementary metal oxide semiconductor (CMOS) can be used for the imaging means 1404. Needless to say, information about a pattern to be formed over the substrate 1400 is stored in a storage medium 1408, and the control signal is transmitted to the control means 1407 based on the information, whereby the head 1405 and the head 1412 of the droplet discharging means 1403 can be individually controlled. A material to be discharged is supplied to the heads 1405 and 1412 from a material supply sources 1413 and 1414, respectively, through pipes.

Inside the head 1405, a space filled with a liquid material as indicated by a dotted line 1406 and a nozzle which is a discharge outlet are provided. Although not shown, an internal structure of the head 1412 is similar to that of the head 1405. When the nozzle sizes of the heads 1405 and 1412 are different from each other, different materials can be discharged with different widths simultaneously. Each head can discharge and draw a plurality of light-emitting materials. In the case of drawing over a large area, the same material can be simultaneously discharged to be drawn from a plurality of nozzles in order to improve throughput. When a large substrate is used, the heads 1405 and 1412 can freely move over the substrate in a direction indicated by the arrows in FIG. 11, and a region where the material is to be drawn can be freely set. Thus, a plurality of the same patterns can be drawn over one substrate.

In addition, the step of discharging the composition may be performed under reduced pressure. The substrate may be heated when the composition is discharged. After the composition is discharged, either or both steps of drying and baking are performed. Both the drying and baking steps are heat treatments but different in purpose, temperature, and time period. The steps of drying and baking are each performed under normal pressure or under reduced pressure, by laser light irradiation, rapid thermal annealing, heating using a heating furnace, or the like. It is to be noted that there is no particular limitation on the timing and the number of heat treatments. The temperature at that time for performing each of the steps of drying and baking in a favorable manner depends on the material of the substrate and properties of the composition.

As a material used for the second electrode 617 which is formed over the layer 616 containing a light-emitting substance and serves as a cathode, it is preferable to use a material with a low work function (e.g., Al, Mg, Li, Ca, or an alloy or a compound thereof such as MgAg, Mg—In, Al—Li, LiF, or CaF₂). When light generated in the layer 616 containing a light-emitting substance is transmitted through the second electrode 617, the second electrode 617 may be formed of a stack of a metal thin film with a reduced film thickness and a transparent conductive film (e.g., a film of ITO, indium oxide containing 2 wt % to 20 wt % of zinc oxide, indium tin oxide containing silicon or silicon oxide, or zinc oxide (ZnO)).

The sealing substrate 604 is attached using the sealing material 605 to the element substrate 610; thus, a light-emitting element 618 is provided in the space 607 enclosed by the element substrate 610, the sealing substrate 604, and the sealing material 605. It is to be noted that the space 607 is filled with a filler. The space 607 is filled with an inert gas (e.g., nitrogen or argon) or the sealing material 605 in some cases.

It is preferable that an epoxy-based resin be used to form the sealing material 605 and that such a material permeate little moisture and oxygen as much as possible. In addition to a glass substrate or a quartz substrate, the sealing substrate 604 can be formed of a plastic substrate made of fiberglass-reinforced plastic (FRP), polyvinyl fluoride (PVF), polyester, acrylic, or the like. Alternatively, a film (made of polypropylene, polyester, vinyl, polyvinyl fluoride, vinyl chloride, or the like), or an inorganic evaporated film can also be used.

Accordingly, a light-emitting device manufactured using any of the compositions of the present invention which contains an anthracene derivative and a solvent can be obtained.

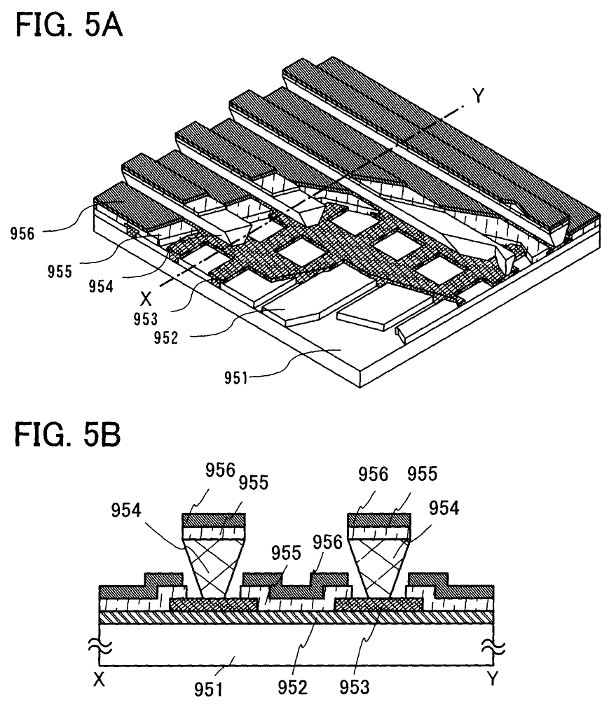

Although, as described above, an active matrix light-emitting device in which driving of a light-emitting element is controlled by transistors is described in this embodiment, the light-emitting device may also be a passive matrix light-emitting device. FIGS. 5A and 5B show a passive matrix light-emitting device to which the present invention is applied. FIG. 5A is a perspective view of the light-emitting device, and FIG. SB is a cross-sectional view taken along a line X-Y of FIG. 5A. In FIGS. 5A and 5B, a layer 955 containing a light-emitting substance is provided between an electrode 952 and an electrode 956 over a substrate 951. End portions of the electrode 952 are covered by an insulating layer 953. Then, a partition layer 954 is provided over the insulating layer 953. A sidewall of the partition layer 954 slopes so that the distance between one sidewall and another sidewall becomes narrower toward the substrate surface. In other words, a cross section taken in the direction of the short side of the partition layer 954 is trapezoidal, and the base of the cross-section (a side facing in the same direction as a plane direction of the insulating layer 953 and in contact with the insulating layer 953) is shorter than the upper side thereof (a side facing in the same direction as the plane direction of the insulating layer 953 and not in contact with the insulating layer 953). The provision of the partition layer 954 in this manner can prevent the light-emitting element from being defective due to static electricity or the like.

The layer 955 containing a light-emitting substance of the passive matrix light-emitting device is formed using any of the compositions of the present invention which contains an anthracene derivative and a solvent by a wet process, as described in Embodiment Mode 1. In this embodiment mode, the layer 955 containing a light-emitting substance is formed by a coating method (a spin coating method). The partition layer 954 of the light-emitting device in FIGS. 5A and 5B has a so-called reverse-tapered shape. Therefore, the layer 955 containing a light-emitting substance is divided by the partition layer 954 in a self-aligned manner to be selectively formed over the electrode 952 even if the composition containing a light-emitting substance is applied by a coating method. Thus, division is formed between adjacent light-emitting elements without being shaped by etching, and electric failure such as a short circuit between the light-emitting elements can be prevented. Accordingly, the light-emitting device shown in FIGS. 5A and 5B can be manufactured in a more simplified step.

A thin film fabricated by a wet process with the use of any of the compositions of this embodiment mode, in which an anthracene derivative is dissolved, can be made to have favorable film properties without defects or the like. Thus, with the use of such a composition and a thin film, a highly reliable light-emitting element (device) can be fabricated.

In this embodiment mode, high material utilization efficiency can be achieved because a wet process is employed for fabrication of a thin film and a light-emitting element, and cost reduction and productivity improvement can be achieved because expensive facilities such as a large size vacuum apparatus can be reduced. Thus, a light-emitting device and an electronic device that are highly reliable can be manufactured while achieving a cost reduction and a productivity improvement.

### Embodiment Mode 5

In this embodiment mode, electronic devices of the present invention, each including the light-emitting device described in Embodiment Mode 4, are described.

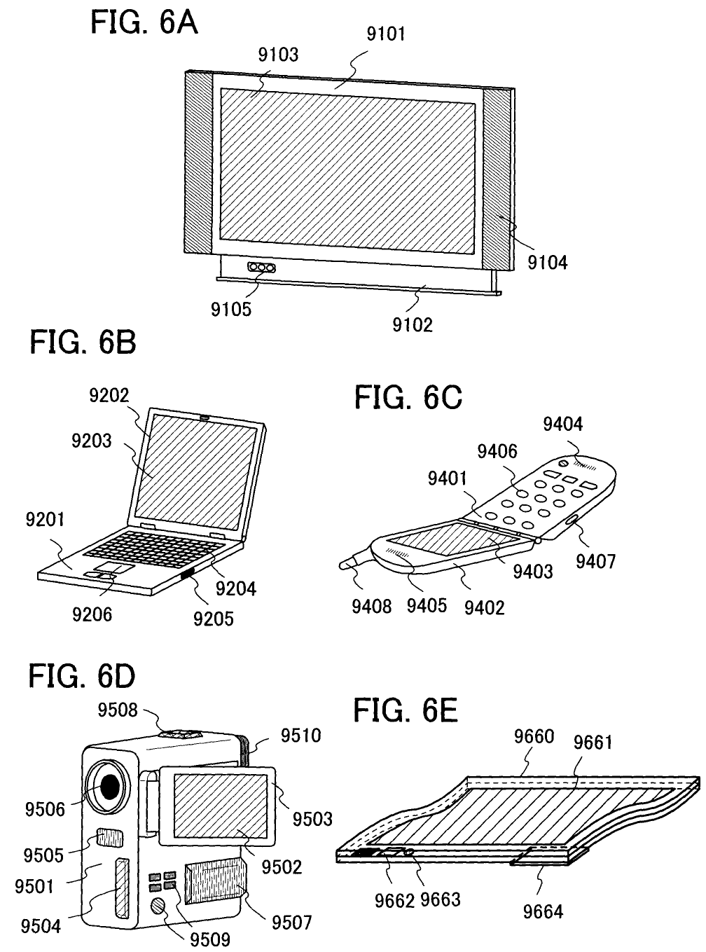

Examples of electronic devices that include light-emitting elements fabricated using any of the compositions of the present invention which contains an solvent and an anthracene derivative include cameras such as video cameras or digital cameras, goggle type displays, navigation systems, audio playback devices (e.g., car audio systems and audio systems), computers, game machines, portable information terminals (e.g., mobile computers, cellular phones, portable game machines, and electronic books), image playback devices in which a recording medium is provided (devices that are capable of playing back recording media such as digital versatile discs (DVDs) and equipped with a display device that can display the image), and the like. Specific examples of these electronic devices are shown in FIGS. 6A to 6D.

FIG. 6A shows a television device according to the present invention which includes a housing 9101, a support stand 9102, a display portion 9103, a speaker portion 9104, a video input terminal 9105, and the like. In the television device, the display portion 9103 has light-emitting elements similar to those described in Embodiment Mode 2 or 3 arranged in matrix form. Each light-emitting element is fabricated using any of the compositions described in Embodiment Mode 1. Accordingly, lower cost and higher productivity can be achieved because of high material utilization efficiency and a reduction in expensive facilities such as a large vacuum apparatus. Thus, by use of the present invention, a highly reliable television device can be provided at low cost. Furthermore, in the television device according to the present invention, the degree of freedom of the shape is high because the display portion is formed by a wet process; thus, products suitable for a residence can be provided.

FIG. 6B shows a computer according to the present invention which includes a main body 9201, a housing 9202, a display portion 9203, a keyboard 9204, an external connection port 9205, a pointing device 9206, and the like. In the computer, the display portion 9203 has light-emitting elements similar to those described in Embodiment Mode 2 or 3 arranged in matrix form. Each light-emitting element is fabricated using any of the compositions described in Embodiment Mode 1. Accordingly, lower cost and higher productivity can be achieved because of high material utilization efficiency and a reduction in expensive facilities such as a large vacuum apparatus. Thus, by use of the present invention, a highly reliable computer can be provided at low cost. Furthermore, in the computer according to the present invention, the degree of freedom of the shape is high because the display portion is formed by a wet process; thus, products suitable for the environment can be provided.

FIG. 6C shows a cellular phone according to the present invention which includes a main body 9401, a housing 9402, a display portion 9403, an audio input portion 9404, an audio output portion 9405, operation keys 9406, an external connection port 9407, an antenna 9408, and the like. In the cellular phone, the display portion 9403 has light-emitting elements similar to those described in Embodiment Mode 2 or 3 arranged in matrix form. Each light-emitting element is fabricated using any of the compositions described in Embodiment Mode 1. Accordingly, lower cost and higher productivity can be achieved because of high material utilization efficiency and a reduction in expensive facilities such as a large vacuum apparatus. Thus, by use of the present invention, a highly reliable cellular phone can be provided at low cost. Furthermore, in the cellular phone according to the present invention, the degree of freedom of the shape is high because the display portion is formed by a wet process; thus, products suitable for portability can be provided.

FIG. 6D shows a camera according to the present invention which includes a main body 9501, a display portion 9502, a housing 9503, an external connection port 9504, a remote control receiver 9505, an image receiver 9506, a battery 9507, an audio input portion 9508, operation keys 9509, an eye piece portion 9510, and the like. In the camera, the display portion 9502 has light-emitting elements similar to those described in Embodiment Mode 2 or 3 arranged in matrix form. Each light-emitting element is fabricated using any of the compositions described in Embodiment Mode 1. Accordingly, lower cost and higher productivity can be achieved because of high material utilization efficiency and a reduction in expensive facilities such as a large vacuum apparatus. Thus, by use of the present invention, a highly reliable camera can be provided at low cost. Furthermore, in the camera according to the present invention, the degree of freedom of the shape is high because the display portion is formed by a wet process; thus, products suitable for portability can be provided.

FIG. 6E shows electronic paper according to the present invention which is flexible and includes a main body 9610, a display portion 9611 which displays images, a driver IC 9612, a receiver 9613, a film battery 9614, and the like. The driver IC, the receiver, or the like may be mounted using a semiconductor component. In the electronic paper of the present invention, the main body 9610 is formed using a flexible material such as plastic or a film. In the electronic paper, the display portion 9502 has light-emitting elements similar to those described in Embodiment Mode 2 or 3 arranged in matrix form.

Each light-emitting element is fabricated using any of the compositions described in Embodiment Mode 1. Accordingly, lower cost and higher productivity can be achieved because of high material utilization efficiency and a reduction in expensive facilities such as a large vacuum apparatus. Thus, by use of the present invention, a highly reliable electronic paper can be provided at low cost. Furthermore, in the electronic paper according to the present invention, the degree of freedom of the shape is high because the display portion is formed by a wet process; thus, products suitable for portability can be provided.

Furthermore, such electronic paper is extremely light and flexible and can be rolled into a cylinder shape as well; thus, the electronic paper is a display device that has a great advantage in terms of portability. The electronic device of the present invention allows a display medium having a large screen to be freely carried.

The electronic paper shown in FIG. 6E can be used as a display means for mainly displaying a still image for any of navigation systems, audio playback devices (e.g., car audio systems, and audio systems), personal computers, game machines, or portable information terminals (e.g., mobile computers, cellular phones, portable game machines, and electronic papers), as well as of electrical home appliances such as refrigerators, washing machines, rice cookers, fixed telephones, vacuum cleaners, or clinical thermometers, train advertisement, and large information displays such as arrival and departure guide plates in railroad stations or airports.

As described above, the applicable range of the light-emitting device of the present invention is wide so that the light-emitting device can be applied to electronic devices of a variety of fields. Since any of the compositions described in Embodiment Mode 1 is used, the material utilization efficiency is high and expensive facilities such as a large vacuum apparatus can be reduced. Accordingly, lower cost and higher productivity can be achieved. Therefore, by use of the present invention, highly reliable electronic devices can be provided at low cost.

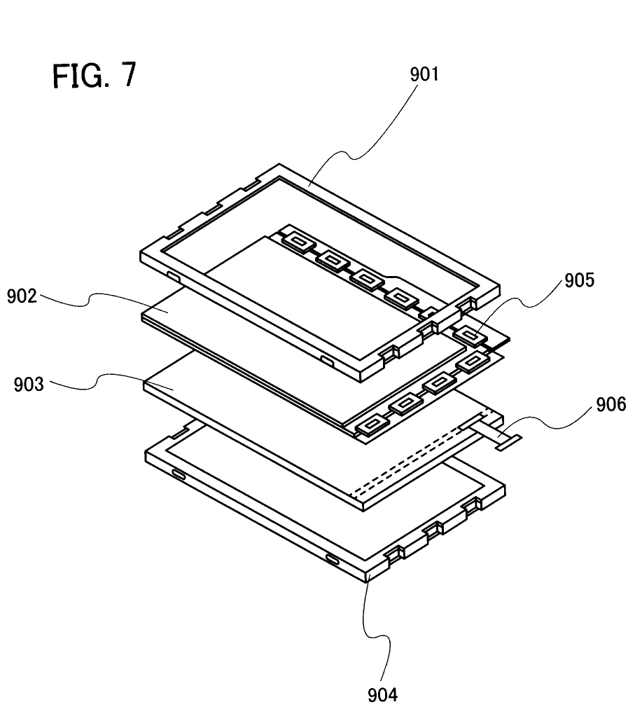

The light-emitting device of the present invention can also be used as a lighting device. One mode in which the light-emitting device of the present invention is used as the lighting device is described using FIG. 7.

FIG. 7 shows an example of a liquid crystal display device in which the light-emitting device of the present invention is used as a backlight. The liquid crystal display device shown in FIG. 7 includes a chassis 901, a liquid crystal layer 902, a backlight 903, and a chassis 904. The liquid crystal layer 902 is connected to a driver IC 905. The light-emitting device of the present invention is used as the backlight 903, and a current is supplied through a terminal 906.

By use of the light-emitting device of the present invention as the backlight of the liquid crystal display device, lower cost and higher productivity can be achieved. Further, since the light-emitting device of the present invention is a lighting device with plane light emission and can be made to have a larger area, the backlight can be made to have a larger area, and a liquid crystal display device can also be made to have a larger area. Furthermore, since the light-emitting device of the present invention is thin, a thinner shape can also be achieved in a display device.

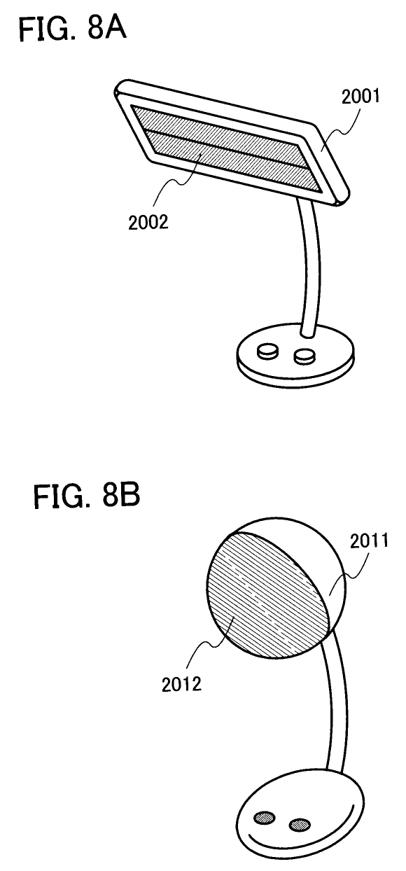

Each of FIGS. 8A and 8B show an example in which the light-emitting device of the present invention is used as a table lamp that is a lighting device. A table lamp shown in FIG. 8A has a chassis 2001 and a light source 2002, and the light-emitting device of the present invention is used as the light source 2002. A table lamp shown in FIG. 8B has a chassis 2011 and a light source 2012, and the light-emitting device of the present invention is used as the light source 2012. In the present invention, a thin film containing a light-emitting substance is formed by a wet process and therefore can be formed even on a curved surface, such as the surface of the light source 2012. Accordingly, by use of the present invention, the shape and design of the light-emitting device of the present invention which can be manufactured can freely be set.

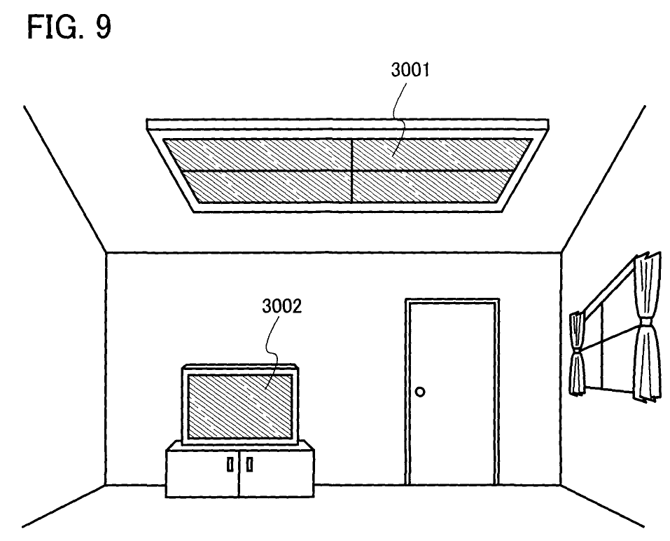

FIG. 9 shows an example in which a light-emitting device to which the present invention is applied is used as an indoor lighting device 3001. Since the light-emitting device of the present invention can be made to have a larger area, the light-emitting device of the present invention can be used as a lighting device having a large emission area. Further, since the light-emitting device of the present invention is thin, the light-emitting device of the present invention can be used as a lighting device with a thinner shape. A television device 3002 according to the present invention as described in FIG. 6A is placed in a room in which a light-emitting device to which the present invention is applied is used as the indoor lighting device 3001, and public broadcasting and movies can be enjoyed.

### EXAMPLE 1

In this example, a thin film was formed by a wet process using one of the compositions of the present invention which contains an anthracene derivative and a solvent.

### PRODUCTION EXAMPLE 1

First, as Production Example 1, an example in which 9-[4-(N-carbazolyl)]phenyl-10-phenylanthracene (CzPA) represented by the structural formula (11) of Embodiment Mode 1 was used as an anthracene derivative and toluene was used as an solvent is described.

Into 15 ml of toluene were mixed 150 mg of CzPA to be dissolved therein, whereby a composition with a solution concentration of 10 g/L was prepared. The composition was applied to a glass substrate under several different spin conditions by a spin coating method, and baking was performed at 100° C. for one hour in the atmosphere, whereby a thin film was formed. The spin conditions for the spin coating and the thickness of the obtained thin film are shown in Table 1.

TABLE 1

| Spinning rates | Film thickness |
|---|---|
| (rpm) | (nm) |
| 500 | 59.1 |
| 1000 | 40.8 |
| 1500 | 32.1 |
| 2000 | 27.4 |

For the spin conditions, the processing time was set to be 60 seconds for all samples, and the spinning rates were set to be 500 rpm, 1000 rpm, 1500 rpm, and 2000 rpm. The film thickness of the thin films were 59.1 nm, 40.8 nm, 32.1 nm, and 27.4 nm, respectively, at spinning rates of 500 rpm, 1000 rpm, 1500 rpm, and 2000 rpm. Under any of all the spin conditions, the obtained film was transparent and uniform without unevenness. It can be seen that even CzPA, which does not have an alkyl group, can be dissolved in a solvent and that a film with a high quality shape can be formed using such CzPA by a wet process.

### PRODUCTION EXAMPLE 2

Next, as Production Example 2, an example in which 9-(4-tert-butylphenyl)-10-[4-(carbazol-9-yl)]phenylanthracene (abbreviated to PTBCzPA) represented by the structural formula (17) of Embodiment Mode 1 was used as an anthracene derivative and toluene was used as an solvent is described.

Into 15 ml of toluene were mixed 150 mg of PTBCzPA to be dissolved therein, hereby a composition with a solution concentration of 10 g/L was prepared. The composition was applied to a glass substrate under several different spin conditions by a spin coating method, and baking was performed at 100° C. for one hour in the atmosphere, whereby a thin film was formed. The spin conditions for the spin coating and the thickness of the obtained thin film are shown in Table 2.

TABLE 2

| Spinning rates | Film thickness |
|---|---|
| (rpm) | (nm) |
| 500 | 73 |
| 1000 | 40.4 |
| 1500 | 35.7 |
| 2000 | 28.2 |

For the spin conditions, the processing time was set to be 60 seconds for all samples, and the spinning rates were set to be 500 rpm, 1000 rpm, 1500 rpm, and 2000 rpm. The film thickness of the thin films were 73.0 nm, 40.4 nm, 35.7 nm, and 28.2 nm, respectively, at spinning rates of 500 rpm, 1000 rpm, 1500 rpm, and 2000 rpm. Under any of all the spin conditions, the obtained film was transparent and uniform without unevenness.

### COMPARATIVE EXAMPLE

As Comparative Example, an example in which 9,10-diphenylanthracene (DPAnth) was dissolved in a solvent toluene to form a composition and a thin film by a wet process using the composition is described.

Into 15 ml of toluene were mixed 150 mg of DPAnth to be dissolved therein, whereby a composition with a solution concentration of 10 g/L was prepared. The composition was applied to a glass substrate under several different spin conditions by a spin coating method, and baking was performed at 100° C. for one hour in the atmosphere, whereby a thin film was formed. For the spin conditions, the processing time was set to be 60 seconds for all samples, and the spinning rates were set to be 500 rpm, 1000 rpm, and 1500 rpm. Under any of all the spin conditions, the obtained film was cloudy and uneven.

Accordingly, it is understood that a uniform thin film with favorable film properties can be formed by a wet process using any of the compositions of the present invention which contains an anthracene derivative and a solvent.

### EXAMPLE 2

In this example, fabrication of the compositions of the present invention and a light-emitting element in which the composition is used are exemplified.

First, a method of forming a composition (Solution A) for forming a hole-transporting layer of a light-emitting element of this example is described. Into an undiluted solution of PEDOT:PSS (BAYTRON P A4083 LVW 142) was mixed 2-methoxyethanol at a volume ratio of 3:2. The mixture was stirred to be uniformly blended, whereby Solution A was obtained.

Next, a method of forming a composition (Solution B) for forming a layer that contains a light-emitting substance of the light-emitting element of this example is described. CzPA was used as an anthracene derivative, and toluene was used as a solvent. Into 42 ml of toluene were mixed 400 mg of CzPA and 20 mg of 9,10-diphenyl-2-[N-phenyl-N-(9-phenyl-9H-carbazol-3-yl)amino]anthracene (2PCAPA). The mixture was stirred for about 12 hours to give Solution B, which is a composition. In Solution B, the weight proportion of 2PCAPA to CZPA was 5% and the solution concentration was 10 g/L.

First, a glass substrate on which an indium tin silicon oxide (ITSO) film was formed to a thickness of 110 nm was prepared. It is to be noted that the ITSO film functions as an anode of the light-emitting element. As a pretreatment for forming the light-emitting element on this substrate, a mixed solution of water and 2-methoxyethanol that were mixed at a volume ratio of 3:2 was dripped onto the ITSO film, and the ITSO film was spin-coated with the mixed solution. The spin coating was carried out at a spinning rate of 300 rpm for 3 seconds and then at a spinning rate of 2000 rpm for 20 seconds.

Next, Solution A was dripped onto the ITSO film that had undergone the pretreatment, and the ITSO film was spin-coated at a spinning rate of 300 rpm for 3 seconds, at a spinning rate of 2000 rpm for 60 seconds, and then at a spinning rate of 3000 rpm for 10 seconds. A film formed by the spin coating of Solution A on a terminal portion is removed using ethanol, and drying was performed by heating for one hour in a vacuum oven in which the temperature was set to be 110° C. while the pressure was reduced with a rotary pump, whereby a PEDOT/PSS film was formed.

Solution B was dripped onto the PEDOT/PSS film, which was spin-coated at a spinning rate of 200 rpm for 2 seconds, at a spinning rate of 1000 rpm for 60 seconds, and then at a spinning rate of 2500 rpm for 10 seconds. A film formed by the spin coating of Solution B on the terminal portion is removed using toluene. Thereafter, the film was heated at 70° C. to 80° C. for 10 minutes under a nitrogen atmosphere in a chamber and then further heated for 20 minutes while the pressure was reduced with a rotary pump. Thereafter, the substrate was disposed in a vacuum evaporation apparatus in which the pressure was reduced to 10⁻⁴ Pa so that a surface on which the film was to be formed faced downward, and a tris(8-quinolinolato)aluminum (Alq) film with a thickness of 30 nm, a lithium fluoride film with a thickness of 1 nm, and an aluminum film with a thickness of 200 nm were sequentially vacuum evaporated. The light-emitting element of this example was fabricated by the above process. In addition, structural formulae of 2PCAPA and Alq are shown below.

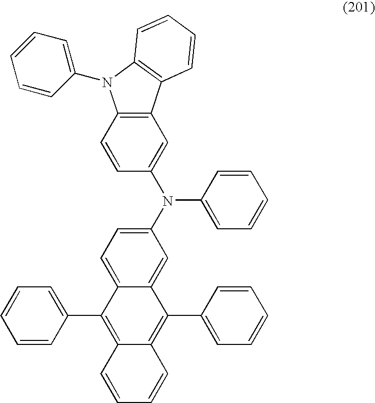

After sealing was performed in a glove box under a nitrogen atmosphere so that the light-emitting element obtained as described above was not exposed to the atmosphere, operation characteristics of the light-emitting element was measured. It is to be noted that the measurements were performed at room temperature (in an atmosphere kept at 25° C.).

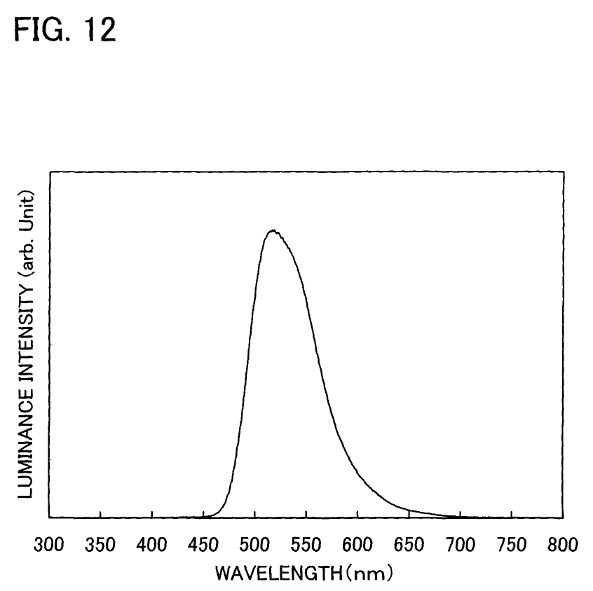

When a voltage of 12 V was applied to the light-emitting element of this example, a luminance of 1000 cd/m² was obtained. FIG. 12 shows an emission spectrum of the light-emitting element of this example. As shown in FIG. 12, green light from 2PCAPA was obtained.

It can be confirmed that the light-emitting element was obtained by use of the present invention for the formation of the layer containing a light-emitting substance as described above.

### EXAMPLE 3

Synthesis methods of 9-(4-tert-butylphenyl)-10-[4-(carbazol-9-yl)]phenylanthracene (PTBCzPA) used in Example 1 represented by the structural formula (17) and 9,10-diphenyl-2-[N-phenyl-N-(9-phenyl-9H-carbazol-3-yl)amino]anthracene (2PCAPA) used in Example 2 represented by a structural formula (201), which are novel materials, are described below.

First, a synthesis method of 9-(4-tert-butylphenyl)-10-[4-(carbazol-9-yl)]phenylanthracene (PTBCzPA) used in Example 1 represented by the structural formula (17) is described.

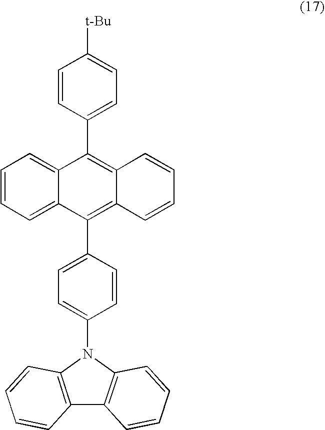

### [Step 1] Synthesis of 9-bromo-10-(4-tert-butylphenyl)anthracene

### (i) Synthesis of 9-(4-tert-butylphenyl)anthracene

A synthesis scheme of 9-(4-tert-butylphenyl)anthracene is shown in (D-1).

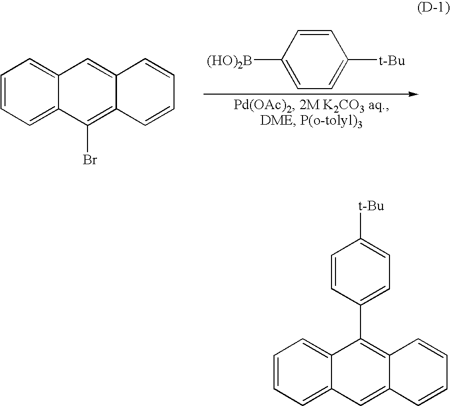

Into a 100 mL three-neck flask were put 5.1 g (20 mmol) of 9-bromoanthracene, 3.6 g (20 mmol) of 4-tert-butylphenylboronic acid, and 244 mg (0.80 mmol) of tri(o-tolyl)phosphine. The air in the flask was replaced with nitrogen. To the mixture were added 20 mL of ethyleneglycoldimethylether (DME). This reaction mixture was stirred to be degassed under reduced pressure. After the degassing, 45 mg (0.20 mmol) of palladium(II) acetate and 10 mL (2.0 mol/L) of an aqueous solution of potassium carbonate were added to the mixture. This reaction mixture was stirred at 80° C. for 3 hours under a stream of nitrogen. After the reaction, the reaction mixture was cooled to room temperature so that a solid was precipitated. This solid was collected by suction filtration. The collected solid was dissolved in toluene. The mixture was filtered by suction through Celite (produced by Wako Pure Chemical Industries, Ltd., Catalog No. 531-16855), Florisil (produced by Wako Pure Chemical Industries, Ltd., Catalog No. 540-00135), and alumina. The filtrate was concentrated to give a solid. This solid was recrystallized with ethanol to give 5.0 g of a white powdered solid, which was the object of the synthesis, at a yield of 81%.

### (ii) Synthesis of 9-bromo-10-(4-tert-butylphenyl)anthracene

A synthesis scheme of 9-bromo-10-(4-tert-butylphenyl)anthracene is shown in (D-2).

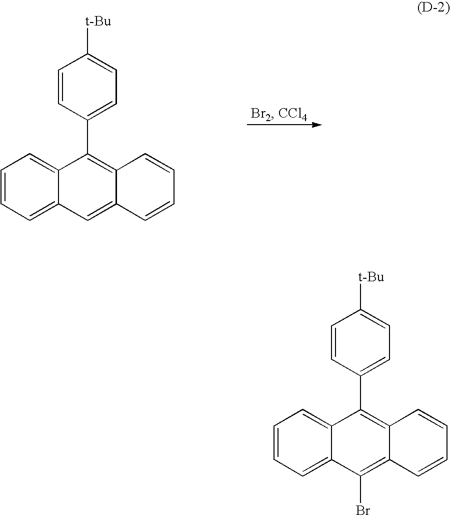

Into a 500 mL three-neck flask were put 5.0 g (16.0 mmol) of 9-(4-tert-butylphenyl)anthracene and 90 mL of carbon tetrachloride. The mixture was stirred to give a solution, to which a solution obtained by dissolving 2.8 g (18 mmol) of bromine in 10 mL of carbon tetrachloride was dripped from a dropping funnel. Thereafter, the mixture was stirred at room temperature for one hour Then, an aqueous solution of sodium thiosulfate was added to the reaction solution, and the reaction was completed. The aqueous layer of the reaction mixture was extracted with chloroform. The extract was combined with an organic layer, followed by washing with a saturated sodium hydrogen carbonate solution and then a saturated saline solution. The organic layer was dried with magnesium sulfate. After magnesium sulfate was removed by gravity filtration of this mixture, the filtrate was concentrated to give a solid. This solid was recrystallized with ethanol to give 6.3 g of a yellow powdered solid, which was the object of the synthesis, at a yield of 99%.

### [Step 2] Synthesis of 9-(4-tert-butylphenyl)-10-[4-(carbazol-9-yl)]phenylanthracene (PTBCzPA)

A synthesis scheme of PTBCzPA is shown in (D-3).

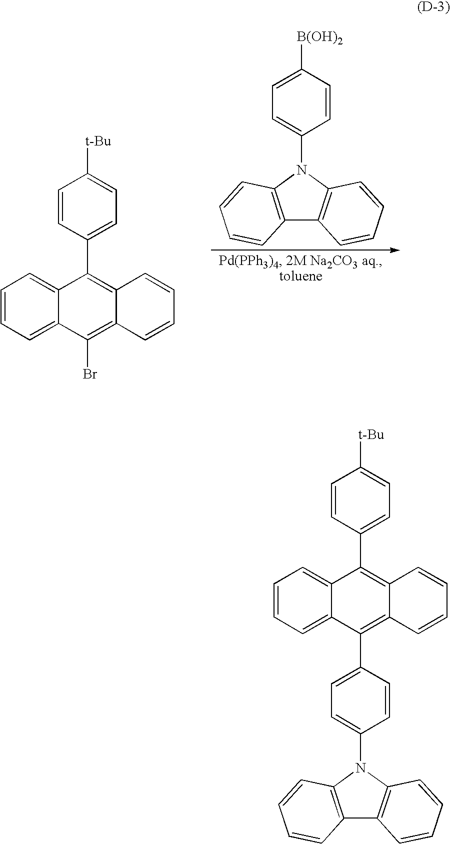

Into a 100 mL three-neck flask were put 2.0 g (5.1 mmol) of 9-bromo-10-(4-tert-butylphenyl)anthracene and 1.5 g (5.1 mmol) of 4-carbazol-9-yl)phenylboronic acid. The air in the flask was replaced with nitrogen. To the mixture were added 25 mL of ethyleneglycoldimethylether (DME) and 10 mL (2.0 mol/L) of an aqueous solution of sodium carbonate. This mixture was stirred to be degassed under reduced pressure. After the degassing, 85 mg (0.017 mmol) of tetrakis(triphenylphosphine)palladium(0) were added to the mixture. This mixture was stirred at 80° C. for 12 hours under a stream of nitrogen. After the reaction, the reaction mixture was cooled to room temperature to give a precipitate. The precipitate was collected by suction filtration. The collected solid was dissolved in toluene. The mixture was filtered by suction through Celite (produced by Wako Pure Chemical Industries, Ltd., Catalog No. 531-16855), Florisil (produced by Wako Pure Chemical Industries, Ltd., Catalog No. 540-00135), and alumina. The filtrate was concentrated to give a solid. This solid was purified by silica gel column chromatography (a developing solvent was a mixed solvent of hexane:toluene=7:3). The obtained solid was recrystallized with hexane to give 912 mg of a light yellow powdered solid, which was the object of the synthesis, at a yield of 32%. It was confirmed by a nuclear magnetic resonance (NMR) method that this compound was 9-(4-tert-butylphenyl)-10-[4-(carbazol-9-yl)]phenylanthracene (PTBCzPA).

¹H-NMR data of PTBCzPA are shown as follows: ¹H-NMR (300 MHz, CDCl₃,): δ=1.50 (s, 9H), 7.33-7.54 (m, 10H), 7.62-7.85 (m, 12H), 8.21 (d, J=7.8 Hz, 2H)

Next, a synthesis method of 9,10-diphenyl-2-[N-phenyl-N-(9-phenyl-9H-carbazol-3-yl)amino]anthracene (2PCAPA) used in Example 2 represented by the structural formula (201) is described.

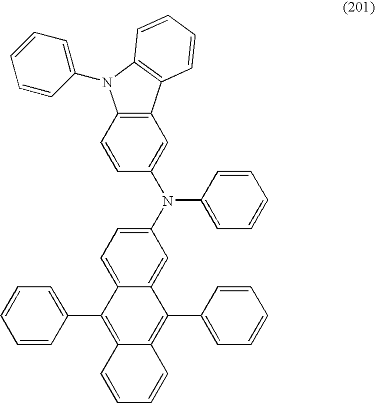

### [Step 1] Synthesis of 2-bromo-9,10-diphenylanthracene

### (i) Synthesis of 2-bromo-9,10-anthraquinone

A synthesis scheme of 2-bromo-9,10-anthraquinone is shown in (C-1).

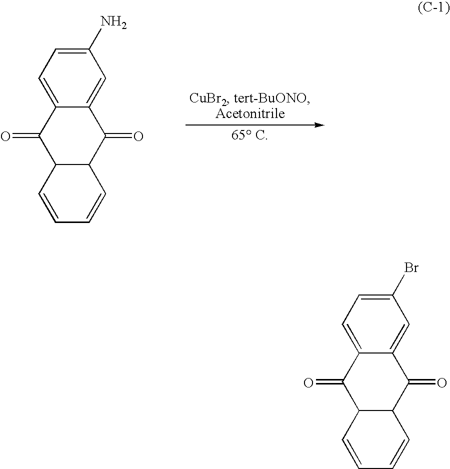

Into a 1 L three-neck flask were put 46 g (206 mmol) of copper(II) bromide and 500 mL of acetonitrile and added 17.3 g (168 mmol) of tert-butyl nitrite. The mixture was heated at 65° C., and 25 g (111.0 mmol) of 2-amino-9,10-anthraquinone was added thereto. The mixture was stirred at the same temperature for 6 hours. After the reaction, the reaction mixture was poured into 3 M hydrochloric acid. This mixture was stirred for 3 hours to give a precipitate, and the precipitate was filtered off, followed by washing with water and ethanol. The solid obtained by the filtration was dissolved in toluene. This mixture was filtered through Florisil (produced by Wako Pure Chemical Industries, Ltd., Catalog No. 540-00135), Celite (produced by Wako Pure Chemical Industries, Ltd., Catalog No. 531-16855), and alumina. The filtrate was concentrated to give a solid. This solid was recrystallized with chloroform and hexane to give 18.6 g of a cream colored solid of 2-bromo-9,10-anthraquinone at a yield of 58%.

### (ii) Synthesis of 2-bromo-9,10-diphenyl-9,10-dihydroanthracene-9,10-diol

A synthesis scheme of 2-bromo-9,10-diphenyl-9,10-dihydroanthracene-9,10-diol is shown in (C-2).

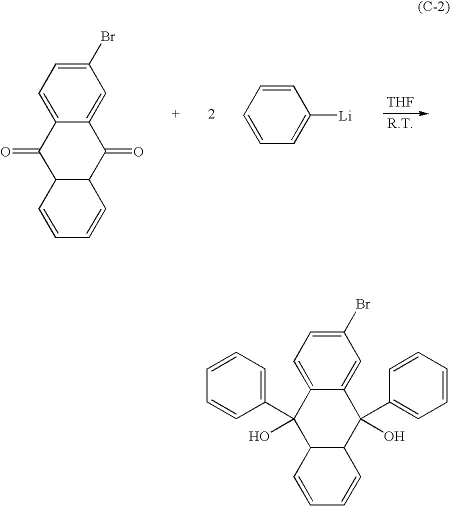

Into a 300 mL three-neck flask were put 4.90 g (16.95 mmol) of 2-bromo-9,10-anthraquinone. The air in the flask was replaced with nitrogen. To the mixture were added 100 mL of tetrahydrofuran (THF) and were dripped 17.76 mL (37.29 mmol) of a dibutyl ether solution of phenyl lithium. The mixture was stirred at room temperature for about 12 hours. After the reaction, the solution was washed with water. Then, the aqueous layer was extracted with ethyl acetate, and the organic layer was dried with magnesium sulfate. The organic layer was filtered, and the filtrate was concentrated to give 2-bromo-9,10-diphenyl-9,10-dihydroanthracene-9,10-diol, which was the object of the synthesis.

### (iii) Synthesis of 2-bromo-9,10-diphenylanthracene

A synthesis scheme of 2-bromo-9,10-diphenylanthracene is shown in (C-3).

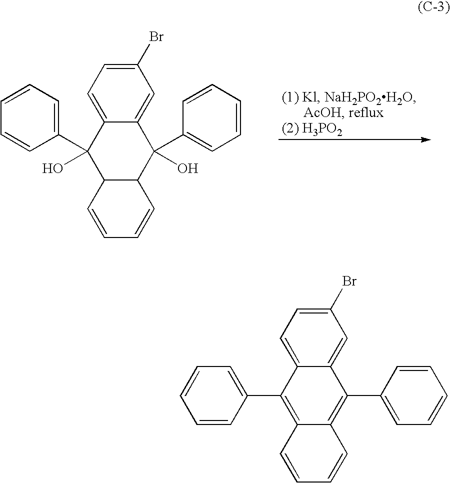

Into a 500 mL three-neck flask were put 7.55 g (16.95 mmol) of 2-bromo-9,10-diphenyl-9,10-dihydroanthracene-9,10-diol, which was obtained, 5.06 g (30.51 mmol) of potassium iodide, 9.70 g (91.52 mmol) of sodium phosphinate monohydrate, and 50 mL of glacial acetic acid. The mixture was stirred at 120° C. for two hours. Thereafter, 30 mL of a 50% phosphinic acid was added to the mixture, which was stirred at stirred at 120° C. for one hour. After the reaction, the reaction mixture was washed with water. Then, the aqueous layer was extracted with ethyl acetate. The organic layer was dried with magnesium sulfate and filtered, and the filtrate was concentrated to obtain a residue. The residue was dissolved in toluene, followed by filtration through Celite (produced by Wako Pure Chemical Industries, lid., Catalog No. 531-16855), Florisil (produced by Wako Pure Chemical Industries, ltd., Catalog No. 540-00135), and alumina. The filtrate was concentrated to give a solid. This solid was recrystallized with chloroform and hexane to give 5.1 g of a light yellow solid of 2-bromo-9,10-diphenylanthracene, which was the object of the synthesis, at a yield of 74%.

### [Step 2] Synthesis of N-phenyl-(9-phenyl-9H-carbazol-3-yl)amine (Abbreviated to PCA)

### (i) Synthesis of 3-bromo-9-phenylcarbazole

A synthesis scheme of 3-bromo-9-phenylcarbazole is shown in (C-5).

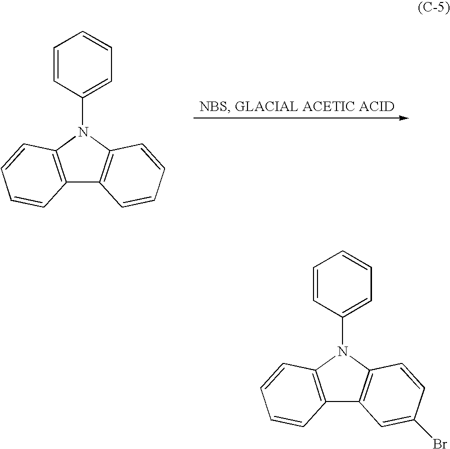

Into a 2 L Erlenmeyer flask were put 24.3 g (100 mmol) of 9-phenylcarbazole. The mixture was dissolved in 600 mL of glacial acetic acid. To the mixture were slowly added 17.8 g (100 mmol) of N-bromosuccinimide. The mixture was stirred at room temperature for about 12 hours. This glacial acetic acid solution was dripped into 1 L of ice water while being stirred so that a white solid was precipitated. This white solid was collected by suction filtration and washed with water three times. This solid was dissolved in 150 mL of diethyl ether, followed by washing with a saturated aqueous sodium hydrogen carbonate solution and then water. The organic layer was dried with magnesium sulfate and filtered. The obtained filtrate was concentrated to obtain a residue. The residue was dissolved in about 50 mL of methanol so that a white solid was precipitated. This white solid was collected by suction filtration and dried to give 28.4 g of a white powder of 3-bromo-9-phenylcarbazole at a yield of 88%.

### (ii) Synthesis of N-phenyl-(9-phenyl-9H-carbazol-3-yl)amine (PCA)

A synthesis scheme of N-phenyl-(9-phenyl-9H-carbazol-3-yl)amine (PCA) is shown in (C-6).

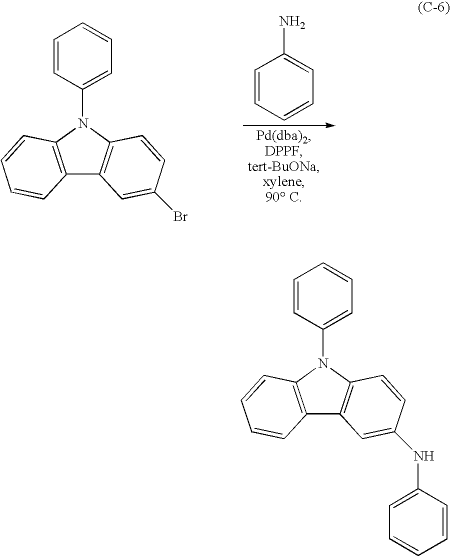

Into a 500 mL three-neck flask were put 19 g (60 mmol) of 3-bromo-9-phenylcarbazole, 340 mg (0.6 mmol) of bis(dibenzylideneacetone)palladium(0), 1.6 g (3.0 mmol) of 1,1-bis(diphenylphosphino)ferrocene, and 13 g (180 mmol) of sodium tert-butoxide, and the air in the flask was replaced with nitrogen. Then, 110 mL of dehydrated xylene and 7.0 g (75 mmol) of aniline were added to the mixture. This mixture was heated and stirred at 90° C. for 7.5 hours under a nitrogen atmosphere. After the reaction was completed, about 500 mL of hot toluene was added to the reaction mixture, and this mixture was filtered through Florisil (produced by Wako Pure Chemical Industries, Ltd., Catalog No. 540-00135), alumina, and Celite (produced by Wako Pure Chemical Industries, Ltd., Catalog No. 531-16855). The obtained filtrate was concentrated to obtain a residue. To the residue were added hexane and ethyl acetate, followed by irradiation with ultrasonic waves, and then, a solid was precipitated. The solid was collected by suction filtration to give 15 g of a cream colored powder of N-phenyl-(9-phenyl-9H-carbazol-3-yl)amine (PCA) at a yield of 75%. It was confirmed by nuclear magnetic resonance (NMR) measurements that this compound was N-phenyl-(9-phenyl-9H-carbazol-3-yl)amine (PCA).

¹H-NMR data of this compound are shown as follows: ¹H-NMR (300 MHz, CDCl₃,): δ=6.84 (t, J=6.9 Hz, 1H), 6.97 (d, J=7.8 Hz, 2H), 7.20-7.61 (m, 13H), 7.90 (s, 1H), 8.04 (d, J=7.8 Hz, 1H)

### [Step 3] Synthesis method of 2PCAPA

A synthesis scheme of 2PCAPA is shown in (C-7).

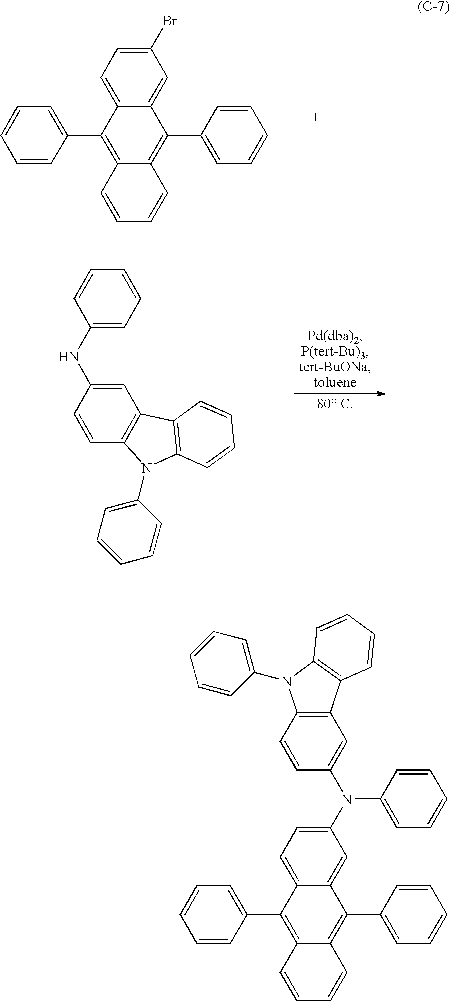

Into a 100 mL three-neck flask were added 1.8 g (4.40 mmol) of 2-bromo-9,10-diphenylanthracene, 1.76 g (5.28 mmol) of N-phenyl-9H-carbazol-3-yl)amine (PCA), 0.126 g (0.220 mmol) of bis(dibenzylideneacetone)palladium(0), and 2.11 g (21.99 mmol) of sodium tert-butoxide. The air in the flask was replaced with nitrogen. Further, 30 mL of toluene and 0.44 g (0.220 mmol) of tri(tert-butyl)phosphine (a 10 t % hexane solution) were added to the mixture. This mixture was stirred at 80° C. for 6 hours. After the reaction, the solution was washed with water. Then, the aqueous layer was extracted with ethyl acetate, and the organic layer was dried with magnesium sulfate. After the drying, the organic layer was filtered, and the filtrate was concentrated. The obtained reaction mixture was dissolved in toluene, followed by filtration through Celite (produced by Wako Pure Chemical Industries, Ltd., Catalog No. 531-16855), Florisil (produced by Wako Pure Chemical Industries, Ltd., Catalog No. 540-00135), and alumina. The filtrate was concentrated to obtain a residue. The residue was recrystallized with chloroform, methanol, and hexane to give 2.33 g of a yellow solid, which was the object of the synthesis, at a yield of 80%. It was confirmed by nuclear magnetic resonance spectroscopy (NMR) measurements that this compound was 9,10-diphenyl-2-[N-phenyl-N-(9-phenyl-9H-carbazol-3-yl)amino]anthracene (2PCAPA).

¹H-NMR data of this compound are shown as follows: ¹H-NMR (CDCl₃, 300 MHz): δ=6.92-6.97 (m, 1H), 7.11-7.32 (m, 16H), 7.39-7.66 (m, 15H), 7.88-7.97 (m, 2H)

### EXAMPLE 4

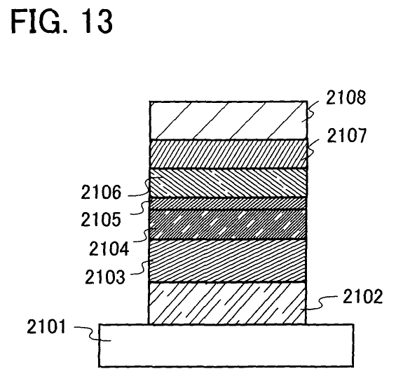

In this example, the light-emitting element of the present invention is described using FIG. 13.

The element structure of the light-emitting element fabricated in this example is shown in Table 3. In Table 3, each mixture ratio is indicated as a weight ratio.

TABLE 3

| | First | First | Second | Third | Forth | Fifth | Second |
|---|---|---|---|---|---|---|---|
| | electrode | layer | layer | layer | layer | layer | electrode |
| | 2102 | 2103 | 2104 | 2105 | 2106 | 2107 | 2108 |
| Light-emitting | ITSO | PEDOT:PSS | CzPA:2PCAPA | Alq | Bphen | LiF | Al |
| element A | 110 nm | 50 nm | (= 1:0.2) | 10 nm | 20 nm | 1 nm | 200 nm |
| | | | 50 nm | | | | |

Each mixture ratio is indicated as a weight ratio.

A method of fabricating Light-Emitting Element A of this example is described below.

First, Light-Emitting Element A is described. For Light-emitting element A, an indium tin oxide containing silicon oxide (ITSO) film was formed over a glass substrate 2101 by a sputtering method, whereby a first electrode 2102 was formed. It is to be noted that the film thickness of the first electrode was set to be 110 nm and that the area of the electrode was set to be 2 mm×2 mm.

Next, a first layer 2103 was formed. As a solution used for a pretreatment for forming Light-emitting element A, Solution C in which water and 2-methoxyethanol are mixed at a ratio of 3:2 and Solution D in which an undiluted solution of PEDOT:PSS (BAYTRON P AI4083 LVW 142) and 2-methoxyethanol are mixed at a rate of 3:2 were prepared. Solution C was dripped onto the substrate on which the first electrode 2102 was formed. After being spin-coated with Solution C at a spinning rate of 2000 rpm for 20 seconds, the substrate was spin-coated with Solution D at a spinning rate of 2000 rpm for 60 seconds and then at a spinning rate of 2500 rpm for 10 seconds. A film formed by the spin coating of Solution D on a terminal portion was removed using ethanol, and drying was performed by heating for two hours in a vacuum oven in which the temperature was set to be 110° C. while the pressure was reduced with a rotary pump, whereby a PEDOT/PSS film with a thickness of 50 nm was formed as the first layer 2103.

As a solution used for a second layer 2104 which is to serve as a layer containing a light-emitting substance, 0.15 g of CzPA and 0.031 g of 2PCAPA were measured to be put in a sample bottle. Into this bottle were added 15 mL of dehydrated toluene (produced by Kanto Chemical Co., Inc.) in an environment of a low moisture concentration (<0.1 ppm) and low oxygen concentration (to 10 ppm), and the sample bottle was stirred overnight with the lid closed, whereby Solution E was prepared.

Solution E was dripped onto the substrate on which the first layer 2103 was formed, in an environment of a low moisture concentration (<0.1 ppm) and a low oxygen concentration (to 10 ppm). The substrate was spin-coated with Solution E at a spinning rate of 300 rpm for 3 seconds, at a spinning rate of 1000 rpm for 60 seconds, and then at a spinning rate of 2500 rpm for 10 seconds. A film formed by the spin coating of Solution E on a terminal portion was removed using toluene, and drying was performed by heating for one hour in a vacuum oven in which the temperature was set to be 110° C. while the pressure was reduced with a rotary pump, whereby the second layer 2104 was formed. Thereafter, the substrate was disposed in a vacuum evaporation apparatus in which the pressure was reduced so that a surface on which the film was to be formed faced downward.

An Alq film was formed over the second layer 2104 to a thickness of 10 nm as a third layer 2105 which is to serve as an electron-transporting layer.

A Bphen film was deposited over the third layer 2105 of Light-Emitting Element A to a thickness of 20 nm as a forth layer 2106. Further, lithium fluoride (LiF) was deposited over the forth layer 2106 to a thickness of 1 nm, whereby a fifth layer 2107 was formed as the electron-injecting layer. Lastly, aluminum was deposited to a thickness of 200 nm for a second electrode 2108 which is to serve as a cathode. Accordingly, Light-Emitting Element A of this example was obtained. It is to be noted that an evaporation method using resistive heating was employed for all the evaporation steps.

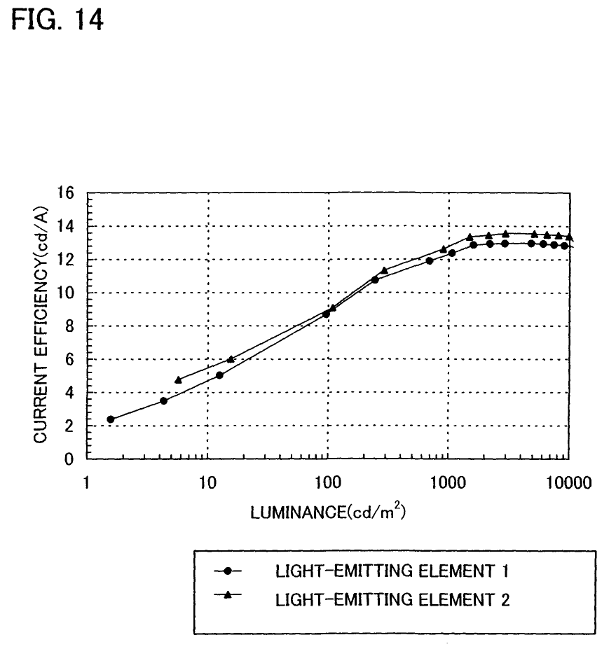

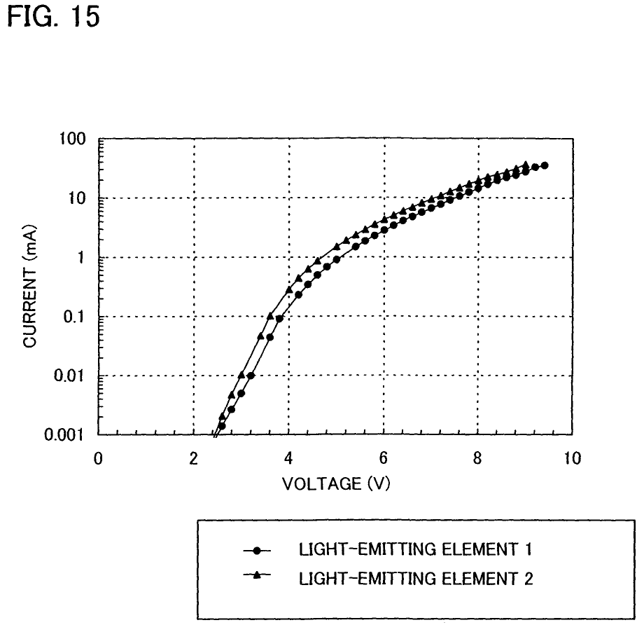

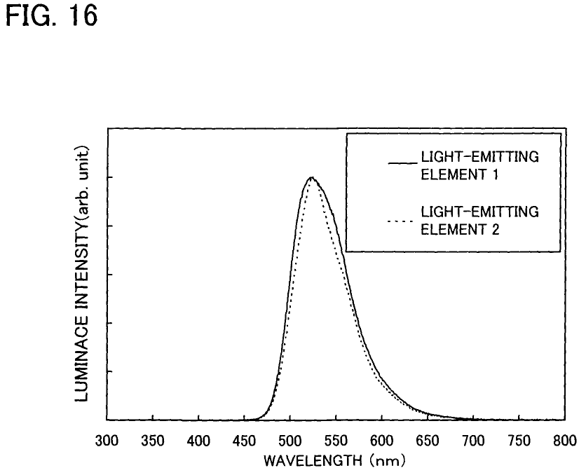

Luminance-current efficiency characteristics and current-voltage characteristics of Light-Emitting Element A are shown in FIG. 14 and FIG. 15, respectively. Further, the emission spectrum measured at a current of 1 mA is shown in FIG. 16.

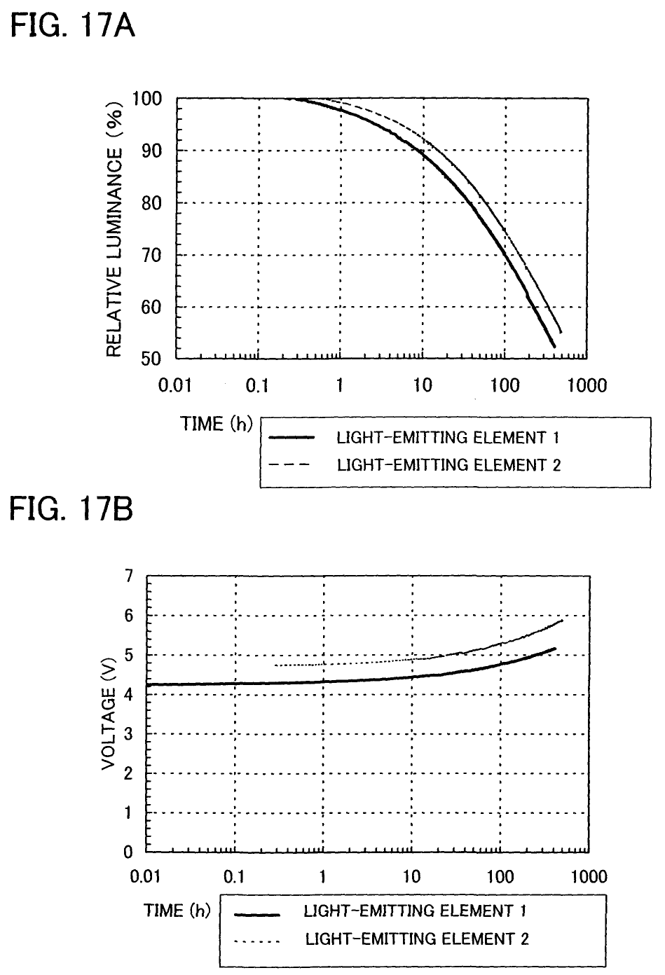

Furthermore, reliability testing of fabricated Light-Emitting Element A was performed. The reliability testing was performed as follows: the luminance was measured after every certain period of time passes while a current having the same value as that flows through Light-Emitting Element A where it emits light with a luminance of 1000 cd/m² was continued to be made flow in an initial state. Results of the reliability testing are shown in FIGS. 17A and 17B. FIG. 17A shows a change in luminance over time, and FIG. 17B shows a change in voltage over time. It is to be noted that in FIG. 17A, the horizontal axis represents current flow time (hour) and that the vertical axis represents the proportion of luminance with respect to the initial luminance at each time, that is, relative luminance (%). Further, in FIG. 17B, the horizontal axis represents current flow time (hour), and the vertical axis represents voltage.

According to this example, it was confirmed that the light-emitting element of the present invention has the characteristics as a light-emitting element and fully functions. Further, from the results of the reliability testing, it is understood that a highly reliable light-emitting element in which a short circuit due to defects of the film or the like is not caused even if the element is continuously made to emit light.

This application is based on Japanese Patent Application serial no. 2007-131241 filed with Japan Patent Office on May 17, 2007, the entire contents of which are hereby incorporated by reference.

What is claimed is:

1. A composition comprising an anthracene derivative represented by a general formula (1) and a solvent, 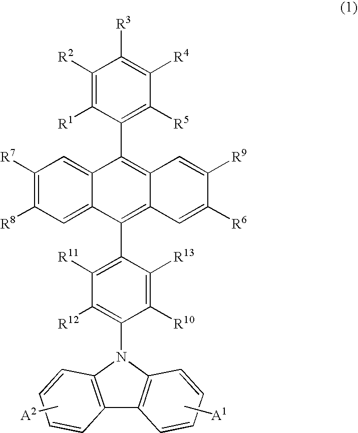
wherein R¹ to R¹³ each represent hydrogen, an alkyl group having 1 to 6 carbon atoms, or a substituted or unsubstituted aryl group having 6 to 14 carbon atoms, and are the same or different from each other, and
wherein A¹ and A² each represent hydrogen, an alkyl group having 1 to 6 carbon atoms, a substituted or unsubstituted aryl group having 6 to 14 carbon atoms, or a substituted or unsubstituted diarylamino group, and are the same or different from each other.

2. A composition comprising an anthracene derivative represented by a general formula (2) and a solvent, 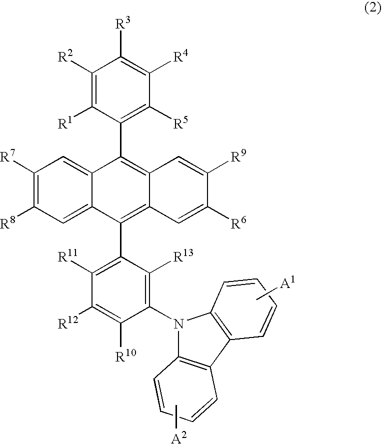
wherein R¹ to R¹³ each represent hydrogen, an alkyl group having 1 to 6 carbon atoms, or a substituted or unsubstituted aryl group having 6 to 14 carbon atoms, and are the same or different from each other, and
wherein A¹ and A² each represent hydrogen, an alkyl group having 1 to 6 carbon atoms, a substituted or unsubstituted aryl group having 6 to 14 carbon atoms, or a substituted or unsubstituted diarylamino group, and are the same or different from each other.

3. The composition according to claim 1,
wherein R¹ to R¹³ each represent hydrogen or a substituted or unsubstituted aryl group having 6 to 14 carbon atoms, and are the same or different from each other, and
wherein A¹ and A² each represent hydrogen, a substituted or unsubstituted aryl group having 6 to 14 carbon atoms, or a substituted or unsubstituted diarylamino group, and are the same or different from each other.

4. The composition according to claim 2,
wherein R¹ to R¹³ each represent hydrogen or a substituted or unsubstituted aryl group having 6 to 14 carbon atoms, and are the same or different from each other, and
wherein A¹ and A² each represent hydrogen, a substituted or unsubstituted aryl group having 6 to 14 carbon atoms, or a substituted or unsubstituted diarylamino group, and are the same or different from each other.

5. A composition comprising an anthracene derivative represented by a general formula (3) and a solvent, 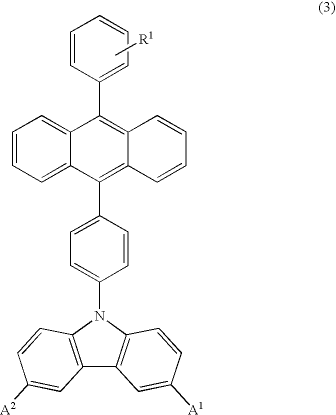
wherein R¹ represents hydrogen, an alkyl group having 1 to 6 carbon atoms, or a substituted or unsubstituted aryl group having 6 to 14 carbon atoms, and
wherein A¹ and A² each represent hydrogen, an alkyl group having 1 to 6 carbon atoms, a substituted or unsubstituted aryl group having 6 to 14 carbon atoms, or a substituted or unsubstituted diarylamino group, and are the same or different from each other.

6. The composition according to claim 5,
wherein R¹ represents hydrogen or a substituted or unsubstituted aryl group having 6 to 14 carbon atoms, and
wherein A¹ and A² each represent hydrogen, a substituted or unsubstituted aryl group having 6 to 14 carbon atoms, or a substituted or unsubstituted diarylamino group, and are the same or different from each other.

7. The composition according to claim 1,
wherein R¹, R², and R⁴ to R¹³ represent hydrogen,
wherein R represents hydrogen, an alkyl group having 1 to 6 carbon atoms, or a substituted or unsubstituted aryl group having 6 to 14 carbon atoms, and
wherein A¹ and A² each represent hydrogen, an alkyl group having 1 to 6 carbon atoms, a substituted or unsubstituted aryl group having 6 to 14 carbon atoms, or a substituted or unsubstituted diarylamino group, and are the same or different from each other.

8. The composition according to claim 1,
wherein R¹, R², and R⁴ to R¹³ each represent hydrogen,
wherein R³ represents hydrogen or a substituted or unsubstituted aryl group having 6 to 14 carbon atoms, and
wherein A¹ and A² each represent hydrogen, a substituted or unsubstituted aryl group having 6 to 14 carbon atoms, or a substituted or unsubstituted diarylamino group and are the same or different from each other.

9. The composition according to claim 1,
wherein R¹, R², and R⁴ to R¹³ each represent hydrogen,
wherein R³ represents hydrogen, an alkyl group having 1 to 6 carbon atoms, or a substituted or unsubstituted aryl group having 6 to 14 carbon atoms, and
wherein A¹ and A² each represent hydrogen.

10. The composition according to claim 1,
wherein R¹, R², and R⁴ to R¹³ each represent hydrogen,
wherein R³ represents hydrogen or a substituted or unsubstituted aryl group having 6 to 14 carbon atoms, and
wherein A¹ and A² each represent hydrogen.

11. The composition according to claim 1,
wherein the solvent has an aromatic ring.

12. The composition according to claim 2,
wherein the solvent has an aromatic ring.

13. The composition according to claim 5,
wherein the solvent has an aromatic ring.

14. A method of fabricating a light-emitting element comprising:
forming a first electrode;
forming a layer containing a light-emitting substance by application of a composition, which comprises an anthracene derivative and a solvent, to the first electrode and removing the solvent; and
forming a second electrode over the layer containing the light-emitting substance,
wherein the anthracene derivative is represented by a general formula (1), 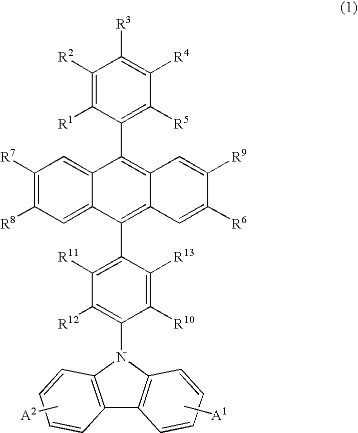
wherein R¹ to R¹³ each represent hydrogen, an alkyl group having 1 to 6 carbon atoms, or a substituted or unsubstituted aryl group having 6 to 14 carbon atoms, and are the same or different from each other, and
wherein A¹ and A² each represent hydrogen, an alkyl group having 1 to 6 carbon atoms, a substituted or unsubstituted aryl group having 6 to 14 carbon atoms, or a substituted or unsubstituted diarylamino group, and are the same or different from each other.

15. A method of fabricating a light-emitting element comprising:
forming a first electrode;
forming a layer containing a light-emitting substance by application of a composition, which comprises an anthracene derivative and a solvent, to the first electrode and removing the solvent; and
forming a second electrode over the layer containing the light-emitting substance,
wherein the anthracene derivative is represented by a general formula (2), 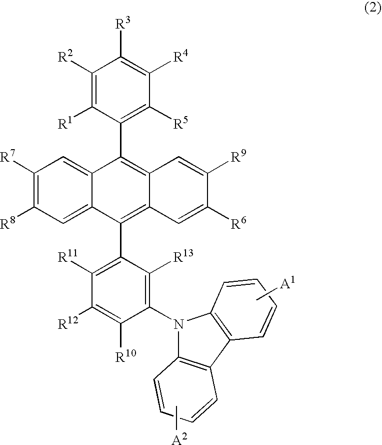
wherein R¹ to R¹³ each represent hydrogen, an alkyl group having 1 to 6 carbon atoms, or a substituted or unsubstituted aryl group having 6 to 14 carbon atoms, and are the same or different from each other, and
wherein A¹ and A² each represent hydrogen, an alkyl group having 1 to 6 carbon atoms, a substituted or unsubstituted aryl group having 6 to 14 carbon atoms, or a substituted or unsubstituted diarylamino group, and are the same or different from each other.

16. The method of fabricating a light-emitting element according to claim 14,
wherein R¹ to R¹³ each represent hydrogen or a substituted or unsubstituted aryl group having 6 to 14 carbon atoms, and are the same or different from each other, and
wherein A¹ and A² each represent hydrogen, a substituted or unsubstituted aryl group having 6 to 14 carbon atoms, or a substituted or unsubstituted diarylamino group, and are the same or different from each other.

17. The method of fabricating a light-emitting element according to claim 15,
wherein R¹ to R¹³ each represent hydrogen or a substituted or unsubstituted aryl group having 6 to 14 carbon atoms, and are the same or different from each other, and
wherein A¹ and A² each represent hydrogen, a substituted or unsubstituted aryl group having 6 to 14 carbon atoms, or a substituted or unsubstituted diarylamino group, and are the same or different from each other.

18. A method of fabricating a light-emitting element comprising:
forming a first electrode;
forming a layer containing a light-emitting substance by application of a composition, which comprises an anthracene derivative and a solvent, to the first electrode and removing the solvent; and
forming a second electrode over the layer containing the light-emitting substance,
wherein the anthracene derivative is represented by a general formula (3), 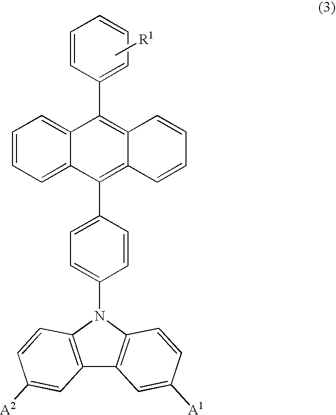
wherein R¹ represents hydrogen, an alkyl group having 1 to 6 carbon atoms, or a substituted or unsubstituted aryl group having 6 to 14 carbon atoms, and
wherein A¹ and A² each represent hydrogen, an alkyl group having 1 to 6 carbon atoms, a substituted or unsubstituted aryl group having 6 to 14 carbon atoms, or a substituted or unsubstituted diarylamino group, and are the same or different from each other.

19. The method of fabricating a light-emitting element according to claim 18,
wherein R¹ represents hydrogen or a substituted or unsubstituted aryl group having 6 to 14 carbon atoms, and
wherein A¹ and A² each represent hydrogen, a substituted or unsubstituted aryl group having 6 to 14 carbon atoms, or a substituted or unsubstituted diarylamino group, and are the same or different from each other.

20. The method of fabricating a light-emitting element according to claim 14,
wherein R¹, R², and R⁴ to R¹³ represent hydrogen,
wherein R³ represents hydrogen, an alkyl group having 1 to 6 carbon atoms, or a substituted or unsubstituted aryl group having 6 to 14 carbon atoms, and
wherein A¹ and A² each represent hydrogen, an alkyl group having 1 to 6 carbon atoms, a substituted or unsubstituted aryl group having 6 to 14 carbon atoms, or a substituted or unsubstituted diarylamino group, and are the same or different from each other.

21. The method of fabricating a light-emitting element according to claim 14,
wherein R¹, R², and R⁴ to R¹³ each represent hydrogen,
wherein R³ represents hydrogen or a substituted or unsubstituted aryl group having 6 to 14 carbon atoms, and
wherein A¹ and A² each represent hydrogen, a substituted or unsubstituted aryl group having 6 to 14 carbon atoms, or a substituted or unsubstituted diarylamino group and are the same or different from each other.

22. The method of fabricating a light-emitting element according to claim 14,
wherein R¹, R², and R⁴ to R¹³ each represent hydrogen,
wherein R³ represents hydrogen, an alkyl group having 1 to 6 carbon atoms, or a substituted or unsubstituted aryl group having 6 to 14 carbon atoms, and
wherein A¹ and A² each represent hydrogen.

23. The method of fabricating a light-emitting element according to claim 14,
wherein R¹, R², and R⁴ to R¹³ each represent hydrogen,
wherein R³ represents hydrogen or a substituted or unsubstituted aryl group having 6 to 14 carbon atoms, and
wherein A¹ and A² each represent hydrogen.

24. The method of fabricating a light-emitting element according to claim 14,
wherein the solvent has an aromatic ring.

25. The method of fabricating a light-emitting element according to claim 15,
wherein the solvent has an aromatic ring.

26. The method of fabricating a light-emitting element according to claim 18,
wherein the solvent has an aromatic ring.

27. The method of fabricating a light-emitting element according to claim 14, further comprising forming a functional layer by a coating method on at least one of a first electrode side and a second electrode side of the layer containing the light-emitting substance.

28. The method of fabricating a light-emitting element according to claim 15, further comprising forming a functional layer by a coating method on at least one of a first electrode side and a second electrode side of the layer containing the light-emitting substance.

29. The method of fabricating a light-emitting element according to claim 18, further comprising forming a functional layer by a coating method on at least one of a first electrode side and a second electrode side of the layer containing the light-emitting substance.

30. The method of fabricating a light-emitting element according to claim 14, further comprising forming a functional layer by an evaporation method on at least one of a first electrode side and a second electrode side of the layer containing the light-emitting substance.

31. The method of fabricating a light-emitting element according to claim 15, further comprising forming a functional layer by an evaporation method on at least one of a first electrode side and a second electrode side of the layer containing the light-emitting substance.

32. The method of fabricating a light-emitting element according to claim 18, further comprising forming a functional layer by an evaporation method on at least one of a first electrode side and a second electrode side of the layer containing the light-emitting substance.
